(19) United States
(12) Patent Application Publication
(10) Pub. No.: US 2026/0090194 A1
(43) Pub. Date: Mar. 26, 2026

(54) ORGANIC ELECTROLUMINESCENT DEVICE

(71) Applicant: DuPont Specialty Materials Korea Ltd., Chungcheongnam-do (KR)

(72) Inventors: Hong-Yeop NA, Gyeonggi-do (KR); Mi-Ja LEE, Gyeonggi-do (KR); Seon-Jin HWANG, Gyeonggi-do (KR)

(21) Appl. No.: 19/328,802

(22) Filed: Sep. 15, 2025

(30) Foreign Application Priority Data
Sep. 23, 2024 (KR) 10-2024-0128064
Jul. 31, 2025 (KR) 10-2025-0104909

(51) Int. Cl. H10K 50/12; C09K 11/06; H10K 50/15; H10K 50/16; H10K 50/17; H10K 85/60; H10K 101/00; H10K 102/00

(52) U.S. Cl. CPC H10K 50/121; C09K 11/06; H10K 85/615; H10K 85/654; H10K 85/6572; H10K 85/6574; H10K 85/6576; H10K 85/658; C09K 2211/1029; H10K 50/15; H10K 50/16; H10K 50/17; H10K 50/171; H10K 2101/27; H10K 2102/351

(57) ABSTRACT

The present disclosure relates to an organic electroluminescent device, and by comprising a compound according to the present disclosure, an organic electroluminescent device exhibiting higher luminous efficiency than a conventional organic electroluminescent device can be provided.

### TECHNICAL FIELD

The present disclosure relates to an organic electroluminescent device.

### BACKGROUND ART

The TPD/Alq₃ bilayer small-molecule organic electroluminescent device (OLED) with green emission, which is constituted with a light-emitting layer and a charge transport layer, was first developed by Tang et al. of Eastman Kodak in 1987. Thereafter, studies on organic electroluminescent devices have proceeded rapidly, and OLEDs have since been commercialized.

The most important factor determining luminous efficiency in an OLED is light-emitting materials. The light-emitting material can be functionally classified into host and dopant materials. A light-emitting material can be used as a combination of a host and a dopant to improve color purity, luminous efficiency, and stability. Generally, a device having excellent electroluminescent (EL) characteristics has a structure comprising a light-emitting layer formed by doping a dopant to a host. When using such a dopant/host material system as a light-emitting material, their selection is important since host materials greatly influence the efficiency and lifespan of the EL device.

Recently, the development of OLEDs with high efficiency and long lifespan has emerged as an urgent task. In particular, the development of a light-emitting material that is highly excellent compared to conventional light-emitting materials is urgently required in consideration of the EL properties necessary for medium and large-sized OLED panels.

However, U.S. Patent Application Publication No. 2017/0271598 A1, Korean Patent Application Laid-Open No. 2023-0115267, and Korean Patent Application Laid-Open No. 2022-151566 disclose an organic electroluminescent device comprising an indolocarbazole derivative as a host, but said references do not specifically disclose a specific combination of host and dopant materials as described in the present disclosure. In addition, there is still a need for development of a light-emitting material having improved performance, such as improved high luminous efficiency properties, compared to the conventional specific combination of compounds disclosed in said references.

### DISCLOSURE OF INVENTION

### Technical Problem

The object of the present disclosure is to provide an organic electroluminescent device which exhibits a high luminous efficacy compared to conventional organic electroluminescent devices.

### Solution to Problem

As a result of intensive studies to solve the technical problem above, the present inventors found that the aforementioned object can be achieved by an organic electroluminescent device comprising: a first electrode; a second electrode; and a light-emitting layer positioned between the first electrode and the second electrode, wherein the light-emitting layer comprises a host and a dopant; wherein the host comprises a compound represented by the following Formula 1, and wherein the dopant comprises a compound comprising a boron (B) atom, thereby completing the present invention.

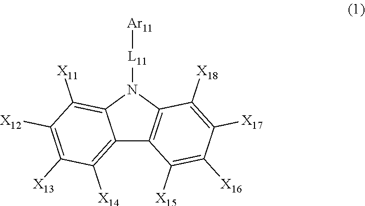

In Formula 1,
an adjacent pair(s) in X₁₅ to X₁₈ is(are) linked to [symbol] in the following Formula 1-A:

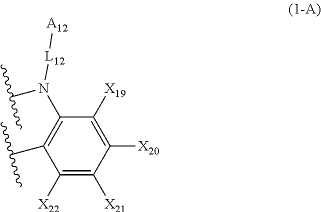

X₁₁ to X₁₄, X₁₅ to X₁₈ that are not linked to form a ring(s), and X₁₉ to X₂₂ each independently represent hydrogen, deuterium, a substituted or unsubstituted (C₆-C₃₀)alkyl, a substituted or unsubstituted (C₆-C₃₀)cycloalkyl, a substituted or unsubstituted (C₆-C₃₀)aryl, a substituted or unsubstituted (3- to 30-membered)heteroaryl, or a combination thereof;
L₁₁ and L₁₂ each independently represent a single bond or a substituted or unsubstituted (C₆-C₃₀)arylene; and
Ar₁₁ and Ar₁₂ each independently represent a substituted or unsubstituted (C₆-C₃₀)aryl, a substituted or unsubstituted (3- to 30-membered)heteroaryl having hole-transporting properties, or a combination thereof.

### Advantageous Effects of Invention

An organic electroluminescent device exhibits high luminous efficiency by comprising a plurality of hosts and a dopant in a light-emitting layer of an organic electroluminescent device according to the present disclosure.

### BRIEF DESCRIPTION OF DRAWINGS

FIG. 1 schematically illustrates an organic electroluminescent device according to one embodiment of the present disclosure.

FIG. 2 shows a PL spectrum of a dopant according to one embodiment of the present disclosure.

FIG. 3 shows a PL spectrum of thin films according to Example 1 and Comparative Example 1 according to one embodiment of the present disclosure.

FIG. 4 shows a PL spectrum of thin films according to Examples 2 and 3 and Comparative Example 1 according to one embodiment of the present disclosure.

### MODE FOR INVENTION

Hereinafter, the present disclosure will be described in detail. However, the following description is intended to explain the invention, and is not meant in any way to restrict the scope of the invention.

An organic electroluminescent device according to the present disclosure comprises a first electrode; a second electrode; and a light-emitting layer positioned between the first and second electrodes. The light-emitting layer comprises a host and a dopant; wherein the host comprises a compound represented by the following Formula 1, and wherein the dopant comprises a compound containing a boron (B) atom.

Herein, the term “compound” or “organic electroluminescent compound”, as used in the present disclosure, means a compound that may be used in an organic electroluminescent device, and this may be comprised in any material layer constituting an organic electroluminescent device as necessary.

Herein, the term “organic electroluminescent material” means a material that may be used in an organic electroluminescent device, and this may comprise at least one compound. The organic electroluminescent material may be comprised in any layer constituting an organic electroluminescent device as necessary. For example, the organic electroluminescent material may be a hole injection material, a hole transport material, a hole auxiliary material, a light-emitting auxiliary material, an electron-blocking material, a light-emitting material (containing host and dopant materials), an electron buffer material, a hole-blocking material, an electron transport material, or an electron injection material, etc.

Herein, the term “a plurality of host materials” means an organic electroluminescent material comprising a combination of at least two host materials. It may mean both a material before being comprised in an organic electroluminescent device (e.g., before vapor deposition) and a material after being comprised in an organic electroluminescent device (e.g., after vapor deposition). A plurality of host materials of the present disclosure may be comprised in any light-emitting layer constituting an organic electroluminescent device. The at least two compounds comprised in a plurality of host materials may be comprised together in one light-emitting layer, or may each be comprised in separate light-emitting layers. When at least two compounds are comprised in one light-emitting layer, the at least two compounds may be mixture-evaporated to form a layer or may be individually and simultaneously co-evaporated to form a layer.

Herein, “(C₁-C_{3M})alkyl” is meant to be a linear or branched alkyl having 1 to 30 carbon atoms constituting the chain, in which the number of carbon atoms is preferably 1 to 20, more preferably 1 to 10. The above alkyl may include methyl, ethyl, n-propyl, isopropyl, n-butyl, isobutyl, tert-butyl, sec-butyl, etc. Herein, the “(C₃-C₃₀)cycloalkyl” is meant to be a mono- or polycyclic hydrocarbon having 3 to 30 ring backbone carbon atoms, in which the number of carbon atoms is preferably 3 to 20, more preferably 3 to 7. The above cycloalkyl may include cyclopropyl, cyclobutyl, cyclopentyl, cyclohexyl, cyclopentylmethyl, cyclohexylmethyl, etc. The “(3- to 7-membered)heterocycloalkyl” in the present disclosure is meant to be a cycloalkyl having 3 to 7 ring backbone atoms, preferably 5 to 7 ring backbone atoms and including at least one heteroatom selected from the group consisting of B, N, O, S, Si, and P, preferably O, S, and N, and includes tetrahydrofuran, pyrrolidine, thiolan, tetrahydropyran, etc. The “(C₆-C₃₀)aryl(ene)” in the present disclosure is meant to be a monocyclic or fused ring radical derived from an aromatic hydrocarbon having 6 to 30 ring backbone carbon atoms, in which the number of the ring backbone carbon atoms is preferably 6 to 20, more preferably 6 to 15. The above aryl may be partially saturated and may comprise a spiro structure. Examples of the aryl specifically include phenyl, biphenyl, terphenyl, quaterphenyl, naphthyl, binaphthyl, phenylnaphthyl, naphthylphenyl, fluorenyl, phenylfluorenyl, dimethylfluorenyl, diphenylfluorenyl, benzofluorenyl, diphenylbenzofluorenyl, dibenzofluorenyl, phenanthrenyl, benzophenanthrenyl, phenylphenanthrenyl, anthracenyl, benzanthracenyl, indenyl, triphenylenyl, pyrenyl, tetracenyl, perylenyl, chrysenyl, benzochrysenyl, naphthacenyl, fluoranthenyl, benzofluoranthenyl, tolyl, xylyl, mesityl, cumenyl, spiro[fluorene-fluorene]yl, spiro[fluorene-benzofluorene]yl, azulenyl, tetramethyl-dihydrophenanthrenyl, etc. More specifically, the aryl may be o-tolyl, m-tolyl, p-tolyl, 2,3-xylyl, 3,4-xylyl, 2,5-xylyl, mesityl, o-cumenyl, m-cumenyl, p-cumenyl, p-t-butylphenyl, p-(2-phenylpropyl)phenyl, 4′-methylbiphenyl, 4″-t-butyl-p-terphenyl-4-yl, o-biphenyl, m-biphenyl, p-biphenyl, o-terphenyl, m-terphenyl-4-yl, m-terphenyl-3-yl, m-terphenyl-2-yl, p-terphenyl-4-yl, p-terphenyl-3-yl, p-terphenyl-2-yl, m-quaterphenyl, 1-naphthyl, 2-naphthyl, 1-fluorenyl, 2-fluorenyl, 3-fluorenyl, 4-fluorenyl, 9-fluorenyl, 9,9-dimethyl-1-fluorenyl, 9,9-dimethyl-2-fluorenyl, 9,9-dimethyl-3-fluorenyl, 9,9-dimethyl-4-fluorenyl, 9,9-diphenyl-1-fluorenyl, 9,9-diphenyl-2-fluorenyl, 9,9-diphenyl-3-fluorenyl, 9,9-diphenyl-4-fluorenyl, 1-anthryl, 2-anthryl, 9-anthryl, 1-phenanthryl, 2-phenanthryl, 3-phenanthryl, 4-phenanthryl, 9-phenanthryl, 1-chrysenyl, 2-chrysenyl, 3-chrysenyl, 4-chrysenyl, 5-chrysenyl, 6-chrysenyl, benzo[c]phenanthryl, benzo[g]chrysenyl, 1-triphenylenyl, 2-triphenylenyl, 3-triphenylenyl, 4-triphenylenyl, 3-fluoranthenyl, 4-fluoranthenyl, 8-fluoranthenyl, 9-fluoranthenyl, benzofluoranthenyl, 11,11-dimethyl-1-benzo[a]fluorenyl, 11,11-dimethyl-2-benzo[a]fluorenyl, 11,11-dimethyl-3-benzo[a]fluorenyl, 11,11-dimethyl-4-benzo[a]fluorenyl, 11,11-dimethyl-5-benzo[a]fluorenyl, 11,11-dimethyl-6-benzo[a]fluorenyl, 11,11-dimethyl-7-benzo[a]fluorenyl, 11,11-dimethyl-8-benzo[a]fluorenyl, 11,11-dimethyl-9-benzo[a]fluorenyl, 11,11-dimethyl-10-benzo[a]fluorenyl, 11,11-dimethyl-1-benzo[b]fluorenyl, 11,11-dimethyl-2-benzo[b]fluorenyl, 11,11-dimethyl-3-benzo[b]fluorenyl, 11,11-dimethyl-4-benzo[b]fluorenyl, 11,11-dimethyl-5-benzo[b]fluorenyl, 11,11-dimethyl-6-benzo[b]fluorenyl, 11,11-dimethyl-7-benzo[b]fluorenyl, 11,11-dimethyl-8-benzo[b]fluorenyl, 11,11-dimethyl-9-benzo[b]fluorenyl, 11,11-dimethyl-10-benzo[b]fluorenyl, 11,11-dimethyl-1-benzo[c]fluorenyl, 11,11-dimethyl-2-benzo[c]fluorenyl, 11,11-dimethyl-3-benzo[c]fluorenyl, 11,11-dimethyl-4-benzo[c]fluorenyl, 11,11-dimethyl-5-benzo[c]fluorenyl, 11,11-dimethyl-6-benzo[c]fluorenyl, 11,11-dimethyl-7-benzo[c]fluorenyl, 11,11-dimethyl-8-benzo[c]fluorenyl, 11,11-dimethyl-9-benzo[c]fluorenyl, 11,11-dimethyl-10-benzo[c]fluorenyl, 11,11-diphenyl-1-benzo[a]fluorenyl, 11,11-diphenyl-2-benzo[a]fluorenyl, 11,11-diphenyl-3-benzo[a]fluorenyl, 11,11-diphenyl-4-benzo[a]fluorenyl, 11,11-diphenyl-5-benzo[a]fluorenyl, 11,11-diphenyl-6-benzo[a]fluorenyl, 11,11-diphenyl-7-benzo[a]fluorenyl, 11,11-diphenyl-8-benzo[a]fluorenyl, 11,11-diphenyl-9-benzo[a]fluorenyl, 11,11-diphenyl-10-benzo[a]fluorenyl, 11,11-diphenyl-1-benzo[b]fluorenyl, 11,11-diphenyl-2-benzo[b]fluorenyl, 11,11-diphenyl-3-benzo[b]fluorenyl, 11,11-diphenyl-4-benzo[b]fluorenyl, 11,11-diphenyl-5-benzo[b]fluorenyl, 11,11-diphenyl-6-benzo[b]fluorenyl, 11,11-diphenyl-7-benzo[b]fluorenyl, 11,11-diphenyl-8-benzo[b]fluorenyl, 11,11-diphenyl-9-benzo[b]fluorenyl, 11,11-diphenyl-10-benzo[b]fluorenyl, 11,11-diphenyl-1-benzo[c]fluorenyl, 11,11-diphenyl-2-benzo[c]fluorenyl, 11,11-diphenyl-3-benzo[c]fluorenyl, 11,11-diphenyl-4-benzo[c]fluorenyl, 11,11-diphenyl-5-benzo[c]fluorenyl, 11,11-diphenyl-6-benzo[c]fluorenyl, 11,11-diphenyl-7-benzo[c]fluorenyl, 11,11-diphenyl-8-benzo[c]fluorenyl, 11,11-diphenyl-9-benzo[c]fluorenyl, 11,11-diphenyl-10-benzo[c]fluorenyl, 9,9,10,10-tetramethyl-9,10-dihydro-1-phenanthrenyl, 9,9,10,10-tetramethyl-9,10-dihydro-2-phenanthrenyl, 9,9,10,10-tetramethyl-9,10-dihydro-3-phenanthrenyl, 9,9,10,10-tetramethyl-9,10-dihydro-4-phenanthrenyl, etc. The “(3- to 30-membered)heteroaryl(ene)” in the present disclosure is an aryl having 3 to 30 ring backbone atoms and including at least one heteroatom selected from the group consisting of B, N, O, S, Si, P, Se, and Ge in which the number of the ring backbone atoms is preferably 5 to 25. The number of the heteroatoms in the heteroaryl is preferably 1 to 4. The above heteroaryl may be a monocyclic ring or a fused ring condensed with at least one benzene ring, and may be partially saturated. Also, the above heteroaryl herein may be one formed by linking at least one heteroaryl or aryl group to a heteroaryl group via a single bond(s). Examples of the heteroaryl specifically may include a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, dibenzoselenophenyl, benzofuroquinolinyl, benzofuroquinazolinyl, benzofuronaphthyridinyl, benzofuropyrimidinyl, naphthofuropyrimidinyl, benzothienoquinolinyl, benzothienoquinazolinyl, benzothienonaphthyridinyl, benzothienopyrimidinyl, naphthothienopyrimidinyl, pyrimidoindolyl, benzopyrimidoindolyl, benzofuropyrazinyl, naphthofuropyrazinyl, benzothienopyrazinyl, naphthothienopyrazinyl, pyrazinoindolyl, benzopyrazinoindolyl, benzoimidazolyl, benzothiazolyl, benzoisothiazolyl, benzoisoxazolyl, benzoxazolyl, imidazopyridinyl, isoindolyl, indolyl, benzoindolyl, indazolyl, benzothiadiazolyl, quinolyl, isoquinolyl, cinnolinyl, quinazolinyl, quinoxalinyl, carbazolyl, azacarbazolyl, benzocarbazolyl, dibenzocarbazolyl, phenoxazinyl, phenanthridinyl, benzodioxolyl, indolizidinyl, acridinyl, silafluorenyl, germafluorenyl, benzotriazolyl, phenazinyl, imidazopyridinyl, chromenoquinazolinyl, thiochromenoquinazolinyl, dimethylbenzopyrimidinyl, indolocarbazolyl, indenocarbazolyl, etc. More specifically, the heteroaryl may be 1-pyrrolyl, 2-pyrrolyl, 3-pyrrolyl, 2-pyridinyl, 3-pyridinyl, 4-pyridinyl, 2-pyrimidinyl, 4-pyrimidinyl, 5-pyrimidinyl, 6-pyrimidinyl, 1,2,3-triazin-4-yl, 1,2,4-triazin-3-yl, 1,3,5-triazin-2-yl, 1-imidazolyl, 2-imidazolyl, 1-pyrazolyl, 1-indolizidinyl, 2-indolizidinyl, 3-indolizidinyl, 5-indolizidinyl, 6-indolizidinyl, 7-indolizidinyl, 8-indolizidinyl, 2-imidazopyridinyl, 3-imidazopyridinyl, 5-imidazopyridinyl, 6-imidazopyridinyl, 7-imidazopyridinyl, 8-imidazopyridinyl, 1-indolyl, 2-indolyl, 3-indolyl, 4-indolyl, 5-indolyl, 6-indolyl, 7-indolyl, 1-isoindolyl, 2-isoindolyl, 3-isoindolyl, 4-isoindolyl, 5-isoindolyl, 6-isoindolyl, 7-isoindolyl, 2-furyl, 3-furyl, 2-benzofuranyl, 3-benzofuranyl, 4-benzofuranyl, 5-benzofuranyl, 6-benzofuranyl, 7-benzofuranyl, 1-isobenzofuranyl, 3-isobenzofuranyl, 4-isobenzofuranyl, 5-isobenzofuranyl, 6-isobenzofuranyl, 7-isobenzofuranyl, 2-quinolyl, 3-quinolyl, 4-quinolyl, 5-quinolyl, 6-quinolyl, 7-quinolyl, 8-quinolyl, 1-isoquinolyl, 3-isoquinolyl, 4-isoquinolyl, 5-isoquinolyl, 6-isoquinolyl, 7-isoquinolyl, 8-isoquinolyl, 2-quinoxalinyl, 5-quinoxalinyl, 6-quinoxalinyl, 1-carbazolyl, 2-carbazolyl, 3-carbazolyl, 4-carbazolyl, 9-carbazolyl, azacarbazol-1-yl, azacarbazol-2-yl, azacarbazol-3-yl, azacarbazol-4-yl, azacarbazol-5-yl, azacarbazol-6-yl, azacarbazol-7-yl, azacarbazol-8-yl, azacarbazol-9-yl, 1-phenanthridinyl, 2-phenanthridinyl, 3-phenanthridinyl, 4-phenanthridinyl, 6-phenanthridinyl, 7-phenanthridinyl, 8-phenanthridinyl, 9-phenanthridinyl, 10-phenanthridinyl, 1-acridinyl, 2-acridinyl, 3-acridinyl, 4-acridinyl, 9-acridinyl, 2-oxazolyl, 4-oxazolyl, 5-oxazolyl, 2-oxadiazolyl, 5-oxadiazolyl, 3-furazanyl, 2-thienyl, 3-thienyl, 2-methylpyrrol-1-yl, 2-methylpyrrol-3-yl, 2-methylpyrrol-4-yl, 2-methylpyrrol-5-yl, 3-methylpyrrol-1-yl, 3-methylpyrrol-2-yl, 3-methylpyrrol-4-yl, 3-methylpyrrol-5-yl, 2-t-butylpyrrol-4-yl, 3-(2-phenylpropyl)pyrrol-1-yl, 2-methyl-1-indolyl, 4-methyl-1-indolyl, 2-methyl-3-indolyl, 4-methyl-3-indolyl, 2-t-butyl-1-indolyl, 4-t-butyl-1-indolyl, 2-t-butyl-3-indolyl, 4-t-butyl-3-indolyl, 1-dibenzofuranyl, 2-dibenzofuranyl, 3-dibenzofuranyl, 4-dibenzofuranyl, 1-dibenzothiophenyl, 2-dibenzothiophenyl, 3-dibenzothiophenyl, 4-dibenzothiophenyl, 1-naphtho-[1,2-b]-benzofuranyl, 2-naphtho-[1,2-b]-benzofuranyl, 3-naphtho-[1,2-b]-benzofuranyl, 4-naphtho-[1,2-b]-benzofuranyl, 5-naphtho-[1,2-b]-benzofuranyl, 6-naphtho-[1,2-b]-benzofuranyl, 7-naphtho-[1,2-b]-benzofuranyl, 8-naphtho-[1,2-b]-benzofuranyl, 9-naphtho-[1,2-b]-benzofuranyl, 10-naphtho-[1,2-b]-benzofuranyl, 1-naphtho-[2,3-b]-benzofuranyl, 2-naphtho-[2,3-b]-benzofuranyl, 3-naphtho-[2,3-b]-benzofuranyl, 4-naphtho-[2,3-b]-benzofuranyl, 5-naphtho-[2,3-b]-benzofuranyl, 6-naphtho-[2,3-b]-benzofuranyl, 7-naphtho-[2,3-b]-benzofuranyl, 8-naphtho-[2,3-b]-benzofuranyl, 9-naphtho-[2,3-b]-benzofuranyl, 10-naphtho-[2,3-b]-benzofuranyl, 1-naphtho-[2,1-b]-benzofuranyl, 2-naphtho-[2,1-b]-benzofuranyl, 3-naphtho-[2,1-b]-benzofuranyl, 4-naphtho-[2,1-b]-benzofuranyl, 5-naphtho-[2,1-b]-benzofuranyl, 6-naphtho-[2,1-b]-benzofuranyl, 7-naphtho-[2,1-b]-benzofuranyl, 8-naphtho-[2,1-b]-benzofuranyl, 9-naphtho-[2,1-b]-benzofuranyl, 10-naphtho-[2,1-b]-benzofuranyl, 1-naphtho-[1,2-b]-benzothiophenyl, 2-naphtho-[1,2-b]-benzothiophenyl, 3-naphtho-[1,2-b]-benzothiophenyl, 4-naphtho-[1,2-b]-benzothiophenyl, 5-naphtho-[1,2-b]-benzothiophenyl, 6-naphtho-[1,2-b]-benzothiophenyl, 7-naphtho-[1,2-b]-benzothiophenyl, 8-naphtho-[1,2-b]-benzothiophenyl, 9-naphtho-[1,2-b]-benzothiophenyl, 10-naphtho-[1,2-b]-benzothiophenyl, 1-naphtho-[2,3-b]-benzothiophenyl, 2-naphtho-[2,3-b]-benzothiophenyl, 3-naphtho-[2,3-b]-benzothiophenyl, 4-naphtho-[2,3-b]-benzothiophenyl, 5-naphtho-[2,3-b]-benzothiophenyl, 1-naphtho-[2,1-b]-benzothiophenyl, 2-naphtho-[2,1-b]-benzothiophenyl, 3-naphtho-[2,1-b]-benzothiophenyl, 4-naphtho-[2,1-b]-benzothiophenyl, 5-naphtho-[2,1-b]-benzothiophenyl, 6-naphtho-[2,1-b]-benzothiophenyl, 7-naphtho-[2,1-b]-benzothiophenyl, 8-naphtho-[2,1-b]-benzothiophenyl, 9-naphtho-[2,1-b]-benzothiophenyl, 10-naphtho-[2,1-b]-benzothiophenyl, 2-benzofuro[3,2-d]pyrimidinyl, 6-benzofuro[3,2-d]pyrimidinyl, 7-benzofuro[3,2-d]pyrimidinyl, 8-benzofuro[3,2-d]pyrimidinyl, 9-benzofuro[3,2-d]pyrimidinyl, 2-benzothio[3,2-d]pyrimidinyl, 6-benzothio[3,2-d]pyrimidinyl, 7-benzothio[3,2-d]pyrimidinyl, 8-benzothio[3,2-d]pyrimidinyl, 9-benzothio[3,2-d]pyrimidinyl, 2-benzofuro[3,2-d]pyrazinyl, 6-benzofuro[3,2-d]pyrazinyl, 7-benzofuro[3,2-d]pyrazinyl, 8-benzofuro[3,2-d]pyrazinyl, 9-benzofuro[3,2-d]pyrazinyl, 2-benzothio[3,2-d]pyrazinyl, 6-benzothio[3,2-d]pyrazinyl, 7-benzothio[3,2-d]pyrazinyl, 8-benzothio[3,2-d]pyrazinyl, 9-benzothio[3,2-d]pyrazinyl, 1-silafluorenyl, 2-silafluorenyl, 3-silafluorenyl, 4-silafluorenyl, 1-germafluorenyl, 2-germafluorenyl, 3-germafluorenyl, 4-germafluorenyl, 1-dibenzoselenophenyl, 2-dibenzoselenophenyl, 3-dibenzoselenophenyl, 4-dibenzoselenophenyl, etc. Additionally, “heteroaryl(ene)” can be classified as a heteroaryl(ene) with electronic properties (a heteroaryl(ene) having electron transport properties) or a heteroaryl(ene) with hole properties (a heteroaryl(ene) having hole transporting properties). A heteroaryl(ene) with electronic properties is a substituent with relatively abundant electrons in the parent nucleus, and, for example, it may be a substituted or unsubstituted pyridinyl, a substituted or unsubstituted pyrimidinyl, a substituted or unsubstituted triazinyl, a substituted or unsubstituted quinazolinyl, a substituted or unsubstituted quinoxalinyl, a substituted or unsubstituted quinolyl, etc. A heteroaryl(ene), which has hole properties, is a substituent with a relative lack of electrons in the parent nucleus, and, for example, it may be a substituted or unsubstituted carbazolyl, a substituted or unsubstituted dibenzofuranyl, or a substituted or unsubstituted dibenzothiophenyl. Herein, “a fused ring of a (C₃-C₃₀)aliphatic ring and a (C₆-C₃₀)aromatic ring” means a ring formed by fusing at least one aliphatic ring having 3 to 30 ring backbone carbon atoms in which the number of carbon atoms is preferably 3 to 25, more preferably 3 to 18, and at least one aromatic ring having 6 to 30 ring backbone carbon atoms in which the number of carbon atoms is preferably 6 to 25, more preferably 6 to 18. For example, the fused ring may be a fused ring of at least one benzene and at least one cyclohexane, or a fused ring of at least one naphthalene and at least one cyclopentane, etc. Herein, the carbon atoms in the fused ring of a (C₃-C₃₀)aliphatic ring and a (C₆-C₃₀)aromatic ring may be replaced with at least one heteroatom selected from B, N, O, S, Si, and P, preferably at least one heteroatom selected from N, O, and S. The “halogen” in the present disclosure includes F, Cl, Br, and I.

In addition, “ortho-” (“o-”), “meta-” (“m-”), and “para-” (“p-”) are meant to signify the substitution position of all substituents. An ortho-configuration describes a compound with substituents which are adjacent to each other, e.g., at the 1 and 2 positions on benzene. A meta-configuration indicates the next substitution position of the immediately adjacent substitution position, e.g., a compound with substituents at the 1 and 3 positions on benzene. A para-configuration indicates the next substitution position from the meta-position, e.g., a compound with substituents at the 1 and 4 positions on benzene.

Herein, “a ring formed in linking to an adjacent substituent” means a substituted or unsubstituted 3- to 30-membered mono- or polycyclic, alicyclic, aromatic ring, or a combination thereof, formed by linking or fusing two or more adjacent substituents, and preferably this may be a substituted or unsubstituted 3- to 26-membered mono- or polycyclic, alicyclic, aromatic ring, or a combination thereof. Further, the ring formed may include at least one heteroatom selected from the group consisting of B, N, O, S, Si, and P, preferably N, O, and S. According to one embodiment of the present disclosure, the number of ring backbone atoms is 5 to 20; according to another embodiment of the present disclosure, the number of ring backbone atoms is 5 to 15. In one embodiment, the fused ring may be, for example, a substituted or unsubstituted dibenzothiophene ring, a substituted or unsubstituted dibenzofuran ring, a substituted or unsubstituted naphthalene ring, a substituted or unsubstituted phenanthrene ring, a substituted or unsubstituted fluorene ring, a substituted or unsubstituted benzothiophene ring, a substituted or unsubstituted benzofuran ring, a substituted or unsubstituted indole ring, a substituted or unsubstituted indene ring, a substituted or unsubstituted benzene ring, or a substituted or unsubstituted carbazole ring, etc.

In addition, the term “substituted” in the expression “substituted or unsubstituted” means that a hydrogen atom in a certain functional group is replaced with another atom or functional group, i.e., a substituent. Unless otherwise specified, the substituents may not be limited to hydrogen at positions where the substituents may be substituted, and when two or more hydrogen atoms are each replaced with a substituent in a functional group, the substituents may be the same as or different from each other. The term also includes that the hydrogen atom is replaced with a group formed by a linkage of two or more substituents of the above substituents. For example, the “group formed by a linkage of two or more substituents” may be pyridine-triazine. That is, pyridine-triazine may be heteroaryl or may be interpreted as one substituent in which two heteroaryls are connected. Preferably, the substituted alkyl, the substituted cycloalkyl(ene), the substituted aryl(ene), the substituted heteroaryl(ene), the substituted alkoxy, the substituted trialkylsilyl, the substituted dialkylarylsilyl, the substituted alkyldiarylsilyl, the substituted triarylsilyl, the substituted aliphatic hydrocarbon group, and the substituted fused ring of aliphatic ring and aromatic ring may each independently be substituted with least one selected from the group consisting of: deuterium; halogen; cyano; carboxyl; nitro; hydroxyl; phosphine oxide; (C₁-C₃₀)alkyl; halo(C₁-C₃₀)alkyl; (C₂-C₃₀)alkenyl; (C₂-C₃₀)alkynyl; (C₁-C₃₀)alkoxy; (C₁-C₃₀)alkylthio; (C₃-C₃₀)cycloalkyl; (C₃-C₃₀)cycloalkenyl; (3- to 7-membered)heterocycloalkyl; (C₆-C₃₀)aryloxy; (C₆-C₃₀)arylthio; (C₆-C₃₀)aryl unsubstituted or substituted by at least one of (C₁-C₃₀)alkyl, (C₆-C₃₀)aryl and (3- to 30-membered)heteroaryl; (3- to 30-membered)heteroaryl unsubstituted or substituted by at least one (C₆-C₃₀)aryl; tri(C₁-C₃₀)alkylsilyl; tri(C₆-C₃₀)arylsilyl; di(C₁-C₃₀)alkyl(C₆-C₃₀)arylsilyl; (C₁-C₃₀)alkyldi(C₆-C₃₀)arylsilyl; a fused ring of a (C₃-C₃₀)aliphatic ring and a (C₆-C₃₀)aromatic ring; amino; mono- or di(C₁-C₃₀)alkylamino; mono- or di(C₂-C₃₀)alkenylamino; mono- or di(C₆-C₃₀)arylamino unsubstituted or substituted by (C₁-C₃₀)alkyl; mono- or di(3- to 30-membered)heteroarylamino; (C₁-C₃₀)alkyl(C₂-C₃₀)alkenylamino; (C₁-C₃₀)alkyl(C₆-C₃₀)arylamino; (C₁-C₃₀)alkyl(3- to 30-membered)heteroarylamino; (C₂-C₃₀)alkenyl(C₆-C₃₀)arylamino; (C₂-C₃₀)alkenyl(3- to 30-membered)heteroarylamino; (C₆-C₃₀)aryl(3- to 30-membered)heteroarylamino; (C₁-C₃₀)alkylcarbonyl; (C₁-C₃₀)alkoxycarbonyl; (C₆-C₃₀)arylcarbonyl; di(C₆-C₃₀)arylboronyl; di(C₁-C₃₀)alkylboronyl; (C₁-C₃₀)alkyl(C₆-C₃₀)arylboronyl; (C₆-C₃₀)ar(C₁-C₃₀)alkyl; and (C₁-C₃₀)alkyl(C₆-C₃₀)aryl. For example, the substituted alkyl, etc. may each independently be substituted with least one selected from the group consisting of (C₁-C₂₅)alkyl; (C₃-C₂₅)cycloalkyl; (C₆-C₂₅)aryl unsubstituted or substituted by at least one of (C₁-C₃₀)alkyl, (C₆-C₃₀)aryl, and (3- to 30-membered)heteroaryl; (3- to 25-membered)heteroaryl unsubstituted or substituted by at least one (C₆-C₃₀)aryl; and mono- or di(C₆-C₂₅)arylamino unsubstituted or substituted by (C₆-C₃₀)aryl.

When a substituent is not shown in the chemical formula or the compound structure of the present disclosure, it may signify that all positions that may be present as substituents are hydrogen or deuterium. That is, in the case of deuterium, an isotope of hydrogen, some of the hydrogen atoms may be deuterium, which is an isotope, and in this case, the content of deuterium may be 0% to 100%. In the case where a substituent is not shown in the chemical formula or the compound structure of the present disclosure, when deuterium is not explicitly excluded, hydrogen and deuterium may be mixed and used in the compound, such as when the content of deuterium is 0%, the content of hydrogen is 100%, and all substituents are hydrogen. The deuterium is an element having a deuteron composed of one proton and one neutron as an atomic nucleus, which is one of the isotopes of hydrogen, and may be represented by hydrogen-2, and the element symbol may be D or ²H. The isotope having the same atomic number (Z) and a different mass number (A) may also be interpreted as an element having the same number of protons and a different number of neutrons.

Herein, “combinations thereof” signifies that one or more components of the corresponding list are combined to form a known or chemically stable arrangement that a person skilled in the art would be able to conceive of from the corresponding list. For example, alkyl and deuterium may be combined to form partially or entirely deuterated alkyl groups; halogen and alkyl may be combined to form halogenated alkyl substituents; and halogen, alkyl, and aryl may be combined to form halogenated arylalkyl. For example, preferred combinations of substituents may include up to 50 atoms excluding hydrogen and deuterium, or include up to 40 atoms excluding hydrogen and deuterium, or include up to 30 atoms excluding hydrogen and deuterium, or in many cases, preferred combinations of substituents may include up to 20 atoms excluding hydrogen and deuterium.

In the formulas of the present disclosure, when multiple substituents are indicated by the same symbol, each of these substituents represented by the same symbol may be the same as or different from one another.

Hereinafter, the organic electroluminescent device according to one embodiment will be described in detail.

The organic electroluminescent device according to one embodiment of the present disclosure comprises a first electrode; a second electrode; and a light-emitting layer positioned between the first electrode and the second electrode, wherein the light-emitting layer comprises a host and a dopant; wherein the host comprises a compound represented by the following Formula 1, and wherein the dopant comprises a compound containing a boron (B) atom.

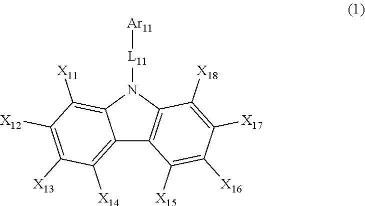

In Formula 1,
an adjacent pair(s) in X₁₅ to X₁₈ is(are) linked to [symbol] in the following Formula 1-A:

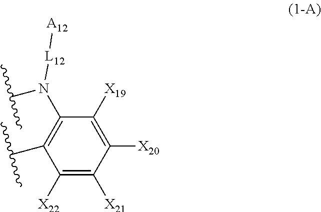

X₁₁ to X₁₄, X₁₅ to X₁₈ that are not linked to form a ring(s), and X₁₉ to X₂₂ each independently represent hydrogen, deuterium, a substituted or unsubstituted (C₆-C₃₀)alkyl, a substituted or unsubstituted (C₆-C₃₀)cycloalkyl, a substituted or unsubstituted (C₆-C₃₀)aryl, a substituted or unsubstituted (3- to 30-membered)heteroaryl, or a combination thereof; L₁₁ and L₁₂ each independently represent a single bond or a substituted or unsubstituted (C₆-C₃₀)arylene; and
Ar₁₁ and Ar₁₂ each independently represent a substituted or unsubstituted (C₆-C₃₀)aryl, a substituted or unsubstituted (3- to 30-membered)heteroaryl having hole-transporting properties, or a combination thereof.

The compound represented by Formula 1 according to one embodiment may be represented by any one of the following Formulas 1-1 to 1-6.

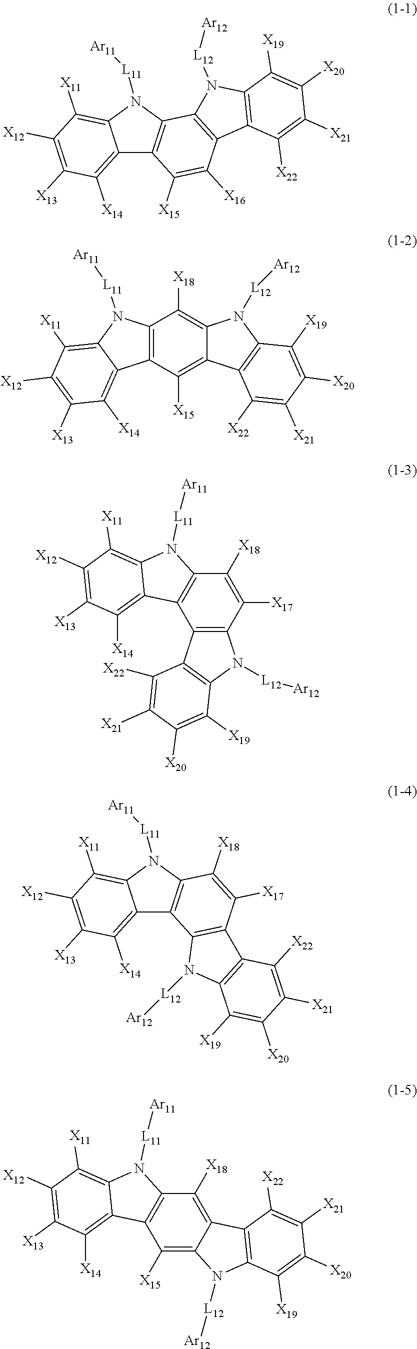

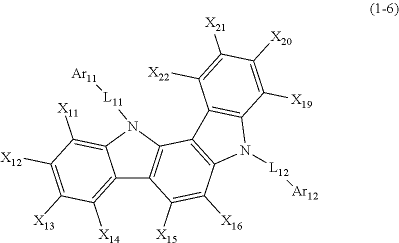

In Formulas 1-1 to 1-6,
Ar₁₁, Ar₁₂, L₁₁, L₁₂, and X₁₁ to X₂₂ are as defined in Formula 1.

In one embodiment, L₁₁ and L₁₂ may each independently be a single bond or a substituted or unsubstituted (C₆-C₃₀)arylene, preferably a single bond or a substituted or unsubstituted (C₆-C₂₅)arylene, and more preferably a single bond or a substituted or unsubstituted (C₆-C₁₈)arylene. For example, L₁₁ and L₁₂ may each independently be a single bond, or phenylene unsubstituted or substituted with phenyl, a substituted or unsubstituted naphthylene, or a substituted or unsubstituted biphenylene.

In one embodiment, Ar₁₁ and Ar₁₂ may be a substituted or unsubstituted carbazolyl, a substituted or unsubstituted dibenzofuranyl, or a substituted or unsubstituted dibenzothiophenyl, for example, carbazolyl unsubstituted or substituted with phenyl, or a substituted or unsubstituted dibenzofuranyl.

In one embodiment, Ar₁₁ and Ar₁₂ may each independently be a substituted or unsubstituted (C₆-C₃₀)aryl, preferably a substituted or unsubstituted (C₆-C₂₅)aryl, and more preferably a substituted or unsubstituted (C₆-C₁₈)aryl. For example, Ar₁₁ and Ar₁₂ may each independently be a substituted or unsubstituted phenyl, a substituted or unsubstituted naphthyl, a substituted or unsubstituted p-biphenyl, a substituted or unsubstituted m-biphenyl, a substituted or unsubstituted o-biphenyl, a substituted or unsubstituted p-terphenyl, a substituted or unsubstituted m-terphenyl, or a substituted or unsubstituted o-terphenyl.

The compound of Formula 1 according to one embodiment may be substituted with at least one deuterium.

In one embodiment, at least one of X₁₁ to X₂₂ may be deuterium.

In one embodiment, at least one of X₁₁ and X₁₉ may be deuterium; for example, all of X₁₁ and X₁₉ may be deuterium

According to one embodiment, the compound represented by Formula 1 may be more specifically illustrated by the following compounds, but is not limited thereto:

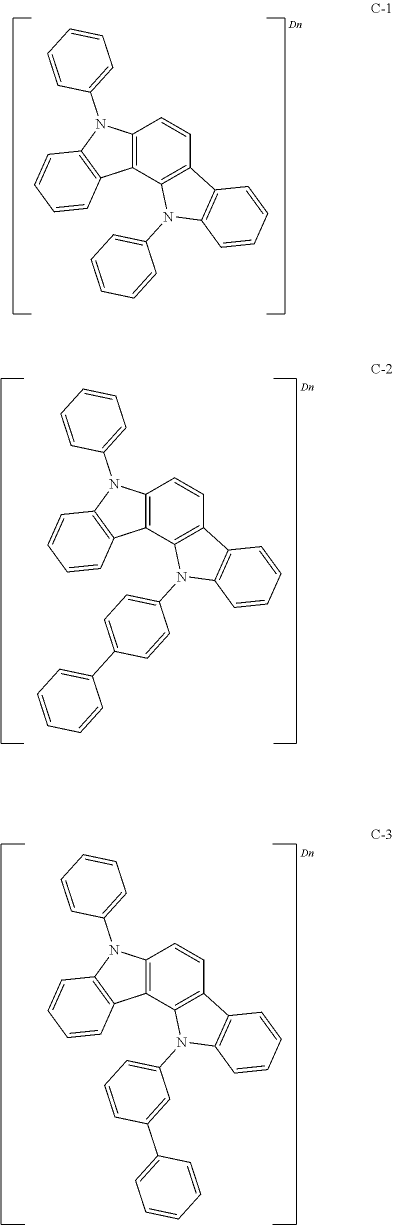

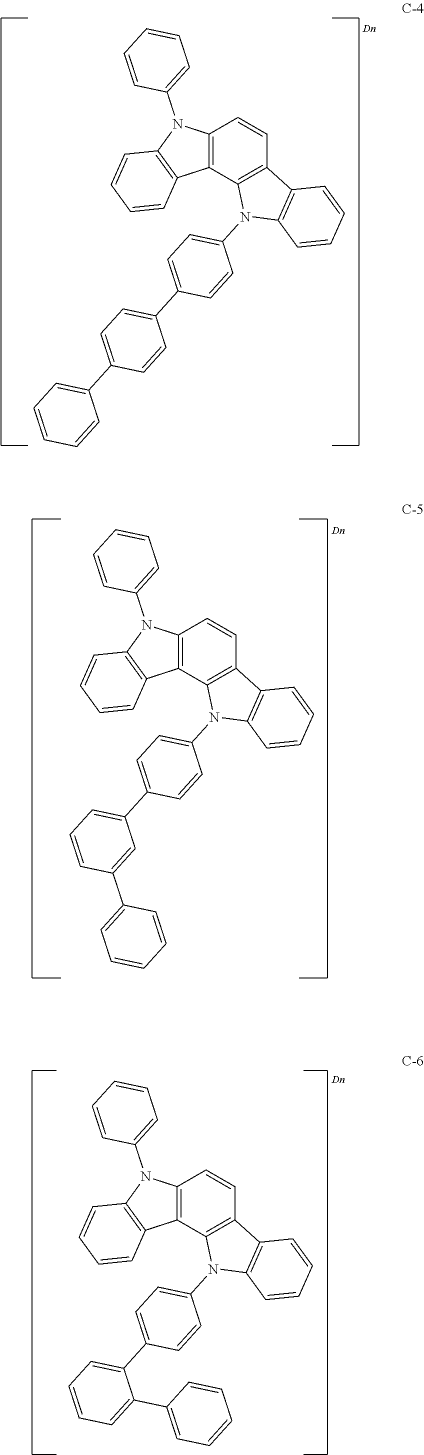

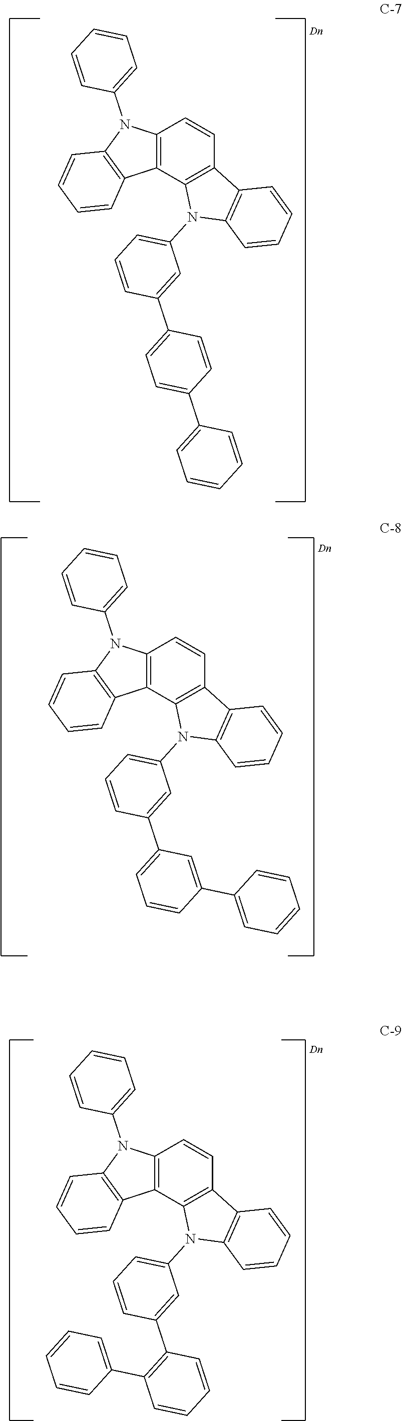

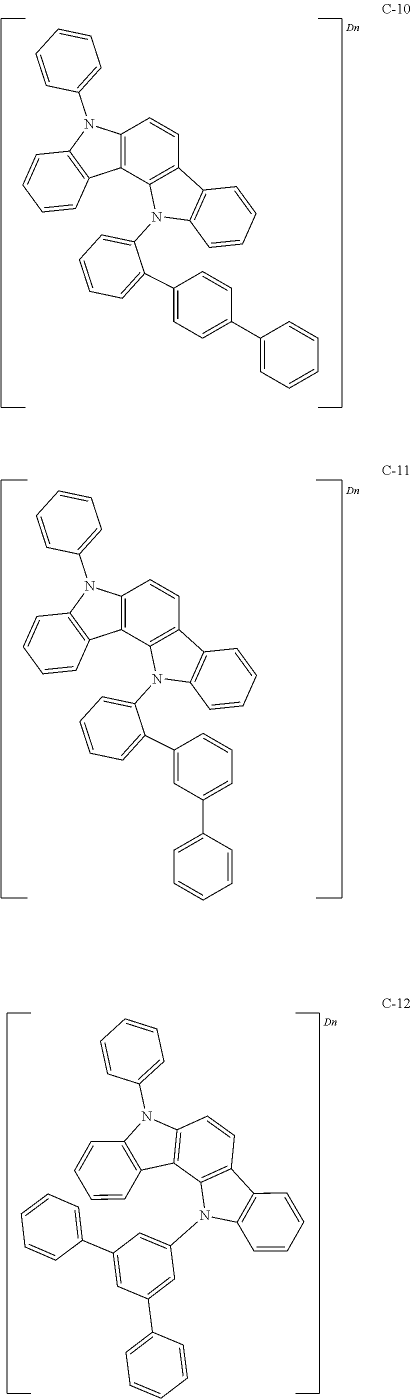

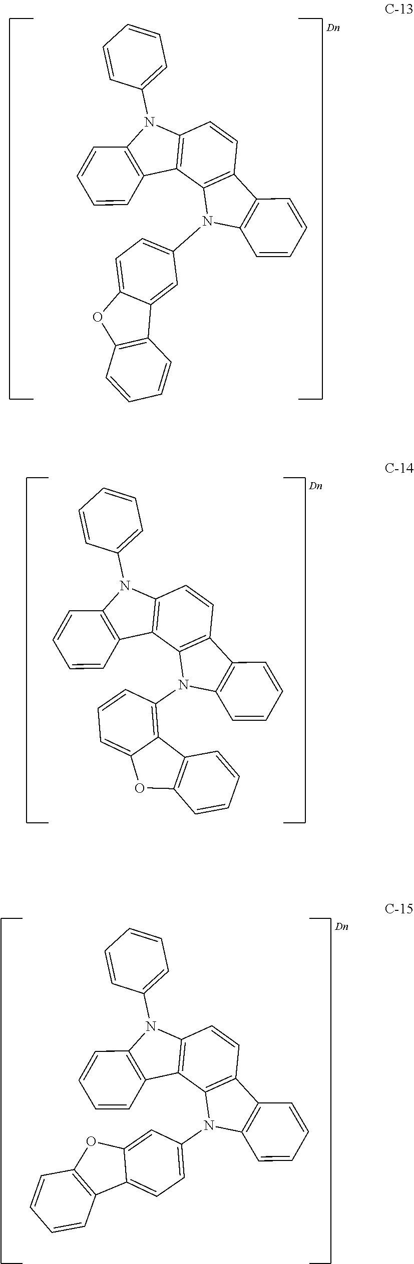

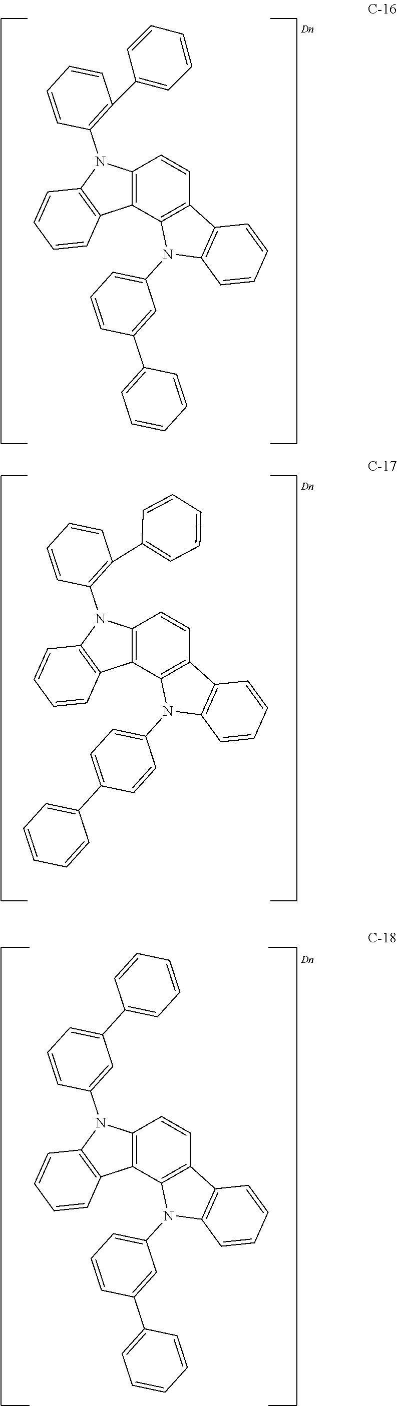

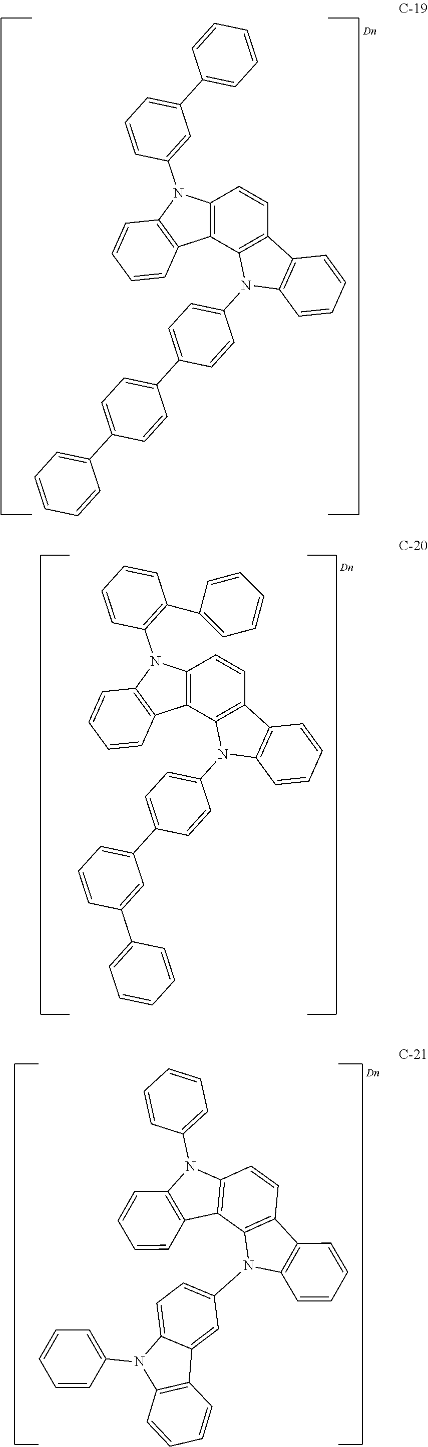

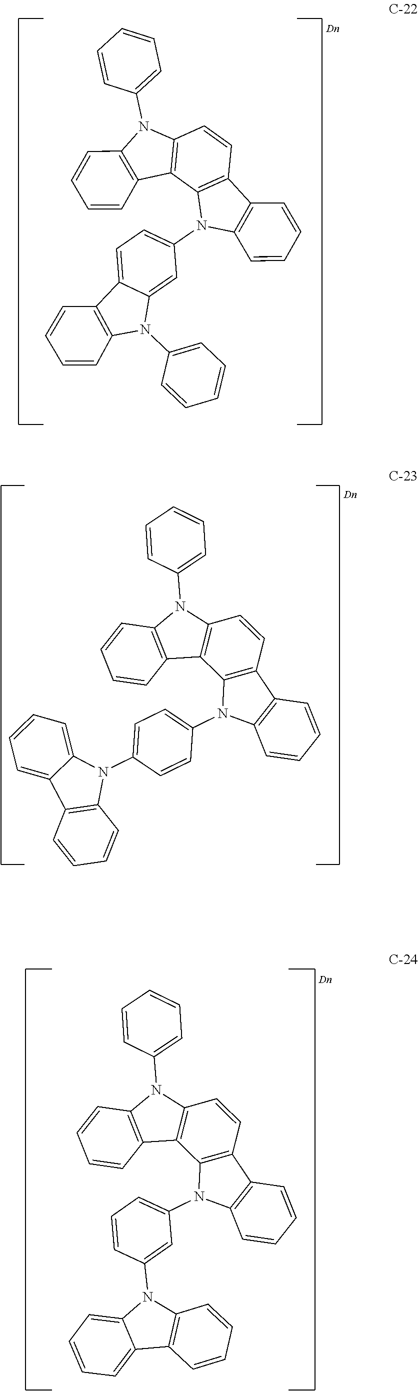

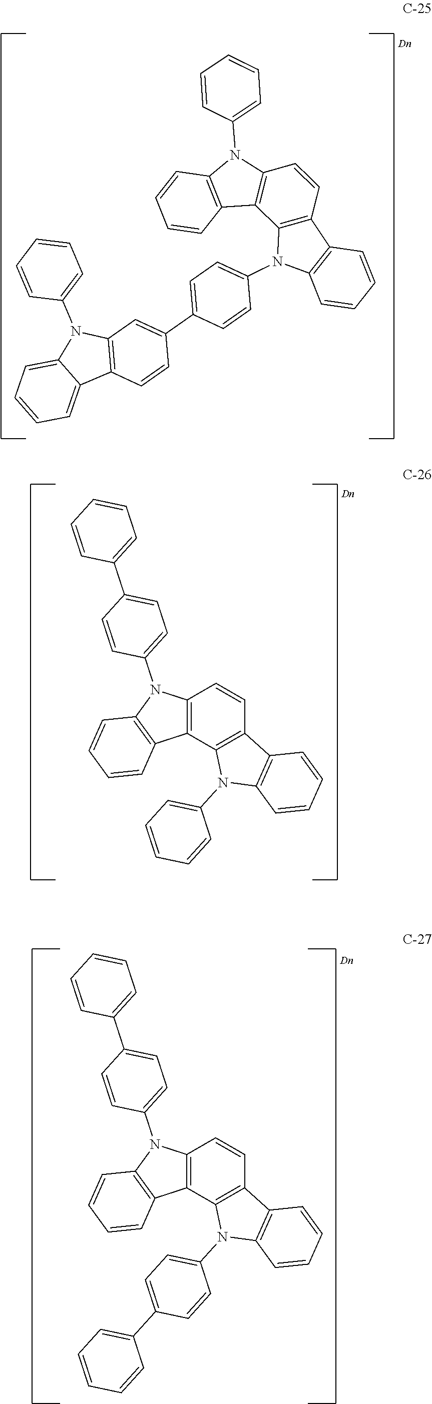

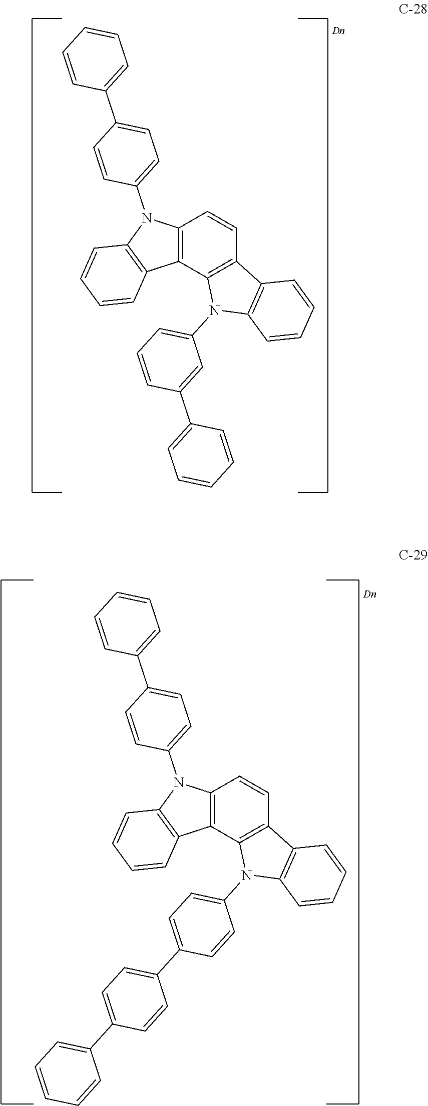

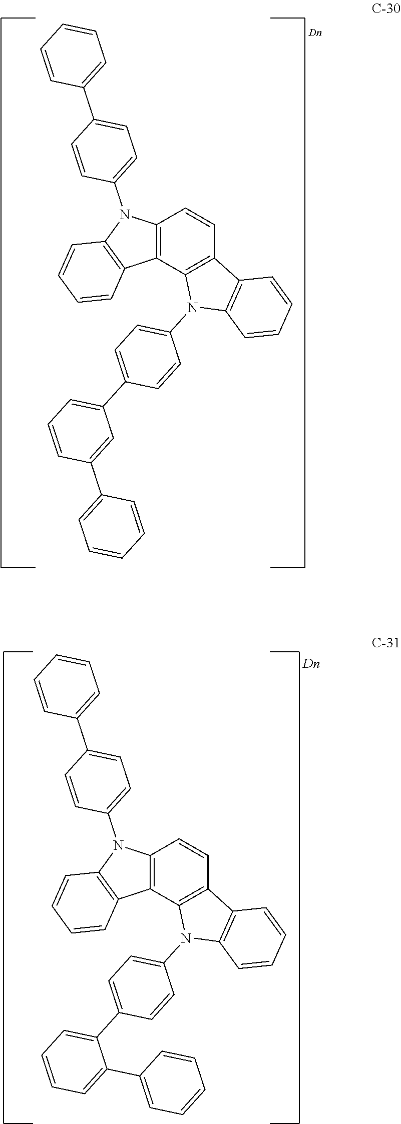

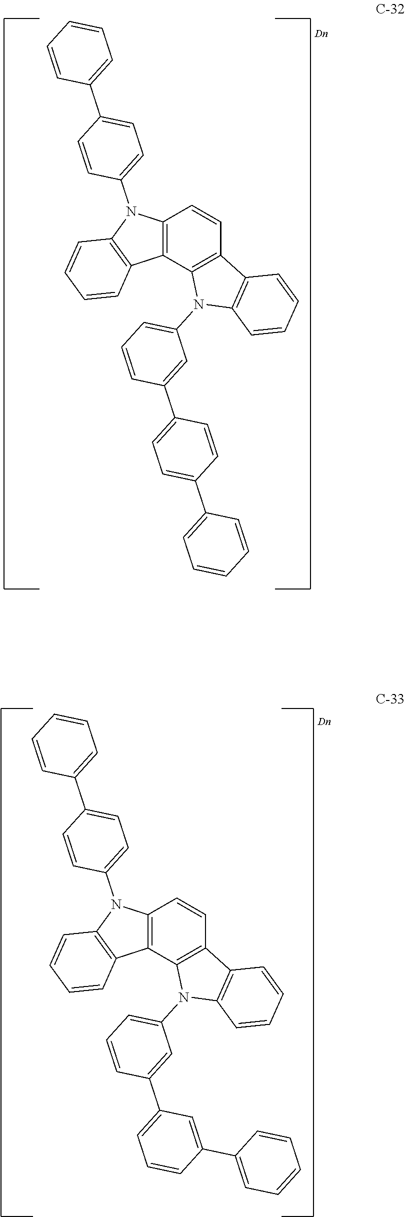

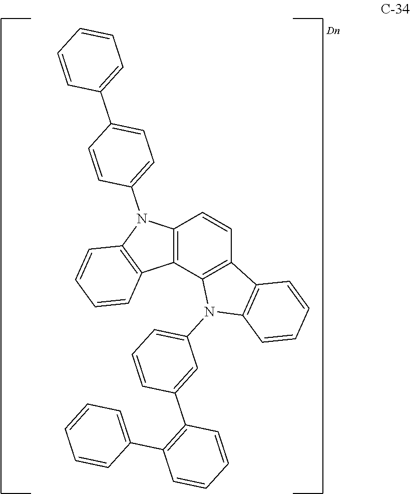

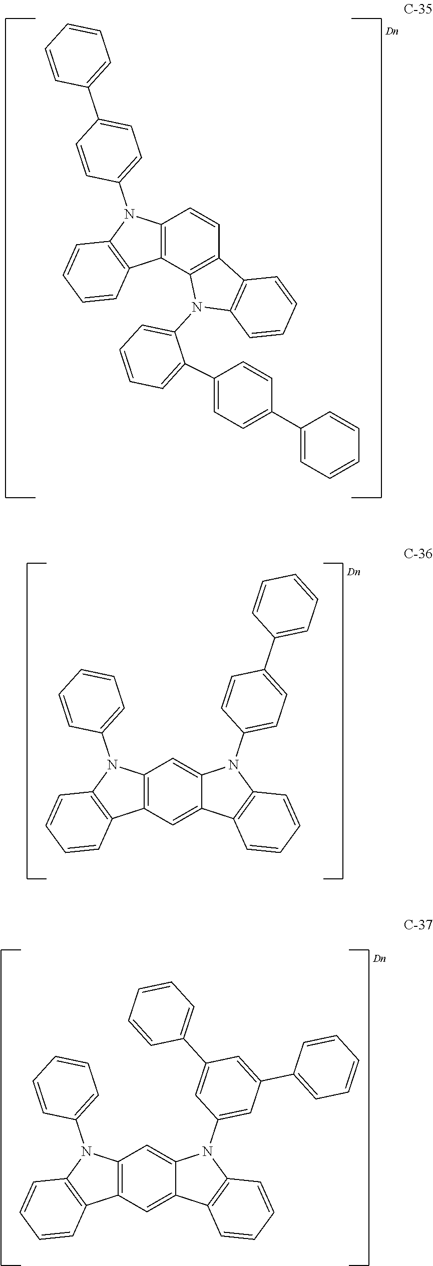

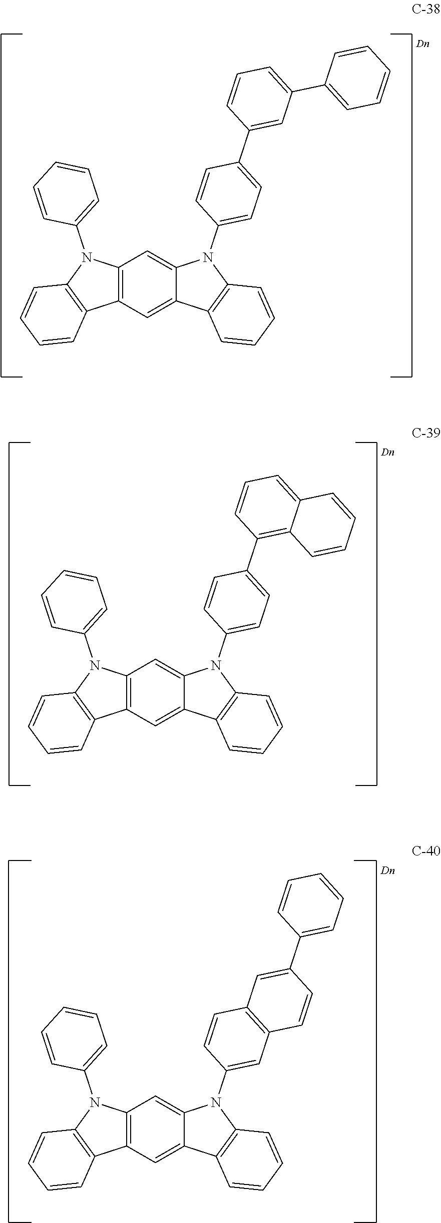

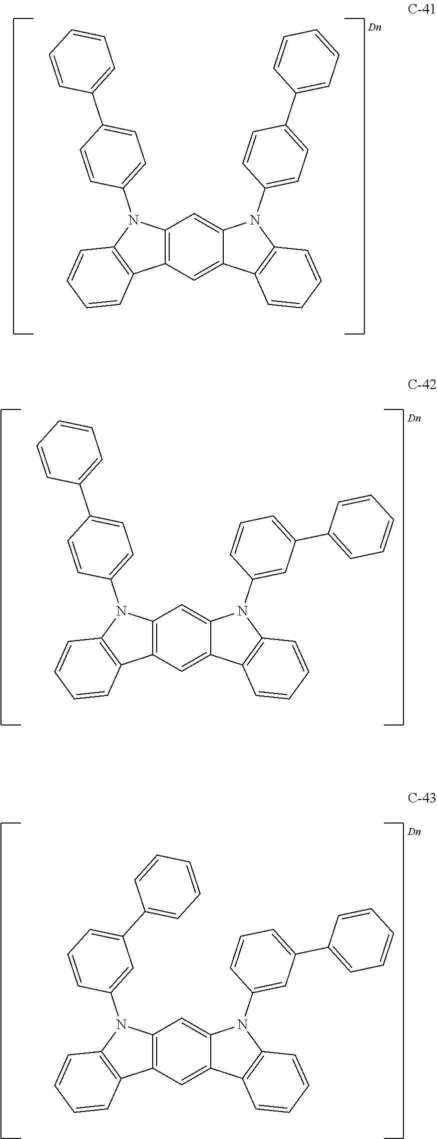

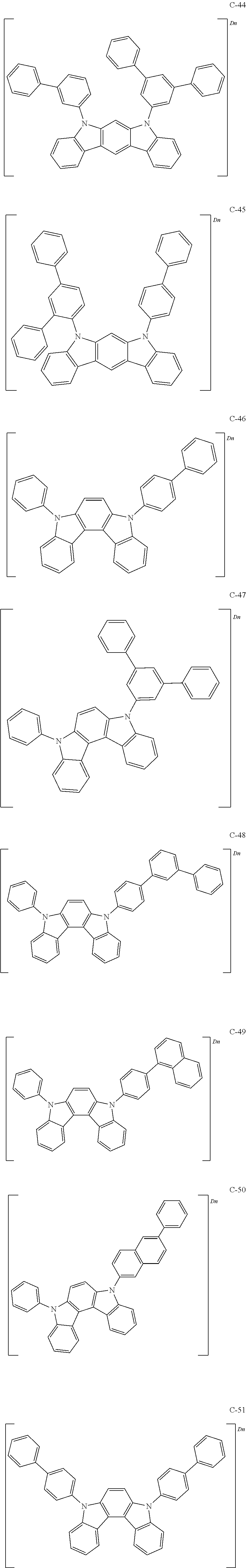

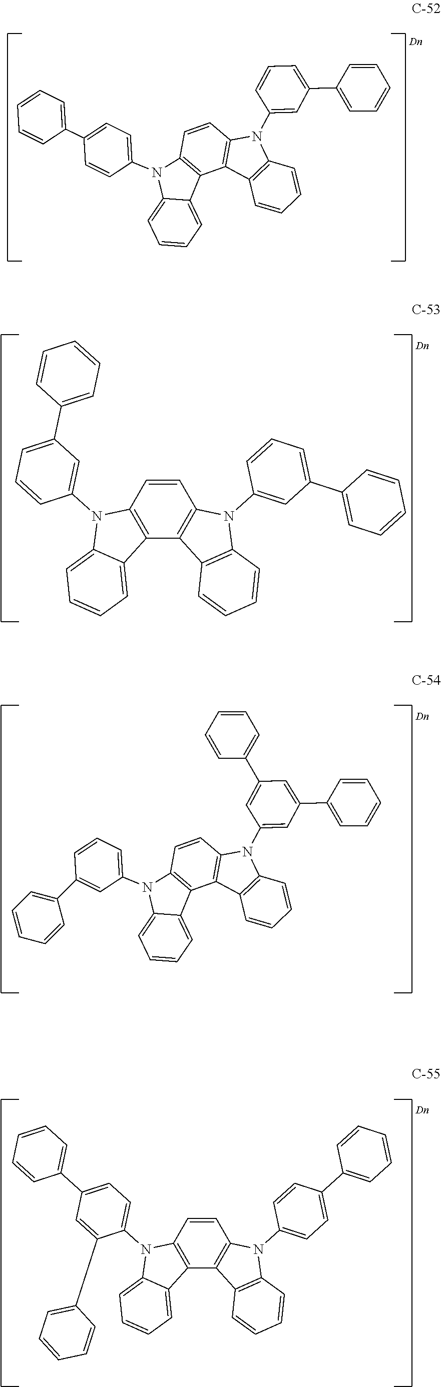

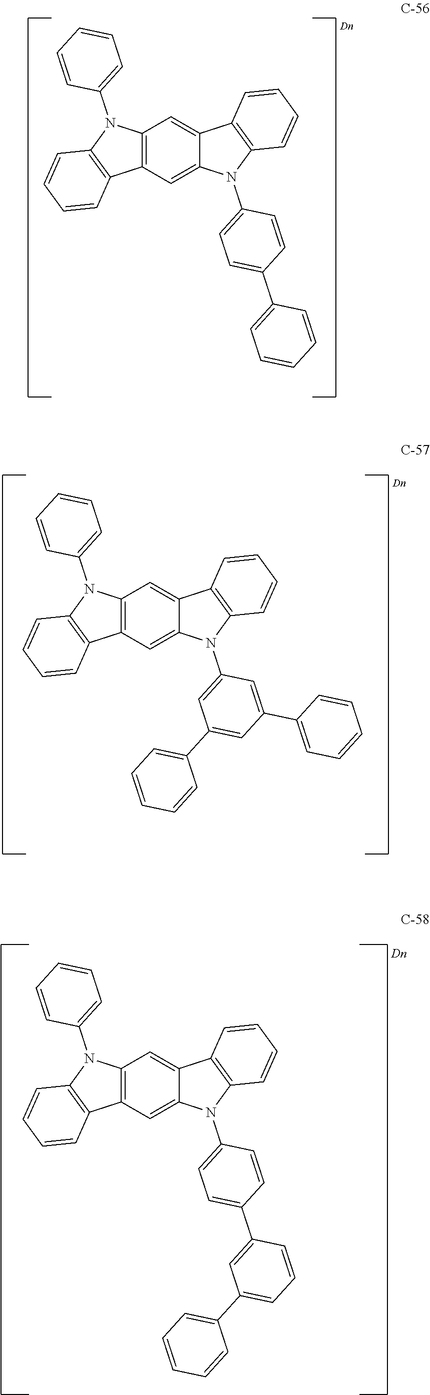

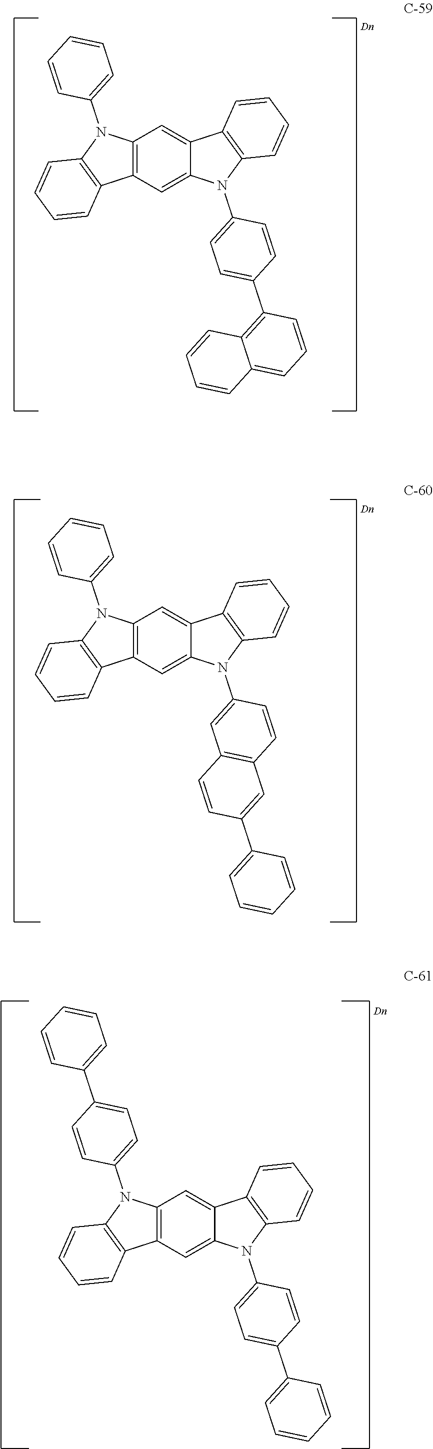

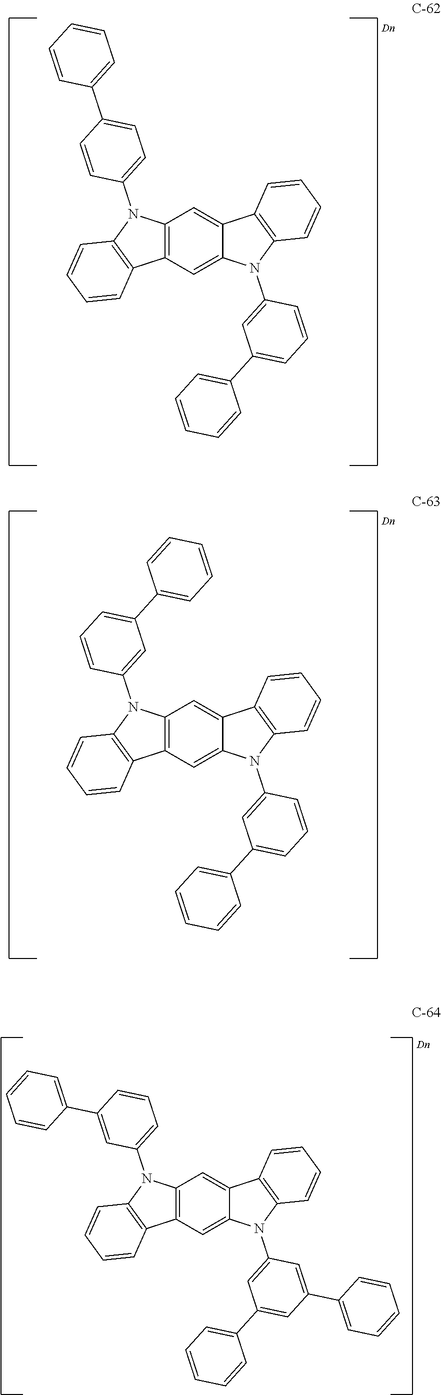

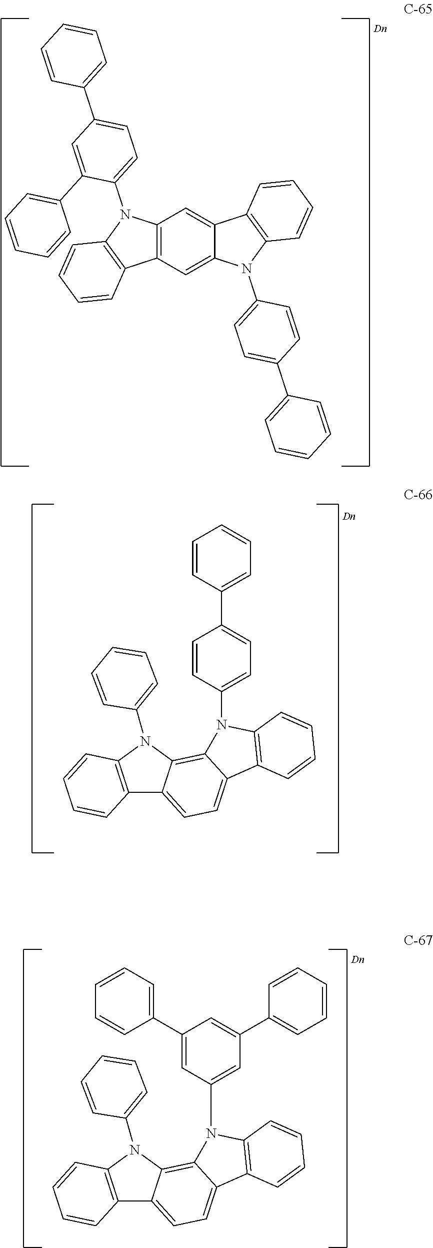

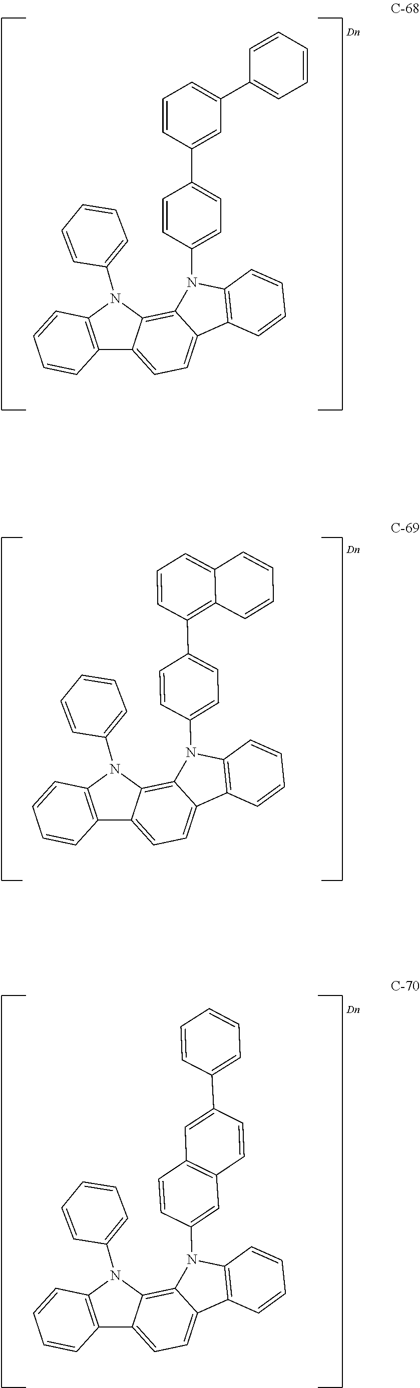

In the compounds, Dₙ means that n hydrogens are replaced by deuterium, and n is an integer from 0 to 1 or more, which sets an upper limit on the number of hydrogen atoms in the non-deuterated compound.

A compound comprising a boron (B) atom as a dopant according to one embodiment is represented by the following Formula 11:

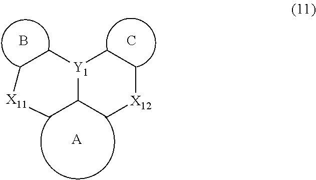

In Formula 11,
ring A, ring B, and ring C each independently represent a substituted or unsubstituted (C₆-C₃₀)aryl or a substituted or unsubstituted (3- to 50-membered)heteroaryl;
X₁₁ and X₁₂ each independently represent NRₐ, O, or S;
Rₐ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L₄-N—(Ar₄)(Ar₅); or may be linked to at least one of ring A, ring B, and ring C to form a ring(s);
L₄ represents a single bond, a substituted or unsubstituted (C₆-C₃₀)arylene, a substituted or unsubstituted (3- to 30-membered)heteroarylene, a substituted or unsubstituted divalent (C₂-C₃₀)aliphatic hydrocarbon group, or a substituted or unsubstituted divalent fused ring of a (C₃-C₃₀)aliphatic ring and a (C₆-C₃₀)aromatic ring; and
Ar₄ and Ar₅ each independently represent a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl.

The compound of Formula 11 according to one embodiment may be represented by the following Formula D-1:

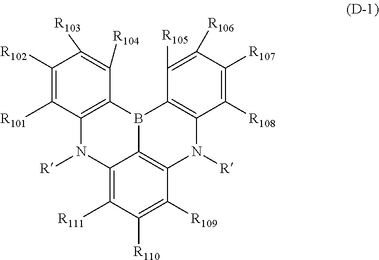

In Formula D-1,
R₁₀₁ to R₁₁₁ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄-N—(Ar′₄)(Ar′₅); or may be linked to an adjacent substituent to form a ring(s);
each R′ independently represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L′₄-N—(Ar′₄)(Ar′₅); or may be connected to one or more of R₁₀₁, R₁₀₈, R₁₀₉, and R₁₁₁ to form a ring(s);
Each L′₄ independently represents a single bond, a substituted or unsubstituted (C₆-C₃₀)arylene, or a substituted or unsubstituted (3- to 30-membered)heteroarylene;
Ar′₄ and Ar′₅ each independently represent hydrogen, a substituted or unsubstituted (C₁-C₃₀)alkyl, substituted or unsubstituted (C₂-C₃₀)alkenyl, a substituted or unsubstituted fused ring of a (C₃-C₃₀)aliphatic ring and a (C₆-C₃₀)aromatic ring, a substituted or unsubstituted (C₆-C₃₀)aryl, or a substituted or unsubstituted (3- to 30-membered)heteroaryl.

Preferably, R₁₀₁ to R₁₁₁ may independently be hydrogen, deuterium, a substituted or unsubstituted (C₁-C₂₀)alkyl, a substituted or unsubstituted (C₆-C₂₅)aryl, a substituted or unsubstituted (5- to 20-membered)heteroaryl, or -L′₄-N—(Ar′₄)(Ar′₅), or may be linked to an adjacent substituent to form a ring(s).

More preferably, R₁₀₁ to R₁₁₁ may independently be hydrogen, deuterium, an unsubstituted (C₁-C₁₀)alkyl; a substituted or unsubstituted (C₆-C₁₈)aryl substituted with one or more of a (C₁-C₁₀)alkyl, a (13- to 18-membered)heteroaryl, and a diarylamino having two (C₆-C₁₈)aryls; a substituted or unsubstituted (5- to 18-membered)heteroaryl substituted with one or more (C₁-C₁₀)alkyls; or -L′₄-N—(Ar′₄)(Ar′₅), or may be linked to an adjacent substituent to form a ring(s). For example, R₁₀₁ to R₁₁₁ may independently be hydrogen, methyl, tert-butyl, a substituted or unsubstituted phenyl, biphenyl, terphenyl, triphenylenyl, carbazolyl, phenoxazinyl, phenothiazinyl, dimethylacridinyl, dimethylxanthenyl, diphenylamino unsubstituted or substituted with one or more of methyl and diphenylamino, phenylnaphthylamino, dibiphenylamino, phenylamino substituted with phenylcarbazolyl or dibenzofuranyl, or a (17- to 21-membered)heteroaryl substituted with one or more of methyl and phenyl; or may be linked to an adjacent substituent to form a benzene ring, an indole ring substituted with one or more of phenyl and diphenylamino, a benzofuran ring, a benzothiophene ring, or a 19-membered heterocycle substituted with one or more methyl(s). The substituent of the substituted phenyl may be one or more selected from methyl, carbazolyl, dibenzofuranyl, diphenylamino, phenoxazinyl, phenothiazinyl, and dimethylacridinyl.

The compound of Formula 11 according to one embodiment may be represented by the following Formula D-2 or D-3:

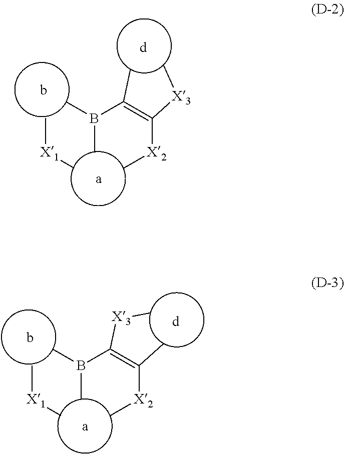

In Formula D-2 and D-3,
X′₁ and X′₂ each independently represent O, S, or NR′;
X′₃ represents O or S;
ring a, ring b, and ring d each independently represent a ring selected from a substituted or unsubstituted aromatic hydrocarbon ring having 6 to 30 carbon atoms or a substituted or unsubstituted aromatic heterocyclic ring having 3 to 50 ring members;
R′ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L₄-N—(Ar₄)(Ar₅); or may be linked to one or more of ring a, ring b, and ring d to form a ring(s);
L₄ represents a single bond, a substituted or unsubstituted (C₆-C₃₀)arylene, a substituted or unsubstituted (3- to 30-membered)heteroarylene, a substituted or unsubstituted divalent (C₂-C₃₀)aliphatic hydrocarbon group, or a substituted or unsubstituted divalent fused ring group of a (C₃-C₃₀)aliphatic ring and a (C₆-C₃₀)aromatic ring;
Ar₄ and Ar₅ each independently represent a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl.

According to one embodiment, the compound represented by Formula 11 may be more specifically illustrated by the following compounds, but is not limited thereto.

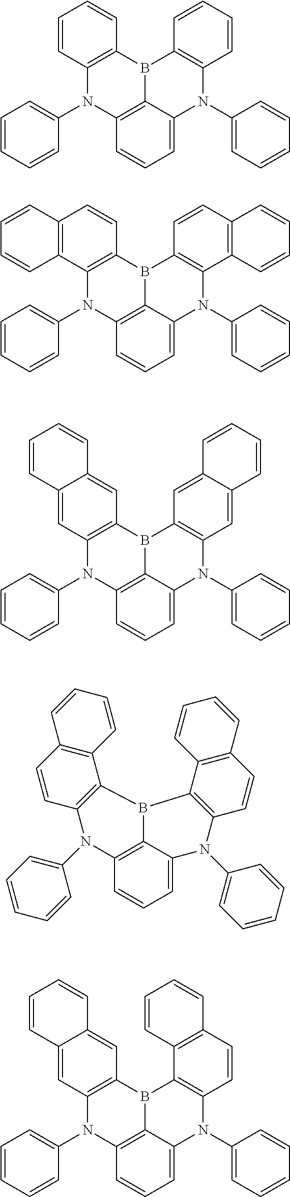

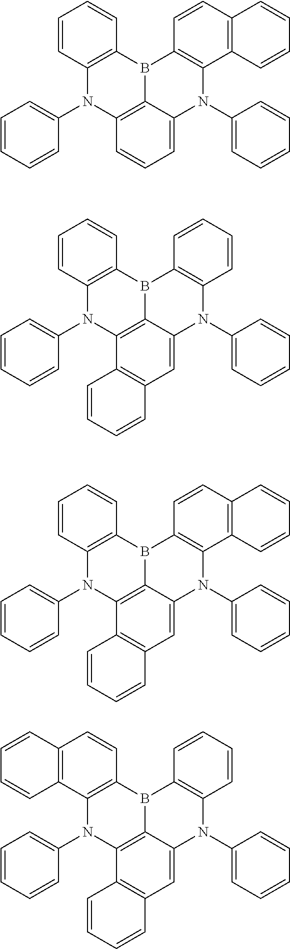

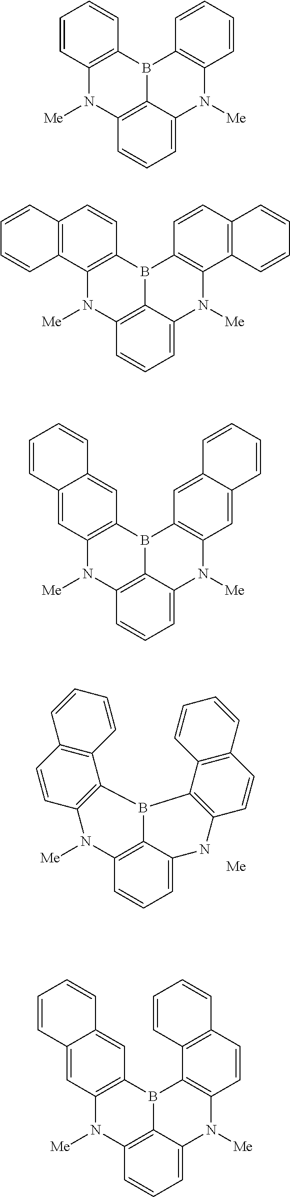 [SMILES: CN1c2ccccc2B2c3ccccc3N(C)c3cccc1c32 ; CN1c2cccc3c2B(c2ccc4ccccc4c21)c1ccc2ccccc2c1N3C ; CN1c2cc3ccccc3cc2B2c3cc4ccccc4cc3N(C)c3cccc1c32 ; CN1c2cccc3c2B(c2c(ccc4ccccc24)N3)c2c1ccc1ccccc21 ; "Me" ; CN1c2cc3ccccc3cc2B2c3c1cccc3N(C)c1ccc3ccccc3c12]

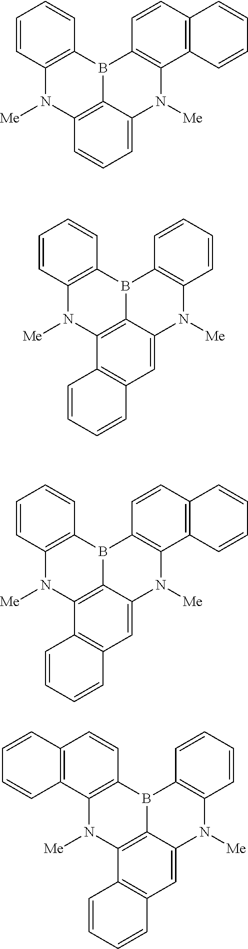

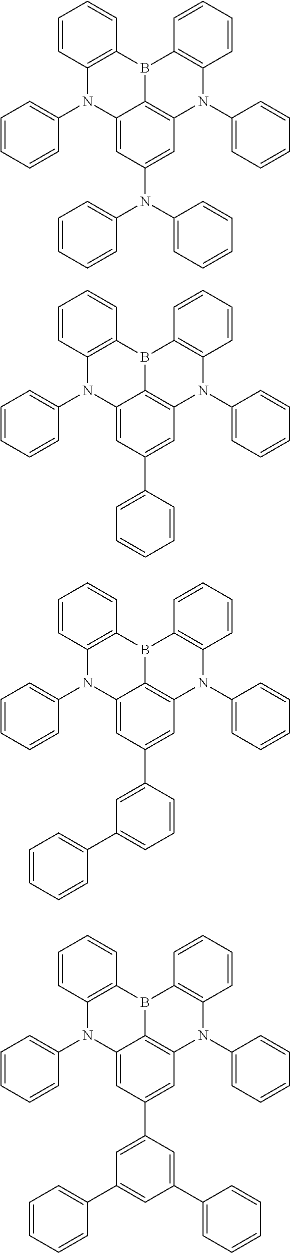

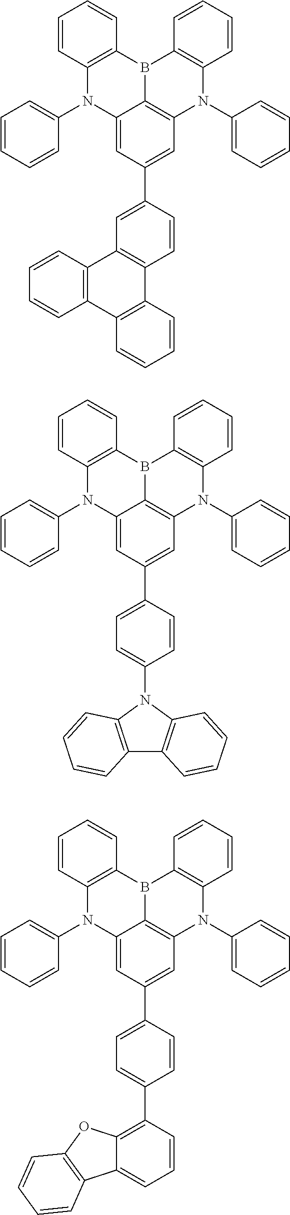 [SMILES: c1ccc(N2c3ccccc3B3c4ccccc4N(c4ccccc4)c4cc(-c5ccc6c7ccccc7c7ccccc7c6c5)cc2c43)cc1 ; c1ccc(N2c3ccccc3B3c4ccccc4N(c4ccccc4)c4cc(-c5ccc(-n6c7ccccc7c7ccccc76)cc5)cc2c43)cc1 ; c1ccc(N2c3ccccc3B3c4ccccc4N(c4ccccc4)c4cc(-c5ccc(-c6cccc7c6oc6ccccc67)cc5)cc2c43)cc1]

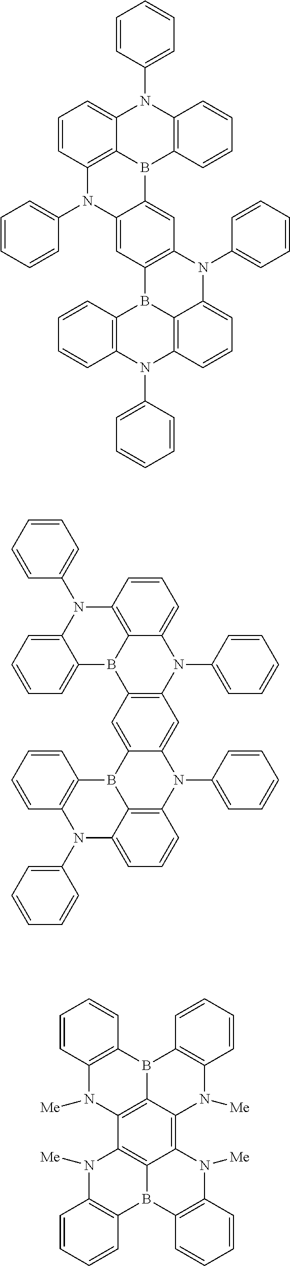 [SMILES: c1ccc(N2c3ccccc3B3c4cc5c(cc4N(c4ccccc4)c4cccc2c43)B2c3ccccc3N(c3ccccc3)c3cccc(c32)N5c2ccccc2)cc1 ; c1ccc(N2c3ccccc3B3c4cc5c(cc4N(c4ccccc4)c4cccc2c43)N(c2ccccc2)c2cccc3c2B5c2ccccc2N3c2ccccc2)cc1 ; CN1c2ccccc2B2c3ccccc3N(C)c3c2c1c1c2c3N(C)c3ccccc3B2c2ccccc2N1C]

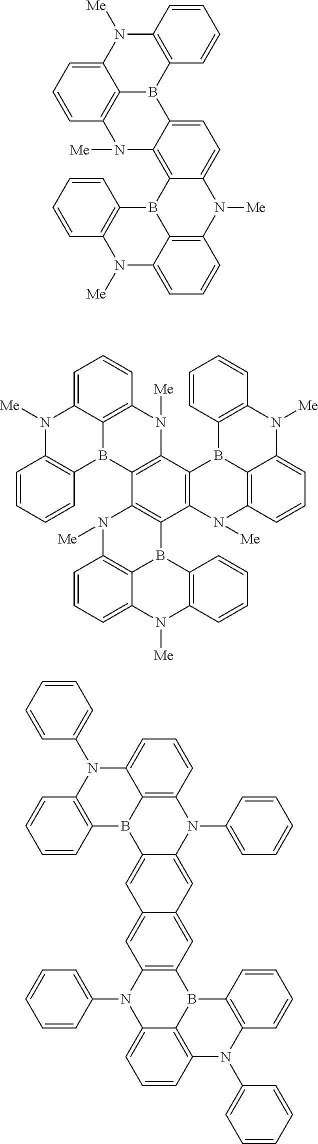 [SMILES: CN1c2ccccc2B2c3c1cccc3N(C)c1ccc3c(c12)N(C)c1cccc2c1B3c1ccccc1N2C ; CN1c2ccccc2B2c3c1cccc3N(C)c1c3c(c4c(c12)N(C)c1cccc2c1B4c1ccccc1N2C)N(C)c1cccc2c1B3c1ccccc1N2C ; c1ccc(N2c3ccccc3B3c4cc5cc6c(cc5cc4N(c4ccccc4)c4cccc2c43)B2c3ccccc3N(c3ccccc3)c3cccc(c32)N6c2ccccc2)cc1]

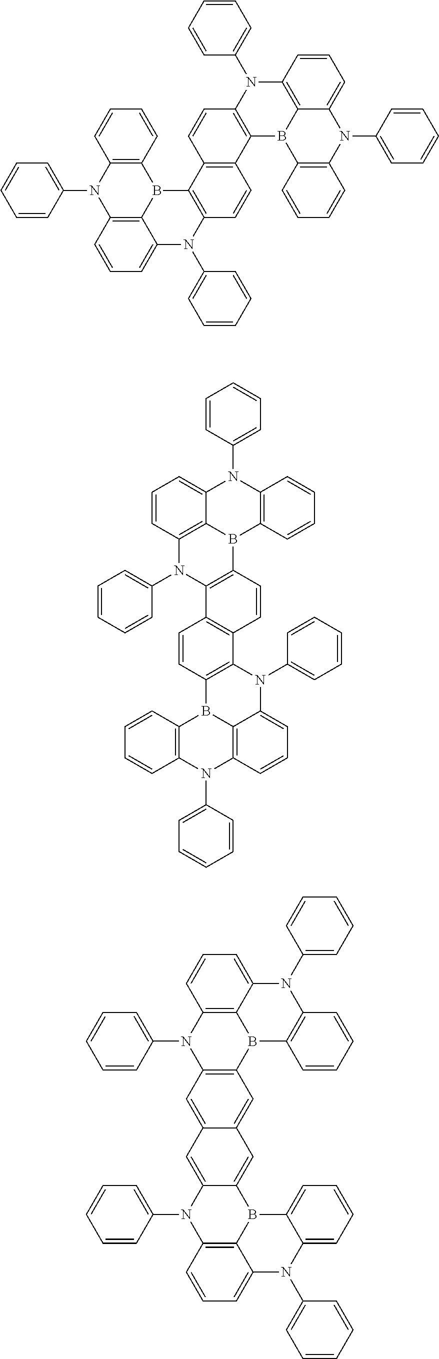 [SMILES: c1ccc(N2c3ccccc3B3c4c2cccc4N(c2ccccc2)c2ccc4c5c(ccc4c23)N(c2ccccc2)c2cccc3c2B5c2ccccc2N3c2ccccc2)cc1 ; c1ccc(N2c3ccccc3B3c4ccc5c6c(ccc5c4N(c4ccccc4)c4cccc2c43)B2c3ccccc3N(c3ccccc3)c3cccc(c32)N6c2ccccc2)cc1 ; c1ccc(N2c3ccccc3B3c4cc5cc6c(cc5cc4N(c4ccccc4)c4cccc2c43)N(c2ccccc2)c2cccc3c2B6c2ccccc2N3c2ccccc2)cc1]

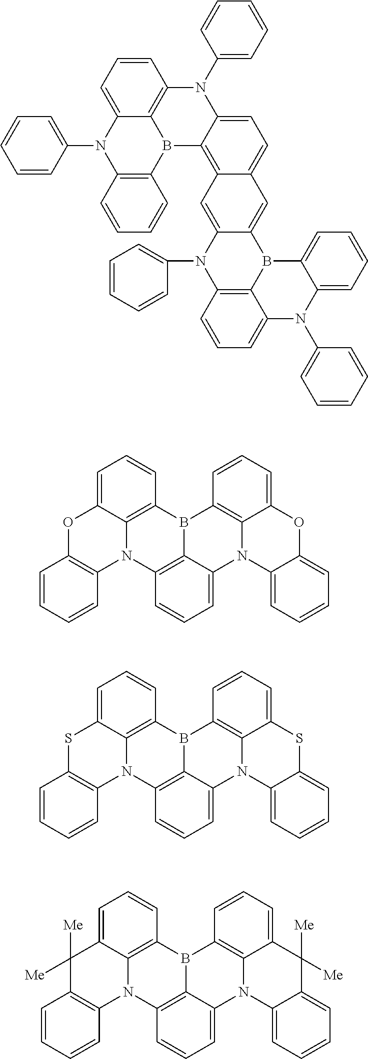 [SMILES: c1ccc(N2c3ccccc3B3c4cc5ccc6c(c5cc4N(c4ccccc4)c4cccc2c43)B2c3ccccc3N(c3ccccc3)c3cccc(c32)N6c2ccccc2)cc1 ; c1ccc2c(c1)Oc1cccc3c1N2c1cccc2c1B3c1cccc3c1N2c1ccccc1O3 ; c1ccc2c(c1)Sc1cccc3c1N2c1cccc2c1B3c1cccc3c1N2c1ccccc1S3 ; CC1(C)c2ccccc2N2c3cccc4c3B(c3cccc1c32)c1cccc2c1N4c1ccccc1C2(C)C]

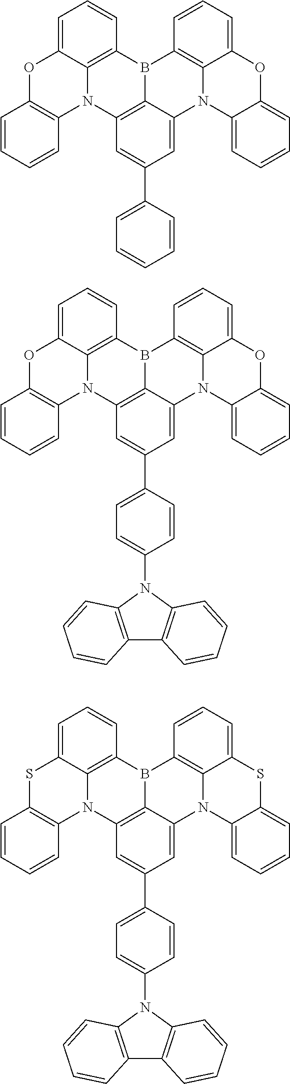

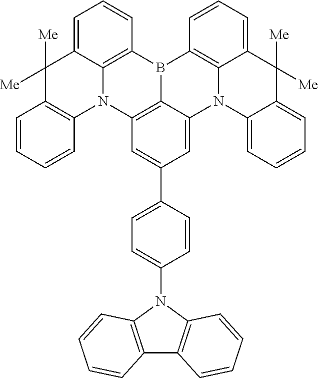 [SMILES: CC1(C)c2ccccc2N2c3cc(-c4ccc(-n5c6ccccc6c6ccccc65)cc4)cc4c3B(c3cccc1c32)c1cccc2c1N4c1ccccc1C2(C)C]

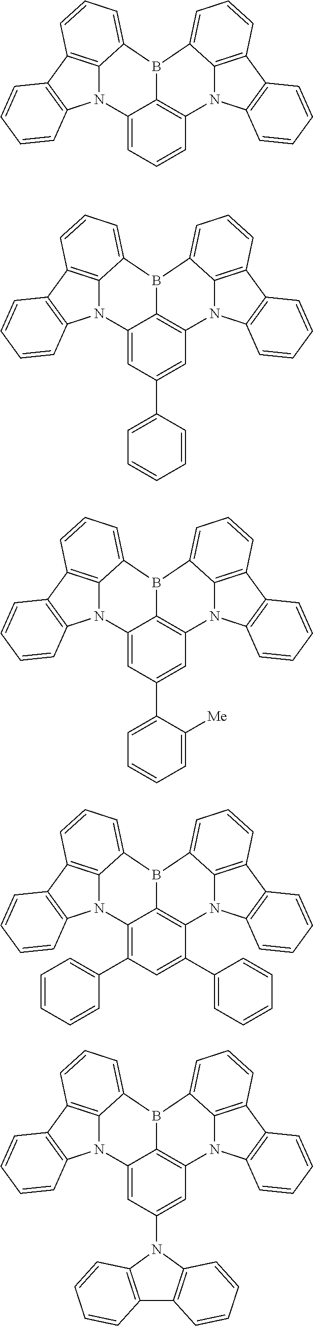

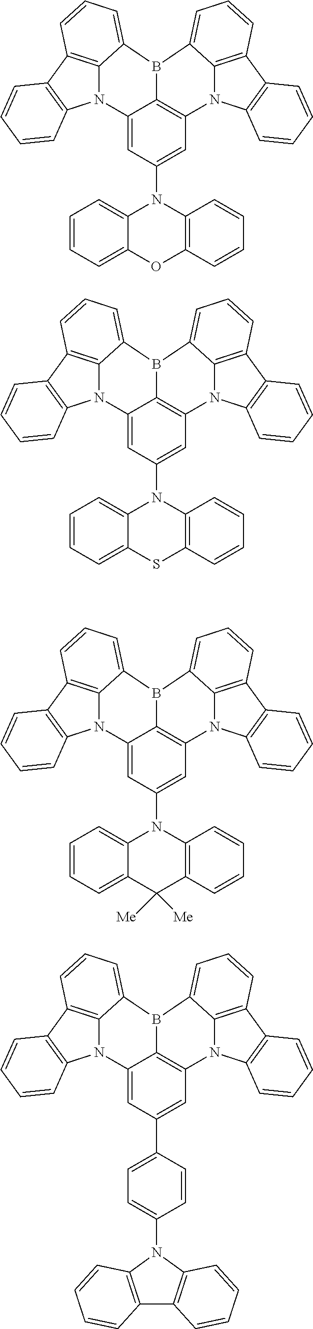

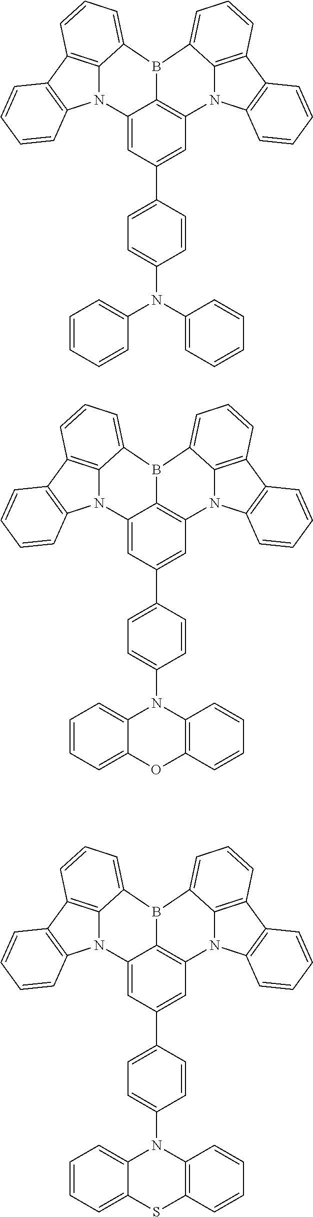

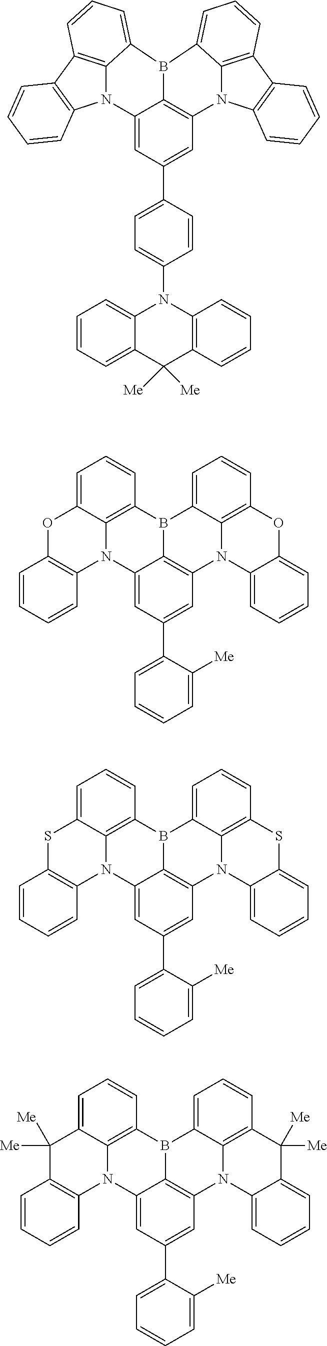 [SMILES: CC1(C)c2ccccc2N(c2ccc(-c3cc4c5c(c3)-n3c6ccccc6c6cccc(c63)B5c3cccc5c6ccccc6n-4c35)cc2)c2ccccc21 ; Cc1ccccc1-c1cc2c3c(c1)N1c4ccccc4Oc4cccc(c41)B3c1cccc3c1N2c1ccccc1O3 ; Cc1ccccc1-c1cc2c3c(c1)N1c4ccccc4Sc4cccc(c41)B3c1cccc3c1N2c1ccccc1S3 ; Cc1ccccc1-c1cc2c3c(c1)N1c4ccccc4C(C)(C)c4cccc(c41)B3c1cccc3c1N2c1ccccc1C3(C)C]

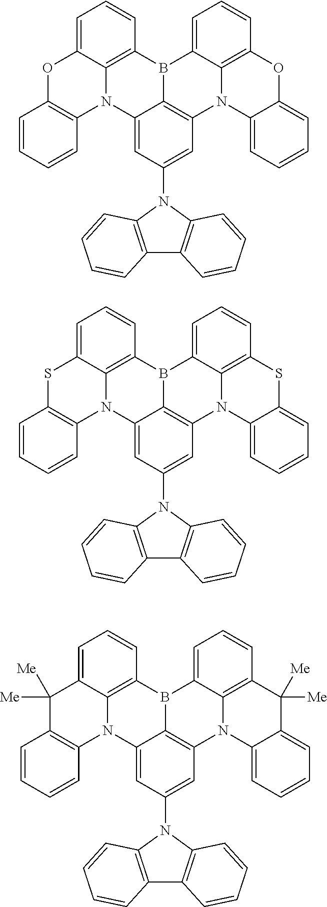

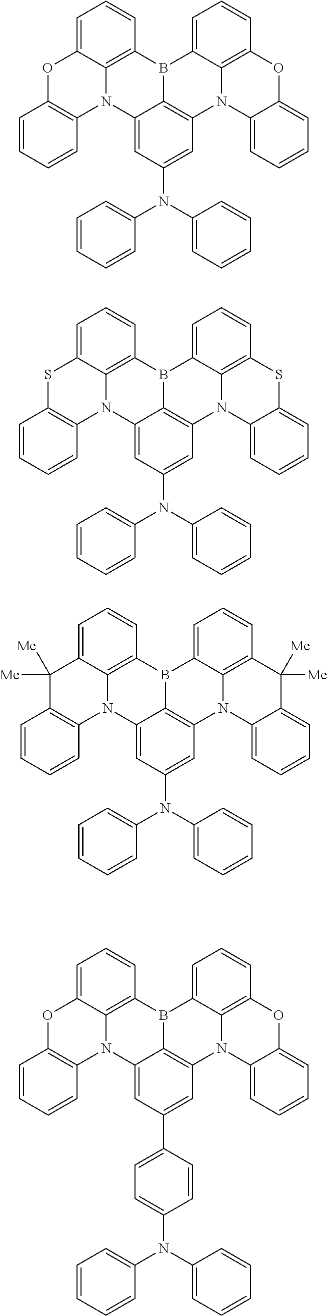

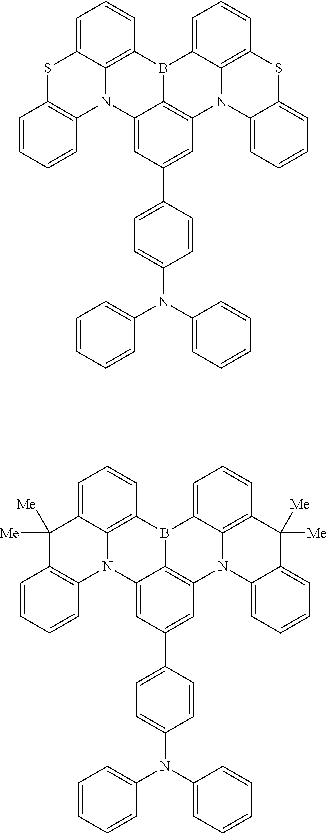 [SMILES: c1ccc(N(c2ccccc2)c2ccc(-c3cc4c5c(c3)N3c6ccccc6Sc6cccc(c63)B5c3cccc5c3N4c3ccccc3S5)cc2)cc1 ; CC1(C)c2ccccc2N2c3cc(-c4ccc(N(c5ccccc5)c5ccccc5)cc4)cc4c3B(c3cccc1c32)c1cccc2c1N4c1ccccc1C2(C)C]

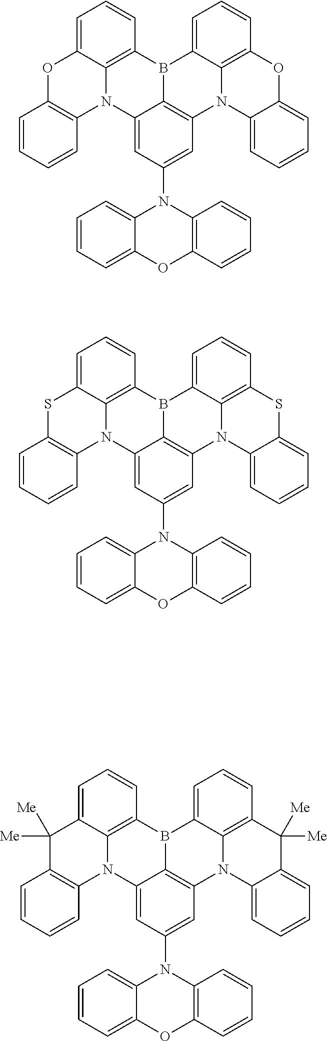 [SMILES: c1ccc2c(c1)Oc1ccccc1N2c1cc2c3c(c1)N1c4ccccc4Oc4cccc(c41)B3c1cccc3c1N2c1ccccc1O3 ; c1ccc2c(c1)Oc1ccccc1N2c1cc2c3c(c1)N1c4ccccc4Sc4cccc(c41)B3c1cccc3c1N2c1ccccc1S3 ; CC1(C)c2ccccc2N2c3cc(N4c5ccccc5Oc5ccccc54)cc4c3B(c3cccc1c32)c1cccc2c1N4c1ccccc1C2(C)C]

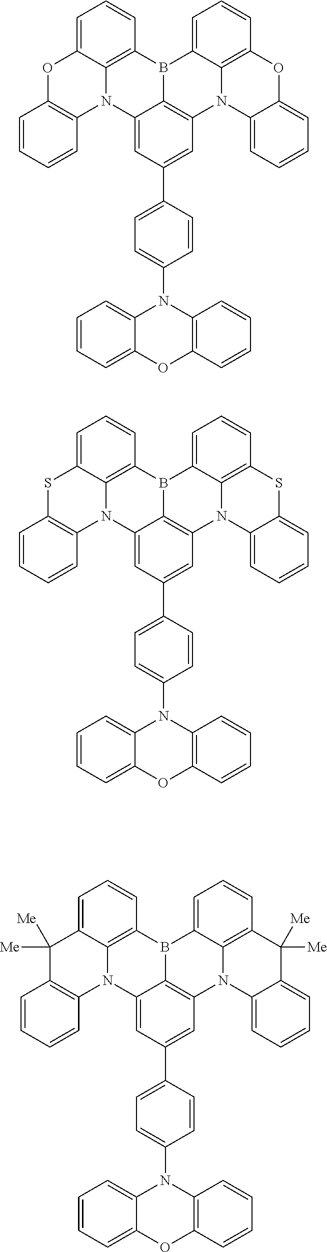 [SMILES: c1ccc2c(c1)Oc1ccccc1N2c1ccc(-c2cc3c4c(c2)N2c5ccccc5Oc5cccc(c52)B4c2cccc4c2N3c2ccccc2O4)cc1 ; c1ccc2c(c1)Oc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Oc6ccccc65)cc4)cc4c3B(c3cccc1c32)c1cccc2c1N4c1ccccc1C2(C)C]

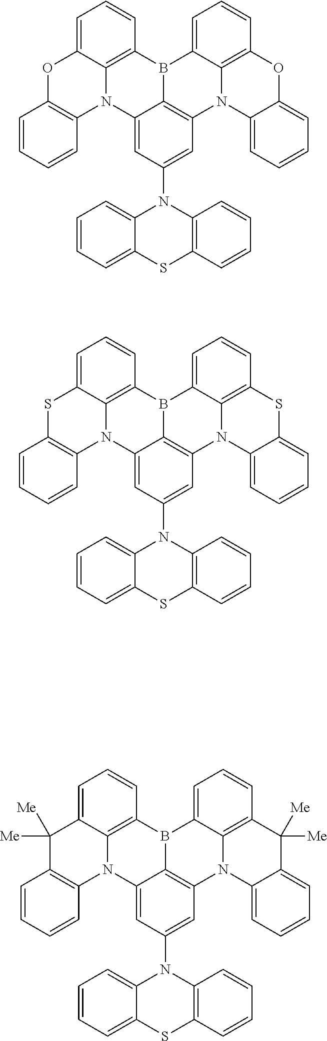 [SMILES: c1ccc2c(c1)Oc1cccc3c1N2c1cc(N2c4ccccc4Sc4ccccc42)cc2c1B3c1cccc3c1N2c1ccccc1O3 ; c1ccc2c(c1)Sc1ccccc1N2c1cc2c3c(c1)N1c4ccccc4Sc4cccc(c41)B3c1cccc3c1N2c1ccccc1S3 ; CC1(C)c2ccccc2N2c3cc(N4c5ccccc5Sc5ccccc54)cc4c3B(c3cccc1c32)c1cccc2c1N4c1ccccc1C2(C)C]

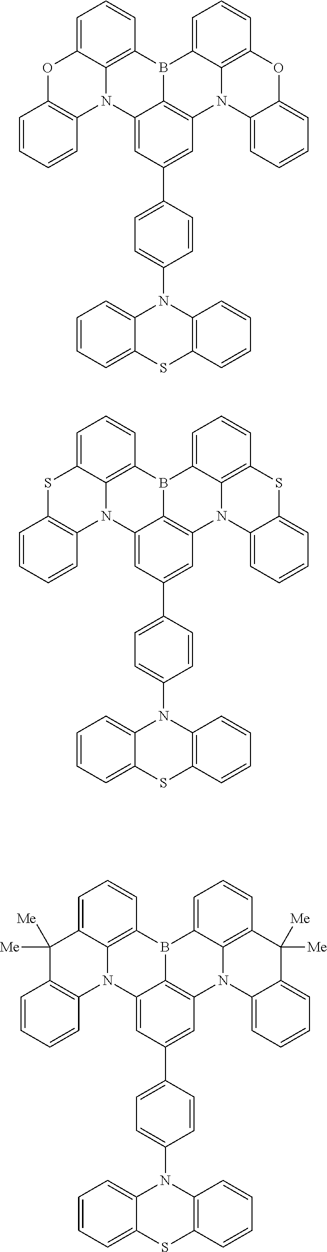 [SMILES: c1ccc2c(c1)Oc1cccc3c1N2c1cc(-c2ccc(N4c5ccccc5Sc5ccccc54)cc2)cc2c1B3c1cccc3c1N2c1ccccc1O3 ; c1ccc2c(c1)Sc1ccccc1N2c1ccc(-c2cc3c4c(c2)N2c5ccccc5Sc5cccc(c52)B4c2cccc4c2N3c2ccccc2S4)cc1 ; CC1(C)c2ccccc2N2c3cc(-c4ccc(N5c6ccccc6Sc6ccccc65)cc4)cc4c3B(c3cccc1c32)c1cccc2c1N4c1ccccc1C2(C)C]

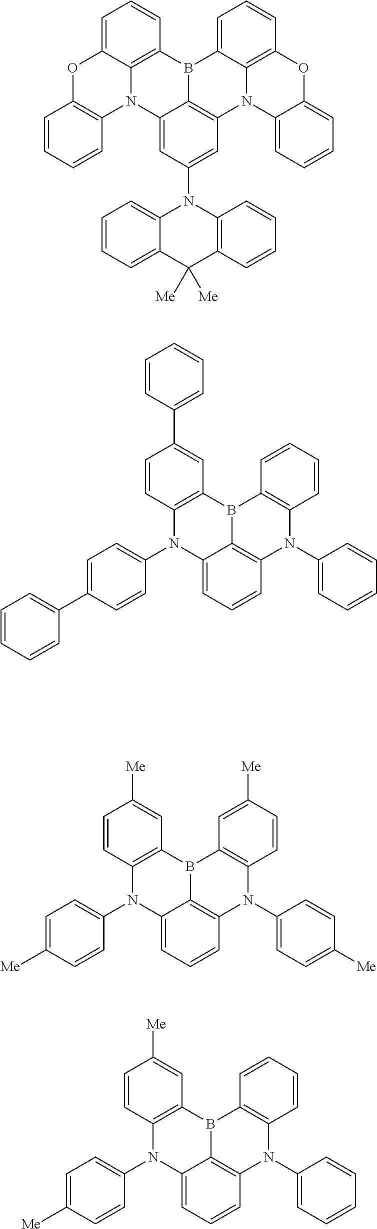 [SMILES: CC1(C)c2ccccc2N(c2cc3c4c(c2)N2c5ccccc5Oc5cccc(c52)B4c2cccc4c2N3c2ccccc2O4)c2ccccc21 ; c1ccc(-c2ccc(N3c4ccc(-c5ccccc5)cc4B4c5ccccc5N(c5ccccc5)c5cccc3c54)cc2)cc1 ; Cc1ccc(N2c3ccc(C)cc3B3c4cc(C)ccc4N(c4ccc(C)cc4)c4cccc2c43)cc1 ; Cc1ccc(N2c3ccc(C)cc3B3c4ccccc4N(c4ccccc4)c4cccc2c43)cc1]

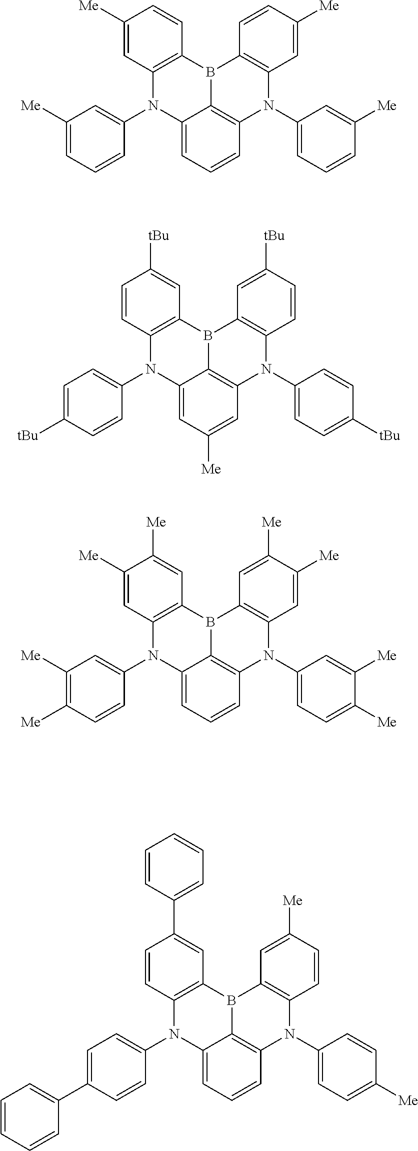 [SMILES: Cc1cccc(N2c3cc(C)ccc3B3c4ccc(C)cc4N(c4cccc(C)c4)c4cccc2c43)c1 ; Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1 ; Cc1ccc(N2c3cc(C)c(C)cc3B3c4cc(C)c(C)cc4N(c4ccc(C)c(C)c4)c4cccc2c43)cc1C ; Cc1ccc(N2c3ccc(C)cc3B3c4cc(-c5ccccc5)ccc4N(c4ccc(-c5ccccc5)cc4)c4cccc2c43)cc1]

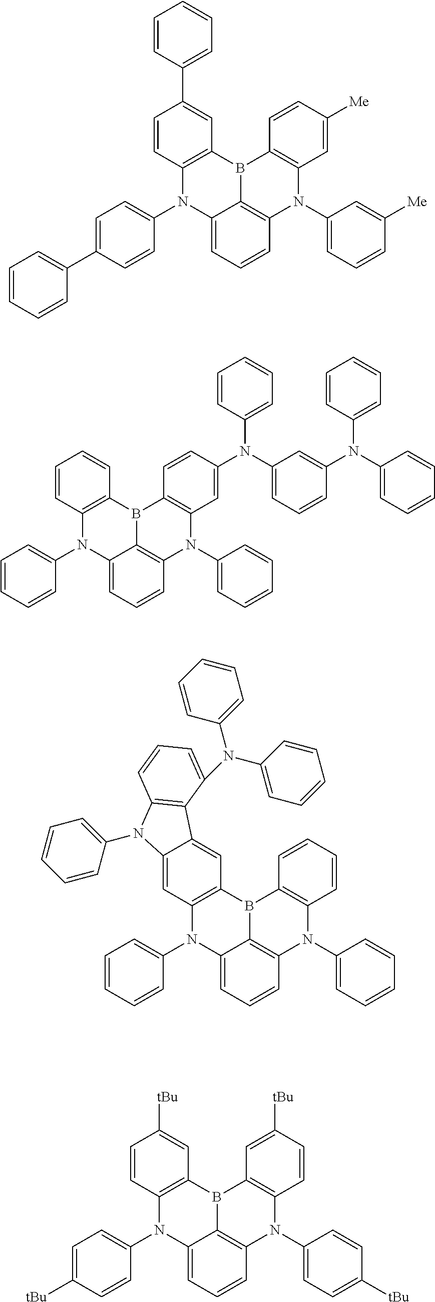 [SMILES: Cc1cccc(N2c3cc(C)ccc3B3c4cc(-c5ccccc5)ccc4N(c4ccc(-c5ccccc5)cc4)c4cccc2c43)c1 ; c1ccc(N(c2ccccc2)c2cccc(N(c3ccccc3)c3ccc4c(c3)N(c3ccccc3)c3cccc5c3B4c3ccccc3N5c3ccccc3)c2)cc1 ; c1ccc(N2c3ccccc3B3c4cc5c6c(N(c7ccccc7)c7ccccc7)cccc6n(-c6ccccc6)c5cc4N(c4ccccc4)c4cccc2c43)cc1 ; CC(C)(C)c1ccc(N2c3ccc(C(C)(C)C)cc3B3c4cc(C(C)(C)C)ccc4N(c4ccc(C(C)(C)C)cc4)c4cccc2c43)cc1]

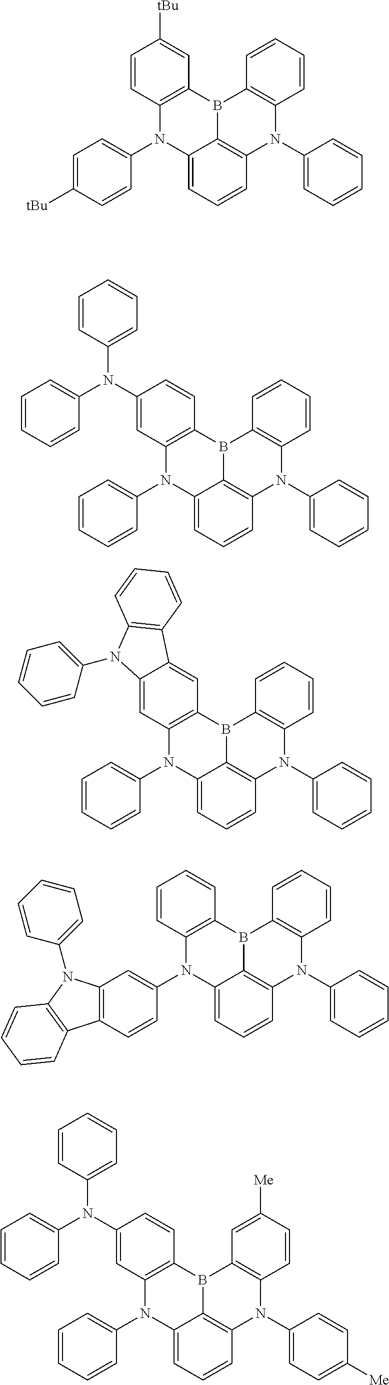

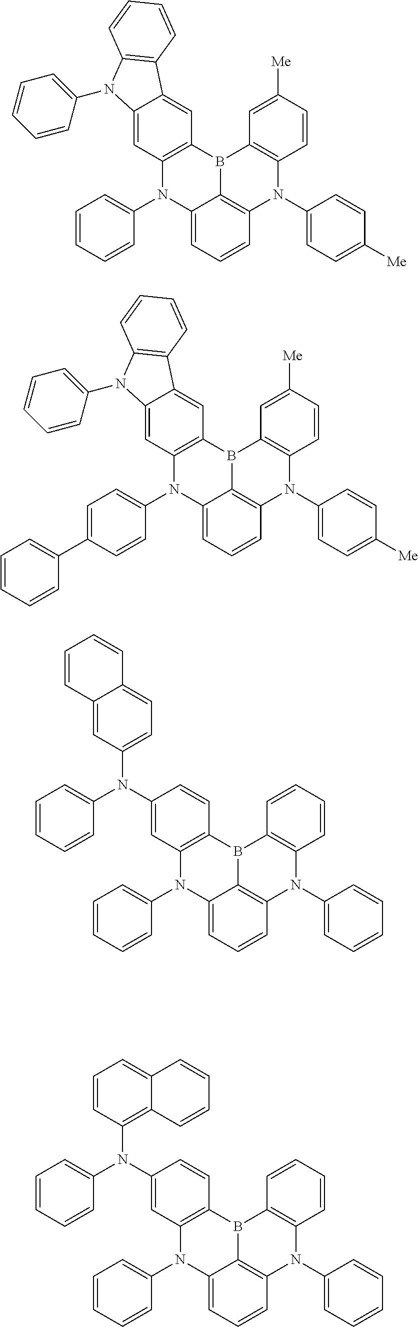 [SMILES: Cc1ccc(N2c3ccc(C)cc3B3c4cc5c6ccccc6n(-c6ccccc6)c5cc4N(c4ccccc4)c4cccc2c43)cc1 ; Cc1ccc(N2c3ccc(C)cc3B3c4cc5c6ccccc6n(-c6ccccc6)c5cc4N(c4ccc(-c5ccccc5)cc4)c4cccc2c43)cc1 ; c1ccc(N(c2ccc3c(c2)N(c2ccccc2)c2cccc4c2B3c2ccccc2N4c2ccccc2)c2ccc3ccccc3c2)cc1 ; c1ccc(N2c3ccccc3B3c4ccc(N(c5ccccc5)c5cccc6ccccc56)cc4N(c4ccccc4)c4cccc2c43)cc1]

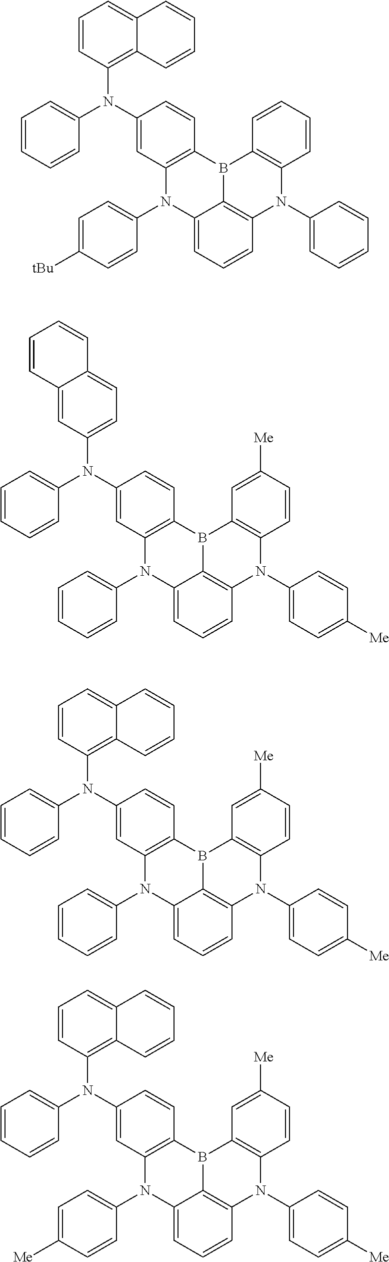

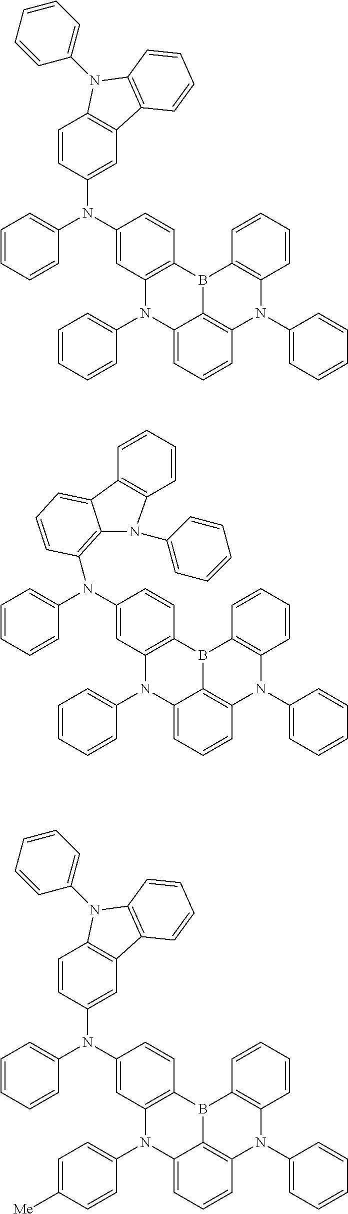 [SMILES: c1ccc(N(c2ccc3c(c2)N(c2ccccc2)c2cccc4c2B3c2ccccc2N4c2ccccc2)c2ccc3c(c2)c2ccccc2n3-c2ccccc2)cc1 ; c1ccc(N2c3ccccc3B3c4ccc(N(c5ccccc5)c5cccc6c7ccccc7n(-c7ccccc7)c56)cc4N(c4ccccc4)c4cccc2c43)cc1 ; Cc1ccc(N2c3cc(N(c4ccccc4)c4ccc5c(c4)c4ccccc4n5-c4ccccc4)ccc3B3c4ccccc4N(c4ccccc4)c4cccc2c43)cc1]

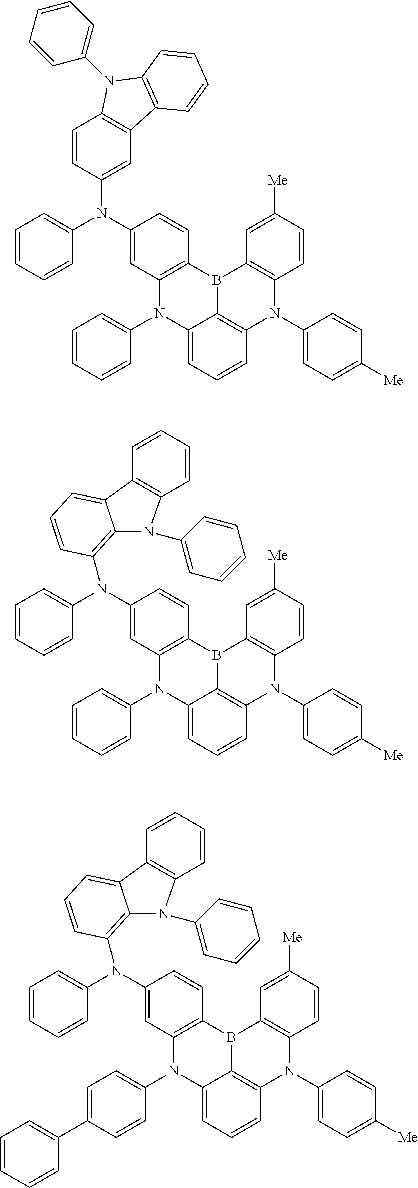 [SMILES: Cc1ccc(N2c3ccc(C)cc3B3c4ccc(N(c5ccccc5)c5ccc6c(c5)c5ccccc5n6-c5ccccc5)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccccc4)c4cccc2c43)cc1 ; Cc1ccc(N2c3ccc(C)cc3B3c4ccc(N(c5ccccc5)c5cccc6c7ccccc7n(-c7ccccc7)c56)cc4N(c4ccc(-c5ccccc5)cc4)c4cccc2c43)cc1]

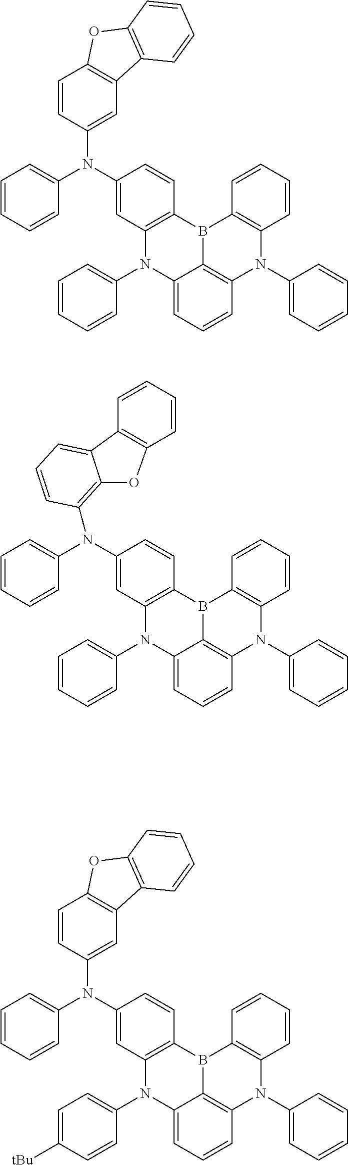 [SMILES: c1ccc(N(c2ccc3c(c2)N(c2ccccc2)c2cccc4c2B3c2ccccc2N4c2ccccc2)c2ccc3oc4ccccc4c3c2)cc1 ; c1ccc(N2c3ccccc3B3c4ccc(N(c5ccccc5)c5cccc6c5oc5ccccc56)cc4N(c4ccccc4)c4cccc2c43)cc1 ; CC(C)(C)c1ccc(N2c3cc(N(c4ccccc4)c4ccc5oc6ccccc6c5c4)ccc3B3c4ccccc4N(c4ccccc4)c4cccc2c43)cc1]

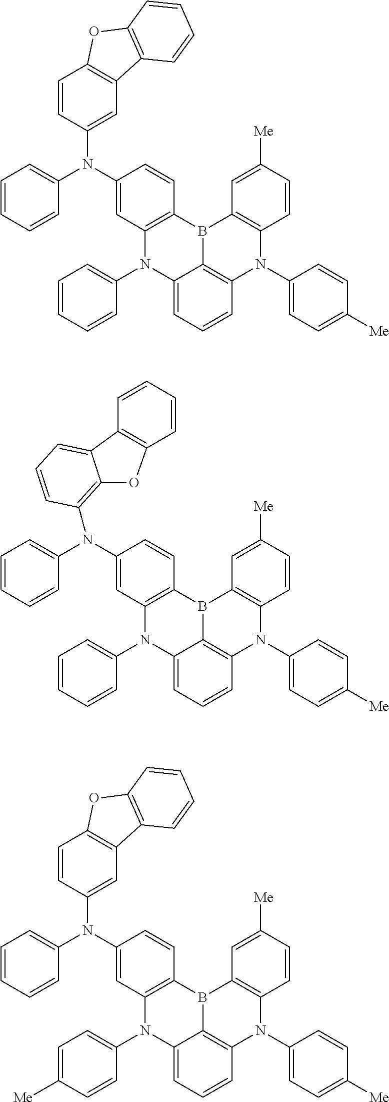 [SMILES: Cc1ccc(N2c3ccc(C)cc3B3c4ccc(N(c5ccccc5)c5ccc6oc7ccccc7c6c5)cc4N(c4ccccc4)c4cccc2c43)cc1 ; Cc1ccc(N2c3ccc(C)cc3B3c4ccc(N(c5ccccc5)c5cccc6c5oc5ccccc56)cc4N(c4ccccc4)c4cccc2c43)cc1 ; Cc1ccc(N2c3ccc(C)cc3B3c4ccc(N(c5ccccc5)c5ccc6oc7ccccc7c6c5)cc4N(c4ccc(C)cc4)c4cccc2c43)cc1]

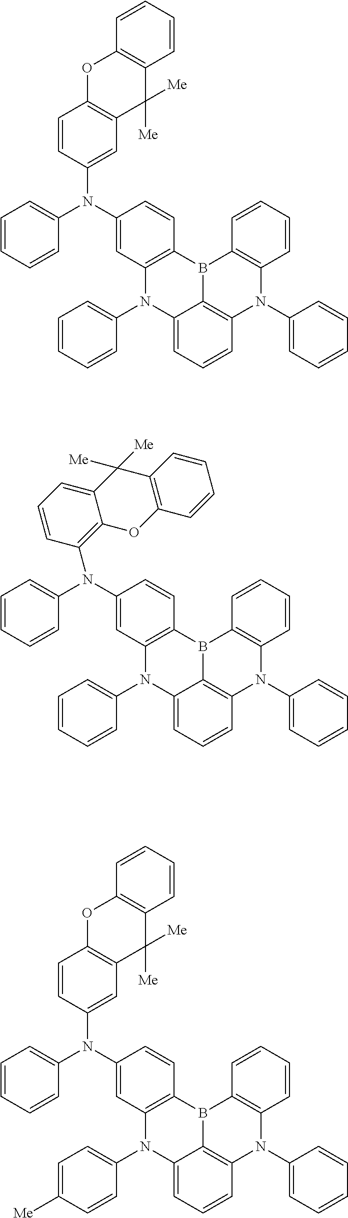 [SMILES: CC1(C)c2ccccc2Oc2ccc(N(c3ccccc3)c3ccc4c(c3)N(c3ccccc3)c3cccc5c3B4c3ccccc3N5c3ccccc3)cc21 ; CC1(C)c2ccccc2Oc2c(N(c3ccccc3)c3ccc4c(c3)N(c3ccccc3)c3cccc5c3B4c3ccccc3N5c3ccccc3)cccc21 ; Cc1ccc(N2c3cc(N(c4ccccc4)c4ccc5c(c4)C(C)(C)c4ccccc4O5)ccc3B3c4ccccc4N(c4ccccc4)c4cccc2c43)cc1]

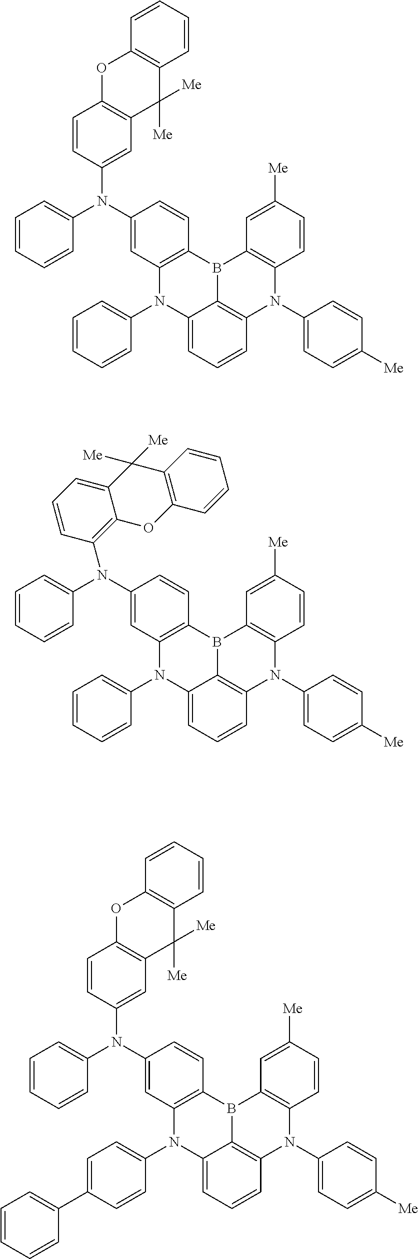 [SMILES: Cc1ccc(N2c3ccc(C)cc3B3c4ccc(N(c5ccccc5)c5ccc6c(c5)C(C)(C)c5ccccc5O6)cc4N(c4ccccc4)c4cccc2c43)cc1 ; Cc1ccc(N2c3ccc(C)cc3B3c4ccc(N(c5ccccc5)c5cccc6c5Oc5ccccc5C6(C)C)cc4N(c4ccccc4)c4cccc2c43)cc1 ; Cc1ccc(N2c3ccc(C)cc3B3c4ccc(N(c5ccccc5)c5ccc6c(c5)C(C)(C)c5ccccc5O6)cc4N(c4ccc(-c5ccccc5)cc4)c4cccc2c43)cc1]

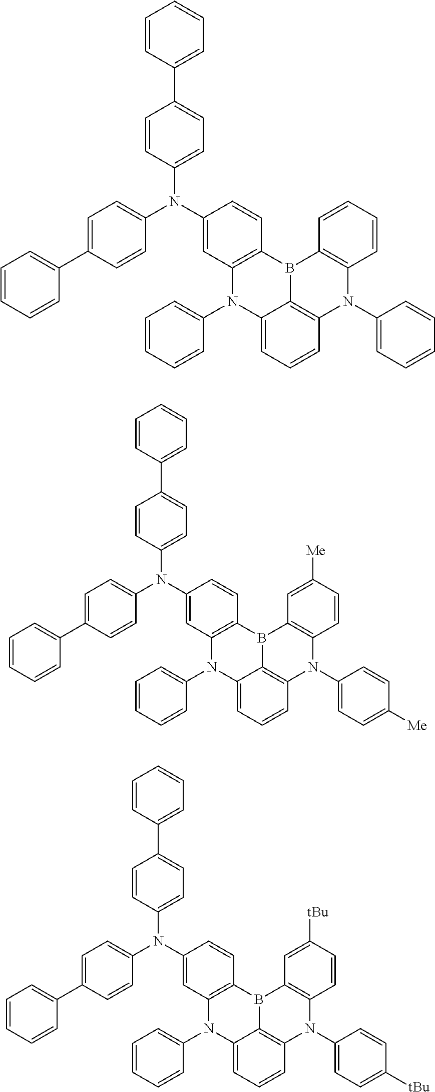

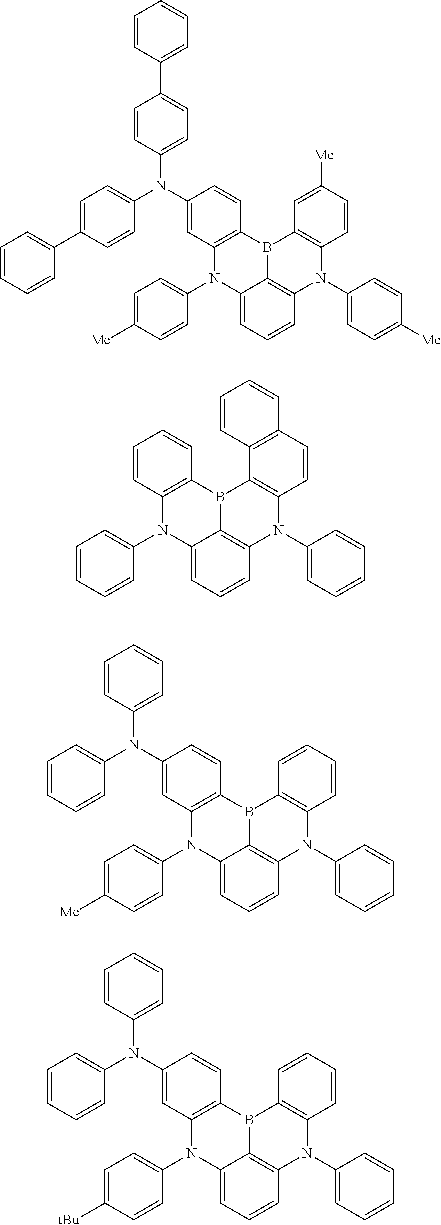

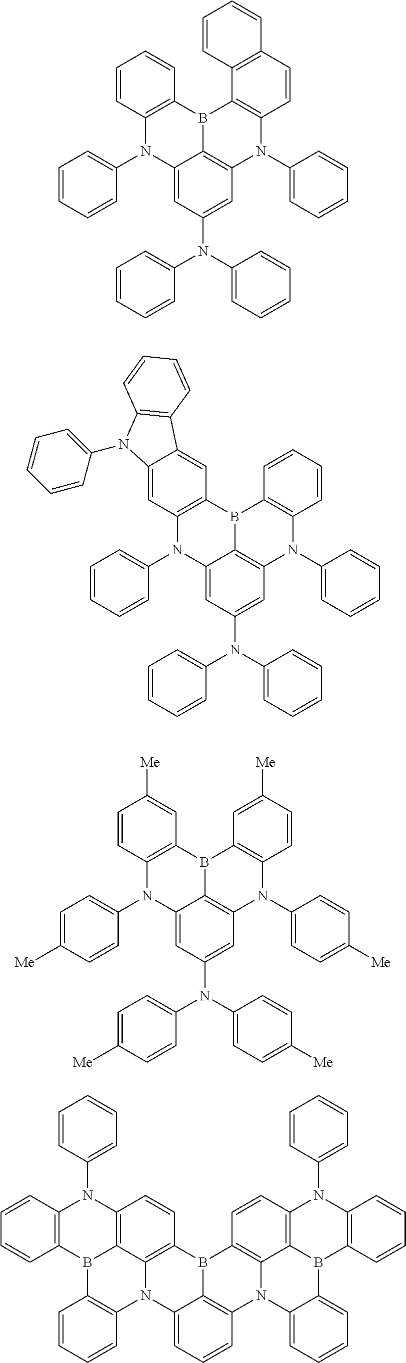

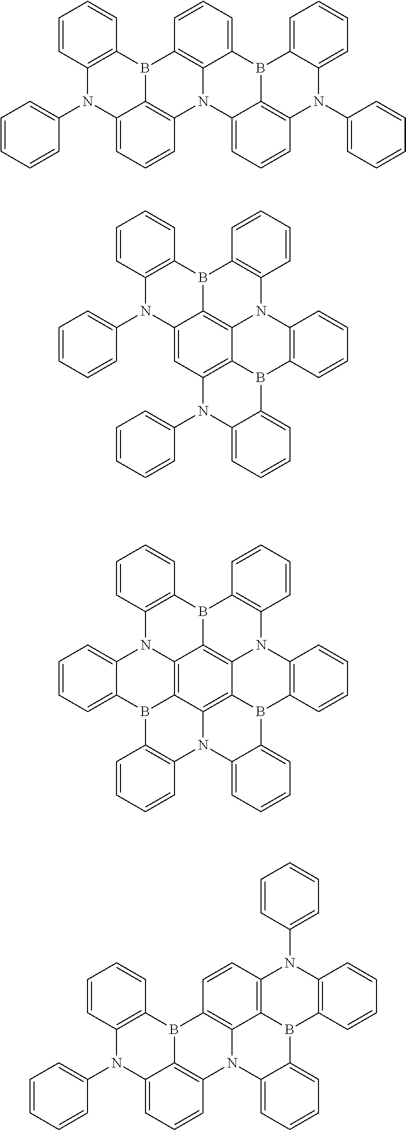

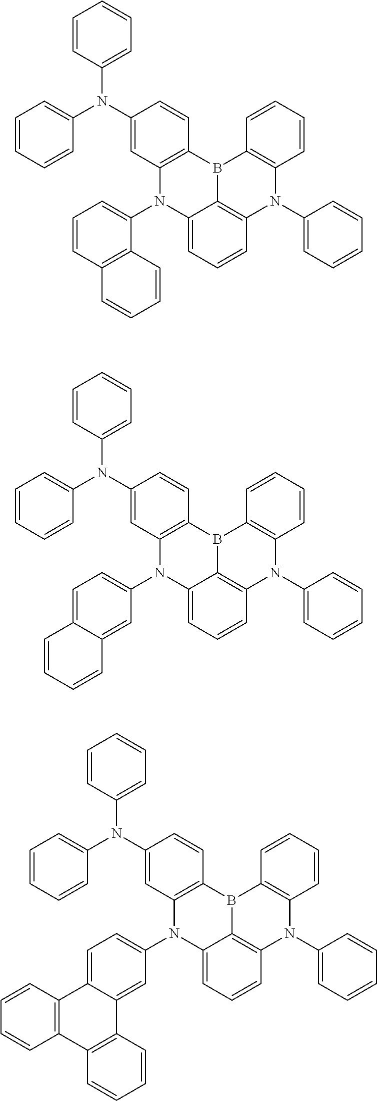 [SMILES: c1ccc(N(c2ccccc2)c2ccc3c(c2)N(c2cccc4ccccc24)c2cccc4c2B3c2ccccc2N4c2ccccc2)cc1 ; c1ccc(N(c2ccccc2)c2ccc3c(c2)N(c2ccc4ccccc4c2)c2cccc4c2B3c2ccccc2N4c2ccccc2)cc1 ; c1ccc(N(c2ccccc2)c2ccc3c(c2)N(c2ccc4c5ccccc5c5ccccc5c4c2)c2cccc4c2B3c2ccccc2N4c2ccccc2)cc1]

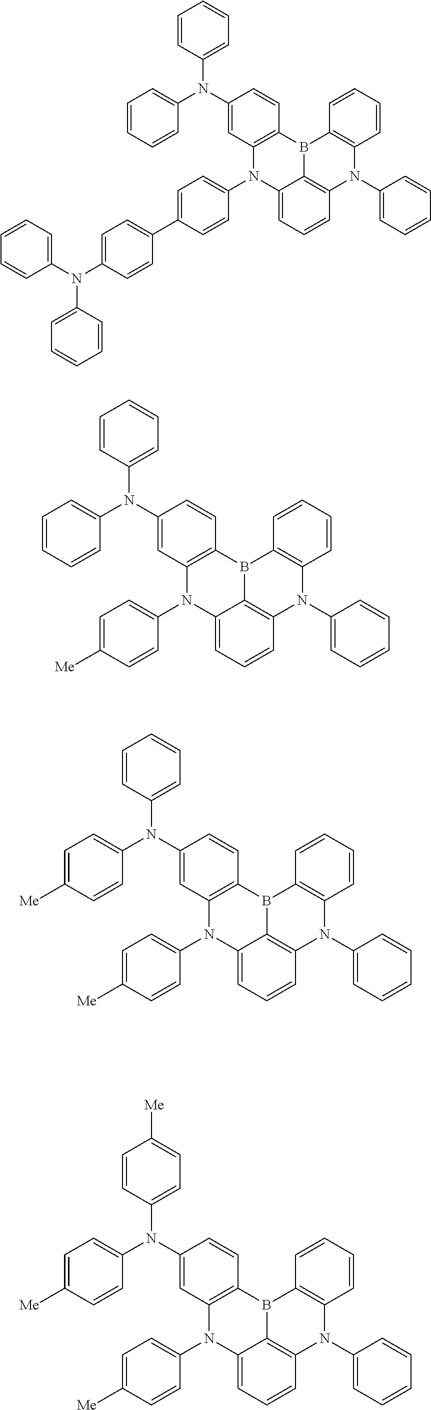 [SMILES: c1ccc(N(c2ccccc2)c2ccc(-c3ccc(N4c5cc(N(c6ccccc6)c6ccccc6)ccc5B5c6ccccc6N(c6ccccc6)c6cccc4c65)cc3)cc2)cc1 ; Cc1ccc(N2c3cc(N(c4ccccc4)c4ccccc4)ccc3B3c4ccccc4N(c4ccccc4)c4cccc2c43)cc1 ; Cc1ccc(N(c2ccccc2)c2ccc3c(c2)N(c2ccc(C)cc2)c2cccc4c2B3c2ccccc2N4c2ccccc2)cc1 ; Cc1ccc(N(c2ccc(C)cc2)c2ccc3c(c2)N(c2ccc(C)cc2)c2cccc4c2B3c2ccccc2N4c2ccccc2)cc1]

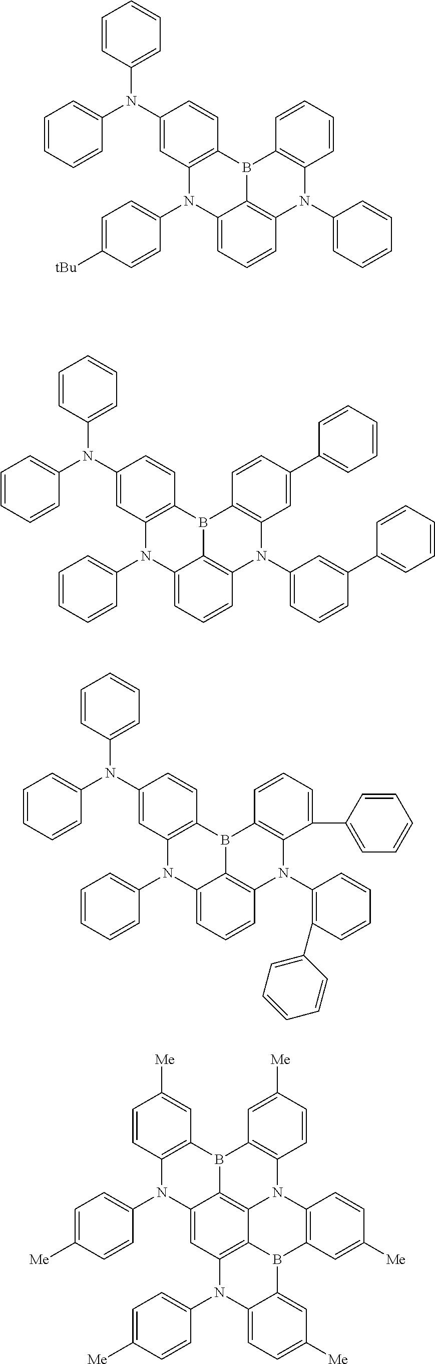

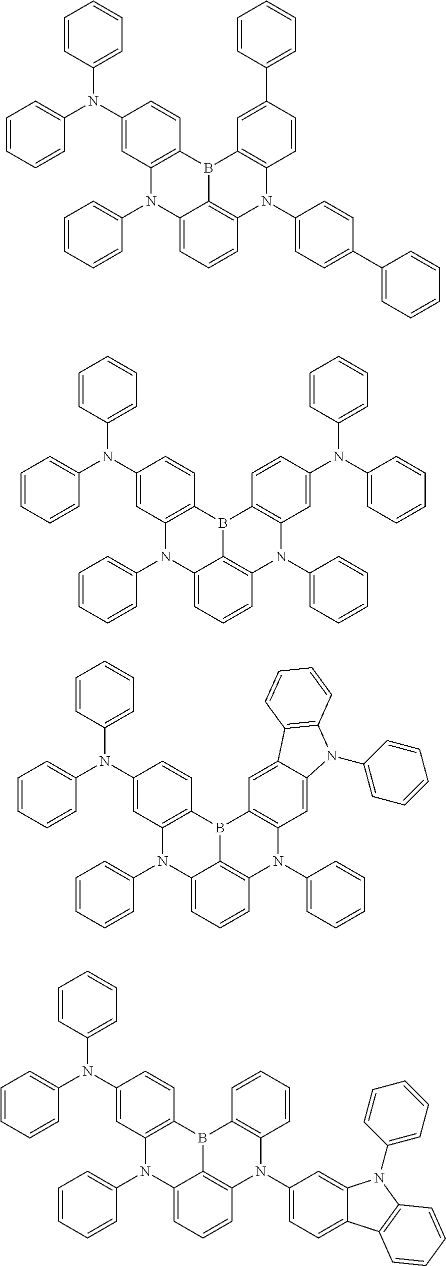

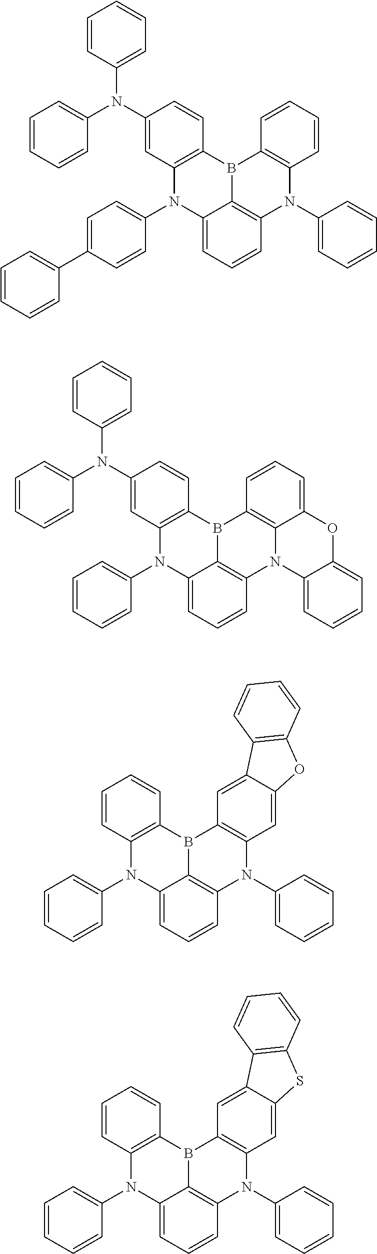 [SMILES: c1ccc(-c2ccc(N3c4cc(N(c5ccccc5)c5ccccc5)ccc4B4c5ccccc5N(c5ccccc5)c5cccc3c54)cc2)cc1 ; c1ccc(N(c2ccccc2)c2ccc3c(c2)N(c2ccccc2)c2cccc4c2B3c2cccc3c2N4c2ccccc2O3)cc1 ; c1ccc(N2c3ccccc3B3c4cc5c(cc4N(c4ccccc4)c4cccc2c43)oc2ccccc25)cc1 ; c1ccc(N2c3ccccc3B3c4cc5c(cc4N(c4ccccc4)c4cccc2c43)sc2ccccc25)cc1]

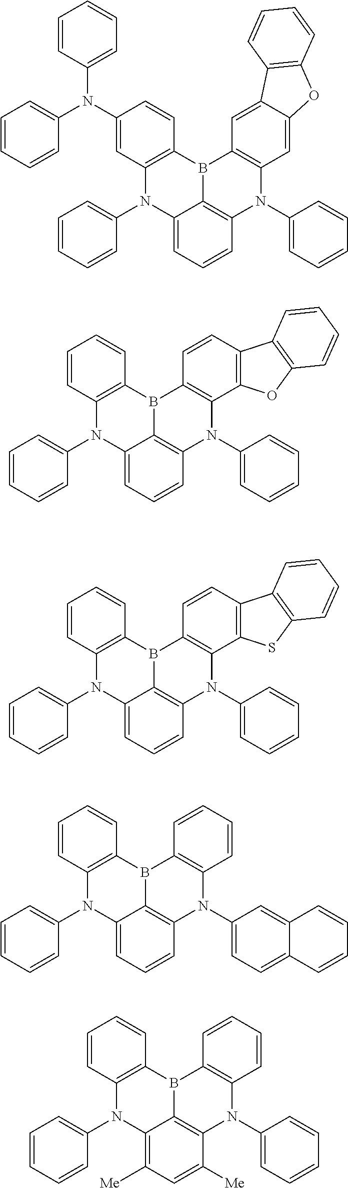

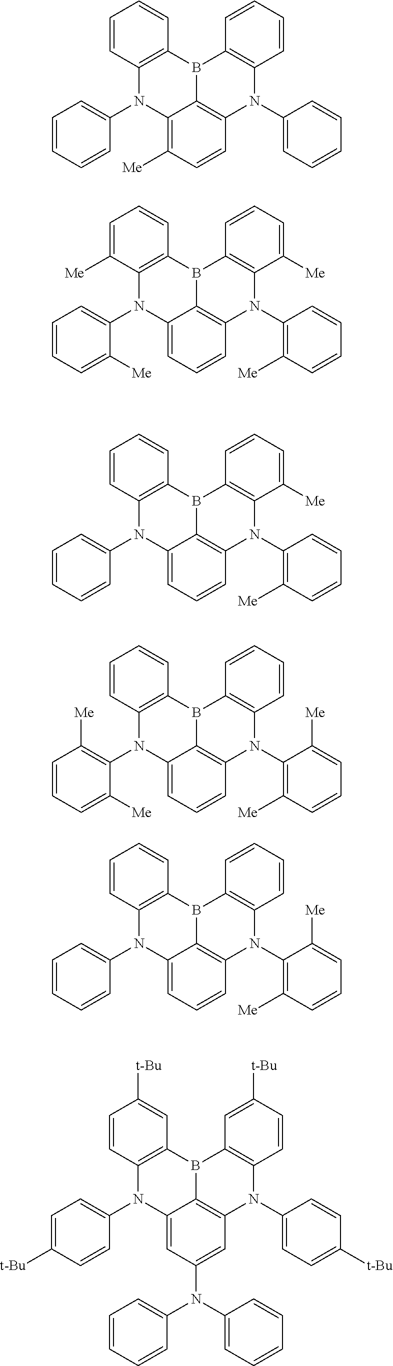

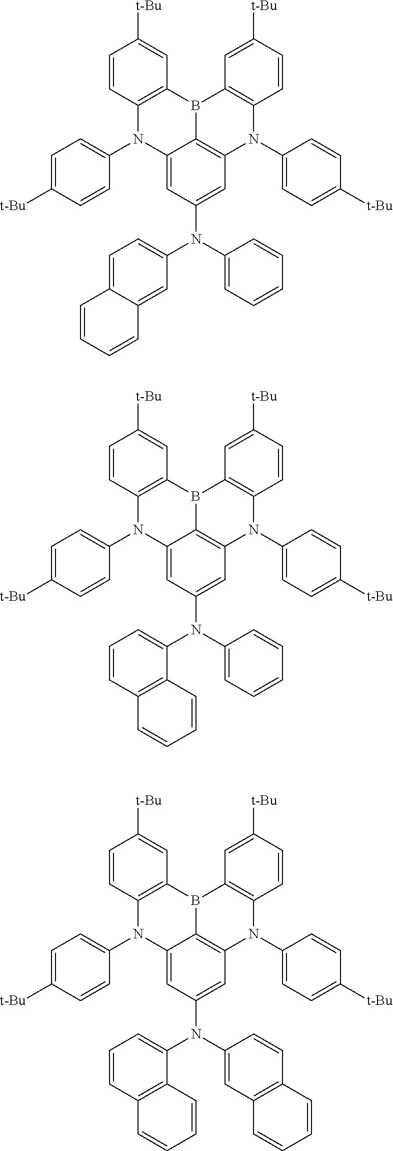 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccc6ccccc6c5)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5cccc6ccccc56)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(N(c5ccc6ccccc6c5)c5cccc6ccccc56)cc2c43)cc1]

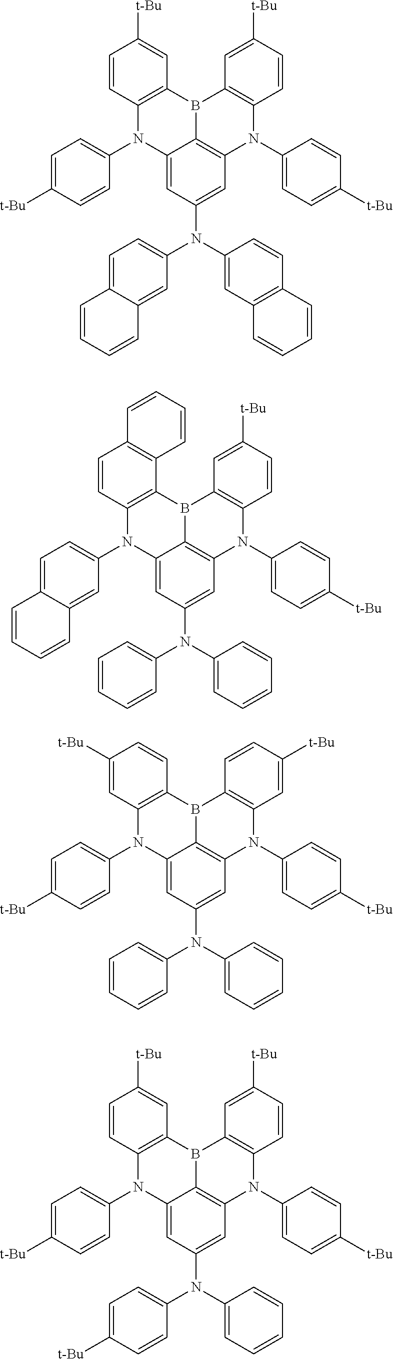

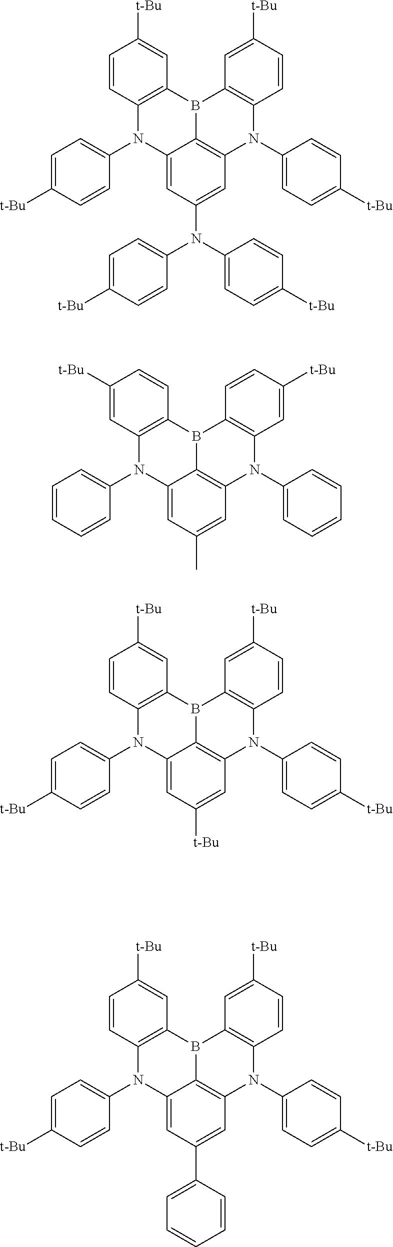 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1 ; Cc1cc2c3c(c1)N(c1ccccc1)c1cc(C(C)(C)C)ccc1B3c1ccc(C(C)(C)C)cc1N2c1ccccc1 ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1 ; CC(C)(C)c1ccc(N2c3ccc(C(C)(C)C)cc3B3c4cc(C(C)(C)C)ccc4N(c4ccc(C(C)(C)C)cc4)c4cc(-c5ccccc5)cc2c43)cc1]

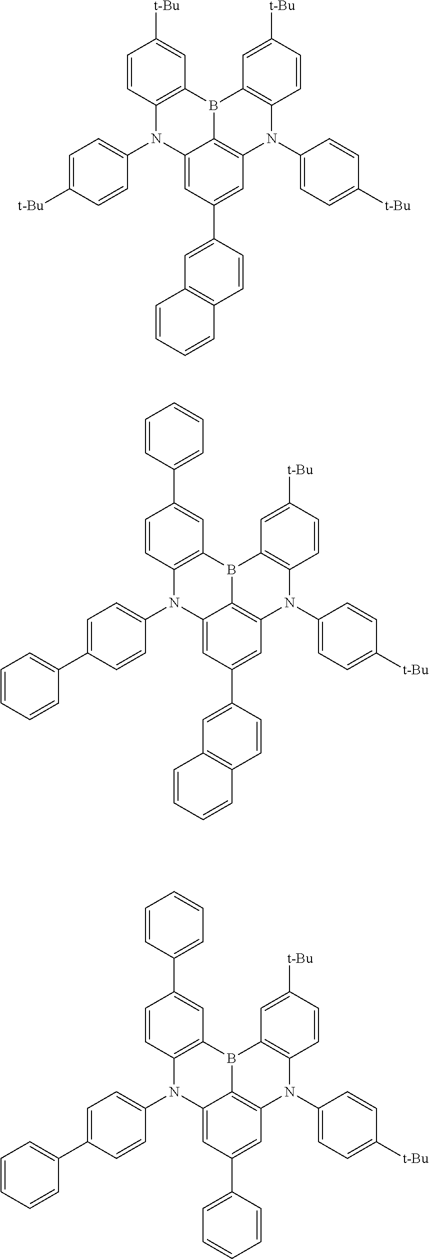 [SMILES: CC(C)(C)c1ccc(N2c3ccc(C(C)(C)C)cc3B3c4cc(C(C)(C)C)ccc4N(c4ccc(C(C)(C)C)cc4)c4cc(-c5ccc6ccccc6c5)cc2c43)cc1 ; CC(C)(C)c1ccc(N2c3ccc(C(C)(C)C)cc3B3c4cc(-c5ccccc5)ccc4N(c4ccc(-c5ccccc5)cc4)c4cc(-c5ccc6ccccc6c5)cc2c43)cc1 ; CC(C)(C)c1ccc(N2c3ccc(C(C)(C)C)cc3B3c4cc(-c5ccccc5)ccc4N(c4ccc(-c5ccccc5)cc4)c4cc(-c5ccccc5)cc2c43)cc1]

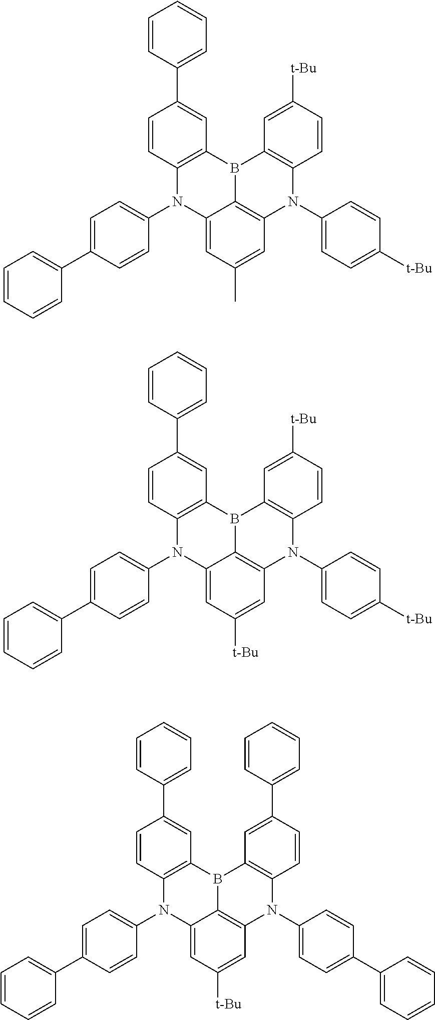 [SMILES: Cc1cc2c3c(c1)N(c1ccc(C(C)(C)C)cc1)c1ccc(C(C)(C)C)cc1B3c1cc(-c3ccccc3)ccc1N2c1ccc(-c2ccccc2)cc1 ; CC(C)(C)c1ccc(N2c3ccc(C(C)(C)C)cc3B3c4cc(-c5ccccc5)ccc4N(c4ccc(-c5ccccc5)cc4)c4cc(C(C)(C)C)cc2c43)cc1 ; CC(C)(C)c1cc2c3c(c1)N(c1ccc(-c4ccccc4)cc1)c1ccc(-c4ccccc4)cc1B3c1cc(-c3ccccc3)ccc1N2c1ccc(-c2ccccc2)cc1]

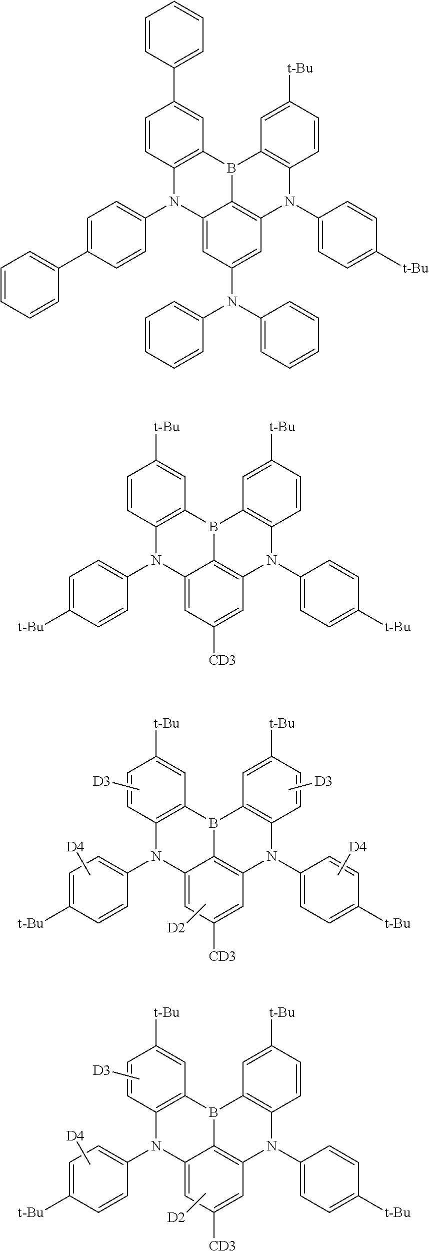

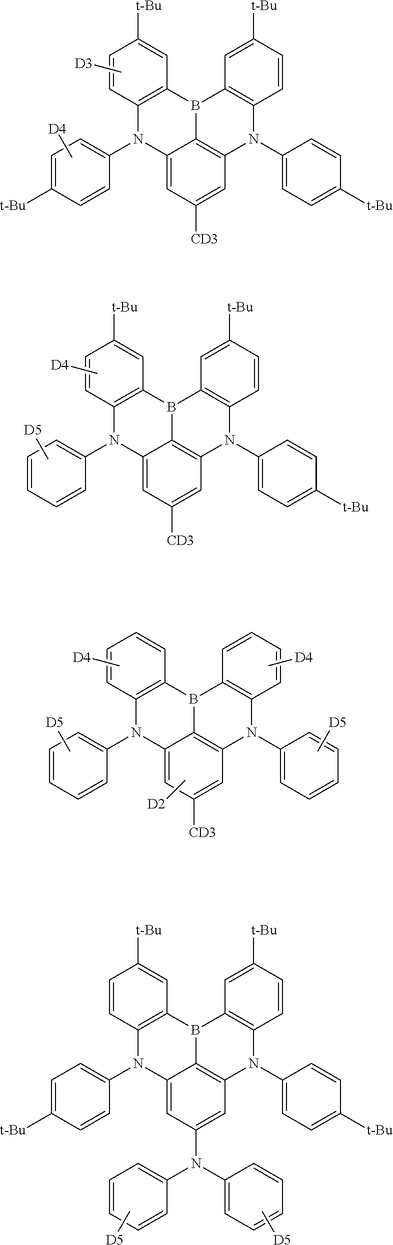

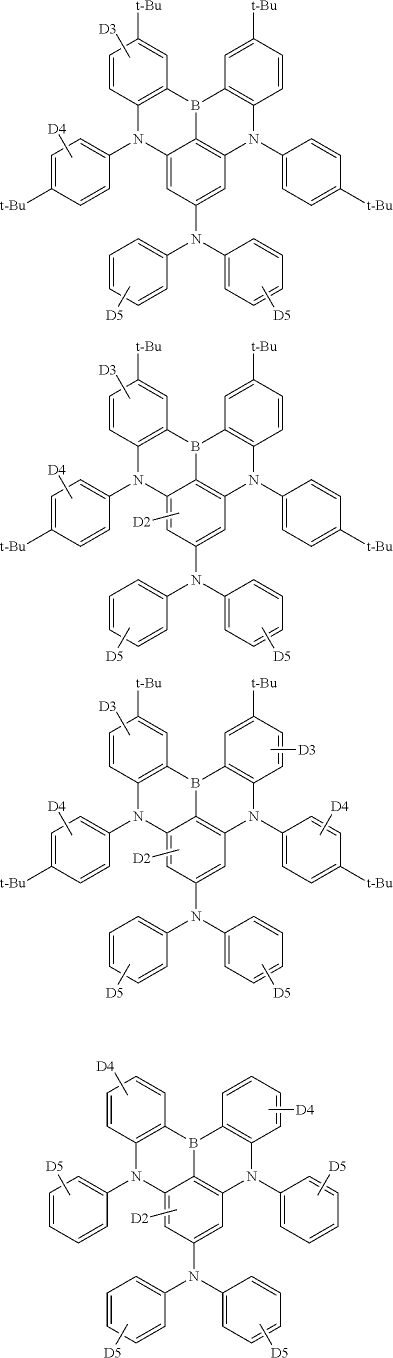

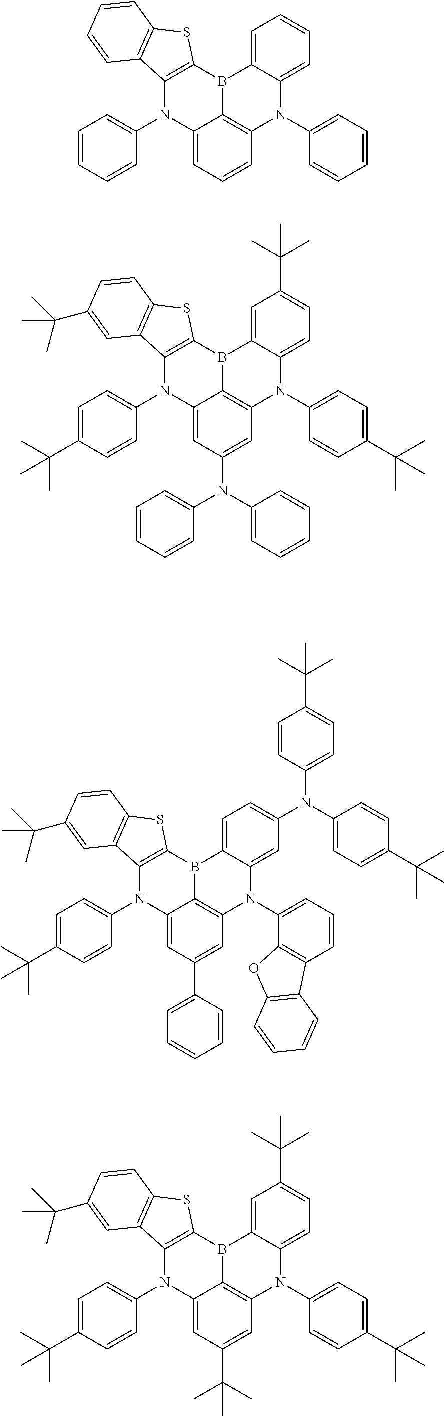

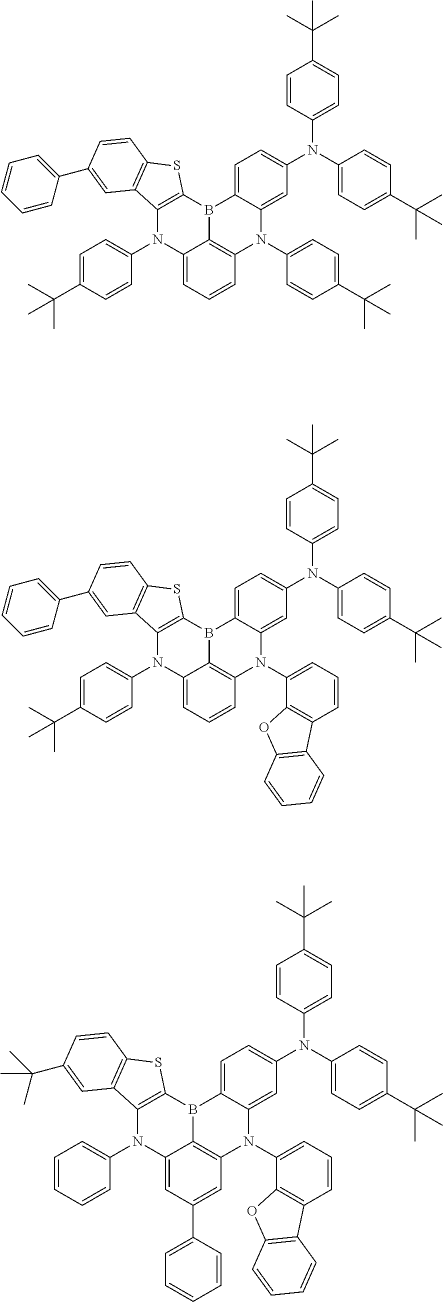

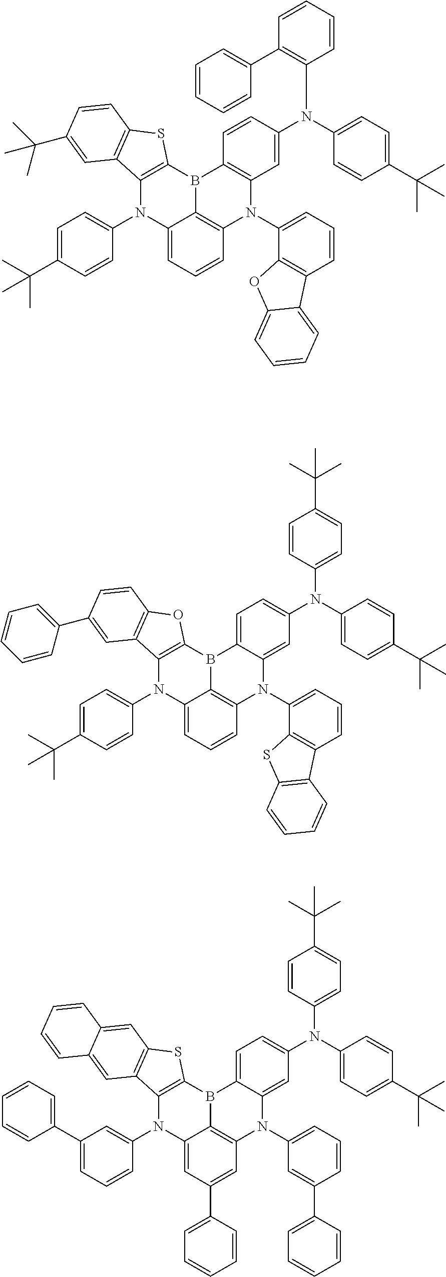 [SMILES: CC(C)(C)c1ccc(N(c2ccc3c(c2)N(c2cccc4c2oc2ccccc24)c2cccc4c2B3c2sc3ccc(C(C)(C)C)cc3c2N4c2ccc(C(C)(C)C)cc2)c2ccccc2-c2ccccc2)cc1 ; CC(C)(C)c1ccc(N(c2ccc(C(C)(C)C)cc2)c2ccc3c(c2)N(c2cccc4c2sc2ccccc24)c2cccc4c2B3c2oc3ccc(-c5ccccc5)cc3c2N4c2ccc(C(C)(C)C)cc2)cc1 ; CC(C)(C)c1ccc(N(c2ccc(C(C)(C)C)cc2)c2ccc3c(c2)N(c2cccc(-c4ccccc4)c2)c2cc(-c4ccccc4)cc4c2B3c2sc3cc5ccccc5cc3c2N4c2cccc(-c3ccccc3)c2)cc1]

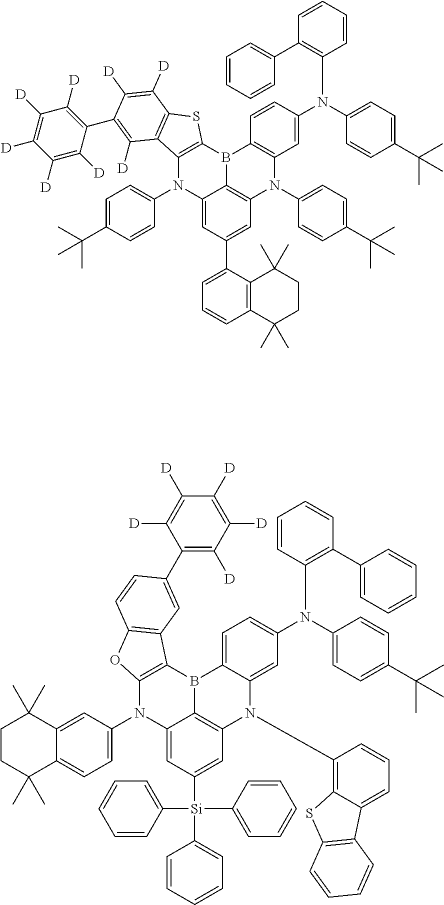 [SMILES: [2H]c1c([2H])c([2H])c(-c2c([2H])c([2H])c3sc4c(c3c2[2H])N(c2ccc(C(C)(C)C)cc2)c2cc(-c3cccc5c3C(C)(C)CCC5(C)C)cc3c2B4c2ccc(N(c4ccc(C(C)(C)C)cc4)c4ccccc4-c4ccccc4)cc2N3c2ccc(C(C)(C)C)cc2)c([2H])c1[2H] ; [2H]c1c([2H])c([2H])c(-c2ccc3oc4c(c3c2)B2c3ccc(N(c5ccc(C(C)(C)C)cc5)c5ccccc5-c5ccccc5)cc3N(c3cccc5c3sc3ccccc35)c3cc([Si](c5ccccc5)(c5ccccc5)c5ccccc5)cc(c32)N4c2ccc3c(c2)C(C)(C)CCC3(C)C)c([2H])c1[2H]]

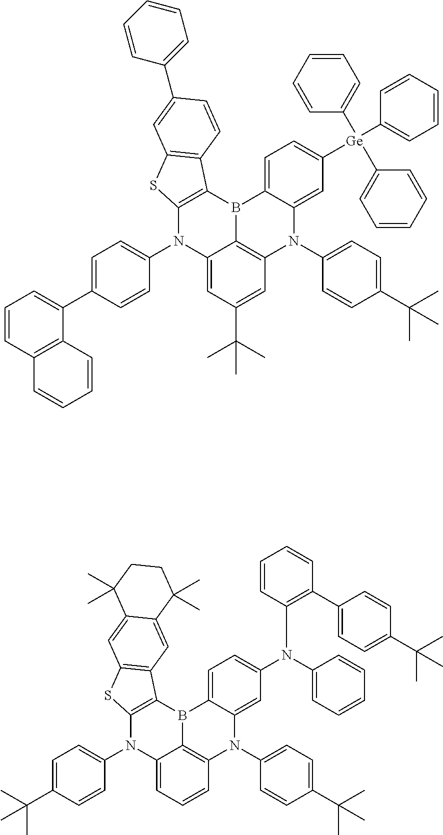

In the compounds, D2 to D5 represent structures in which 2 to 5 hydrogen atoms, respectively, are replaced with deuterium.

An organic electroluminescent device according to one embodiment does not comprise a compound comprising an anthracene-based moiety in the light-emitting layer.

According to one embodiment, a host in the organic electroluminescent device comprises a first host and a second host, wherein the first host is the compound represented by Formula 1, and the first host and the second host may be different from each other.

According to one embodiment, the second host may be a compound represented by the following Formula 2:

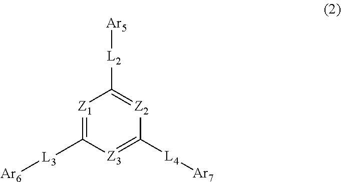

In Formula 2,
Z₁ to Z₃ each independently represent —N═ or —C(R₂₀)═, with the proviso that at least one of Z₁ to Z₃ is N;
R₂₀ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring;
L₂ to L₄ each independently represent a single bond, a substituted or unsubstituted (C₆-C₃₀)arylene, a substituted or unsubstituted (C₃-C₃₀)cycloalkylene, or a substituted or unsubstituted (3- to 30-membered)heteroarylene;
Ar₅ to Ar₇ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, or *—N—(R₁₁)(R₁₂); or may be linked to adjacent substituents to form a ring(s), provided that at least one of Ar₅ to Ar₇ is a substituted or unsubstituted (C₆-C₃₀)aryl or a substituted or unsubstituted (3- to 30-membered)heteroaryl; and
R₁₁ and R₁₂ each independently represent a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl.

In one embodiment, at least two of Z₁ to Z₃ may be N, and preferably, all of Z₁ to Z₃ may be N.

In one embodiment, L₂ to L₄ may each independently be a single bond, a substituted or unsubstituted (C₆-C₃₀)arylene, or a substituted or unsubstituted (5- to 30-membered)heteroarylene, preferably a single bond, a substituted or unsubstituted (C₆-C₂₅)arylene, or a substituted or unsubstituted (5- to 25-membered)heteroarylene, and more preferably a single bond, a substituted or unsubstituted (C₆-C₁₈)arylene, or a substituted or unsubstituted (5- to 18-membered)heteroaryl. For example, L₂ to L₄ may each independently be a single bond, or phenylene unsubstituted or substituted with phenyl, a substituted or unsubstituted biphenylene, a substituted or unsubstituted carbazolylene.

In one embodiment, at least one of L₂ to L₄ may be a substituted or unsubstituted phenylene represented by the following Formula 2-11:

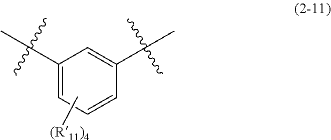

In Formula 2-11,
R′₁₁ represents hydrogen, deuterium, (C₆-C₃₀)aryl, or a combination thereof, and each of R′₁₁ may be the same or different.

In one embodiment, Ar₅ to Ar₇ may each independently be a substituted or unsubstituted (C₆-C₃₀)aryl, a substituted or unsubstituted (5- to 30-membered)heteroaryl, preferably (C₆-C₂₅)aryl unsubstituted or substituted with (5- to 30-membered)heteroaryl, (5- to 25-membered)heteroaryl unsubstituted or substituted with (C₆-C₃₀)aryl, and more preferably (C₆-C₁₈)aryl unsubstituted or substituted with (5- to 30-membered)heteroaryl, or (5- to 18-membered)heteroaryl unsubstituted or substituted with (C₆-C₃₀)aryl. For example, Ar₅ to Ar₇ may each independently be phenyl unsubstituted or substituted with dibenzofuran or dibenzothiophene, a substituted or unsubstituted p-biphenyl, a substituted or unsubstituted m-biphenyl, a substituted or unsubstituted o-biphenyl, a substituted or unsubstituted dimethylfluorenyl, a substituted or unsubstituted diphenylfluorenyl, a substituted or unsubstituted carbazolyl, dibenzofuranyl unsubstituted or substituted by a substituted or unsubstituted carbazolyl, dibenzothiophenyl unsubstituted or substituted by carbazolyl, a substituted or unsubstituted benzofurocarbazolyl, or a substituted or unsubstituted benzothienocarbazolyl.

In one embodiment, at least one of Ar₅ to Ar₇ may be represented by any one of the following Formulas 2-1 to 2-7:

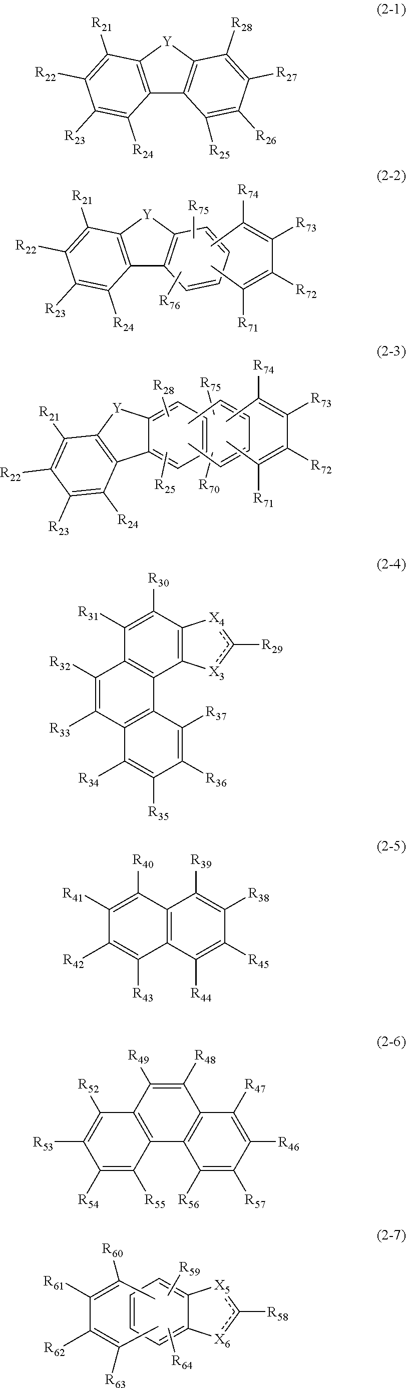

In Formulas 2-1 to 2-7,
Y represents O, S, N(R₇₇), or C(R₇₈)(R₇₉);
R₇₇ is a site linked to any one of L₂ to L₄ or a substituted or unsubstituted (C₆-C₃₀)aryl;
R₇₈ and R₇₉ each independently represent a site linked to any one of L₂ to L₄, or a substituted or unsubstituted (C₁-C₃₀)alkyl, a substituted or unsubstituted (C₆-C₃₀)aryl, or a substituted or unsubstituted (3- to 30-membered)heteroaryl; or may be linked to each other to form a ring(s);
R₂₁ to R₂₈, R₃₀ to R₄₉, R₅₂ to R₅₇, R₅₉ to R₆₄, and R₇₀ to R₇₆ each independently represent a site linked to any one of L₂ to L₄; or hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring; or may be linked to adjacent substituents to form a ring(s);
X₃ to X₆ each independently represent —O—, —S—, —Se—, or —N═; and
R₂₉ and R₅₈ each independently represent a site linked to any one of L₂ to L₄, or a substituted or unsubstituted (C₁-C₃₀)alkyl, a substituted or unsubstituted (C₆-C₃₀)aryl, or a substituted or unsubstituted (3- to 30-membered)heteroaryl.

According to one embodiment, the second host may comprise a compound represented by Formula 2 having a triplet energy (T₁) greater than 2.8.

According to one embodiment, the compound represented by Formula 2 may be specifically exemplified by the following compounds, but is not limited thereto.

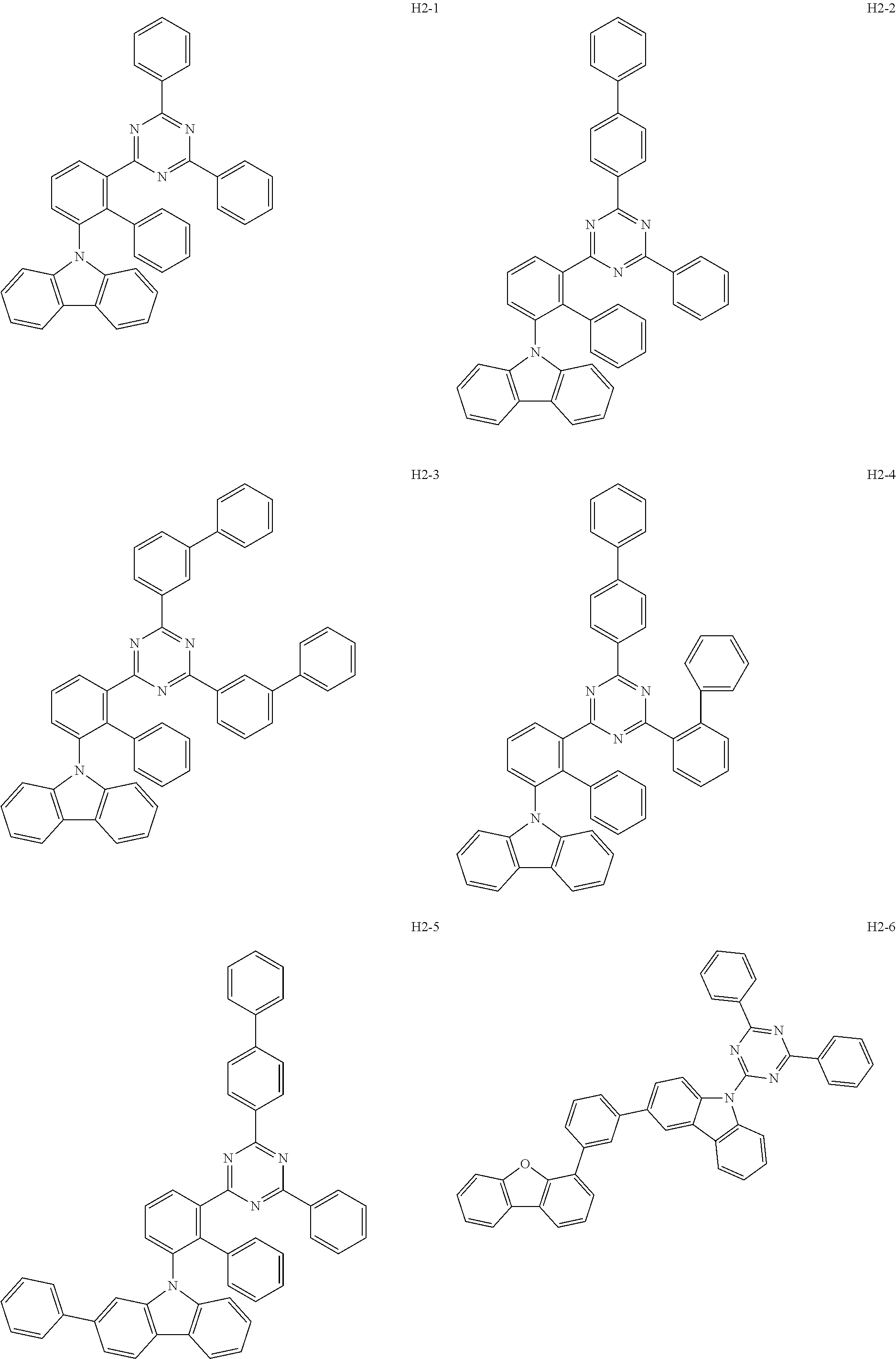

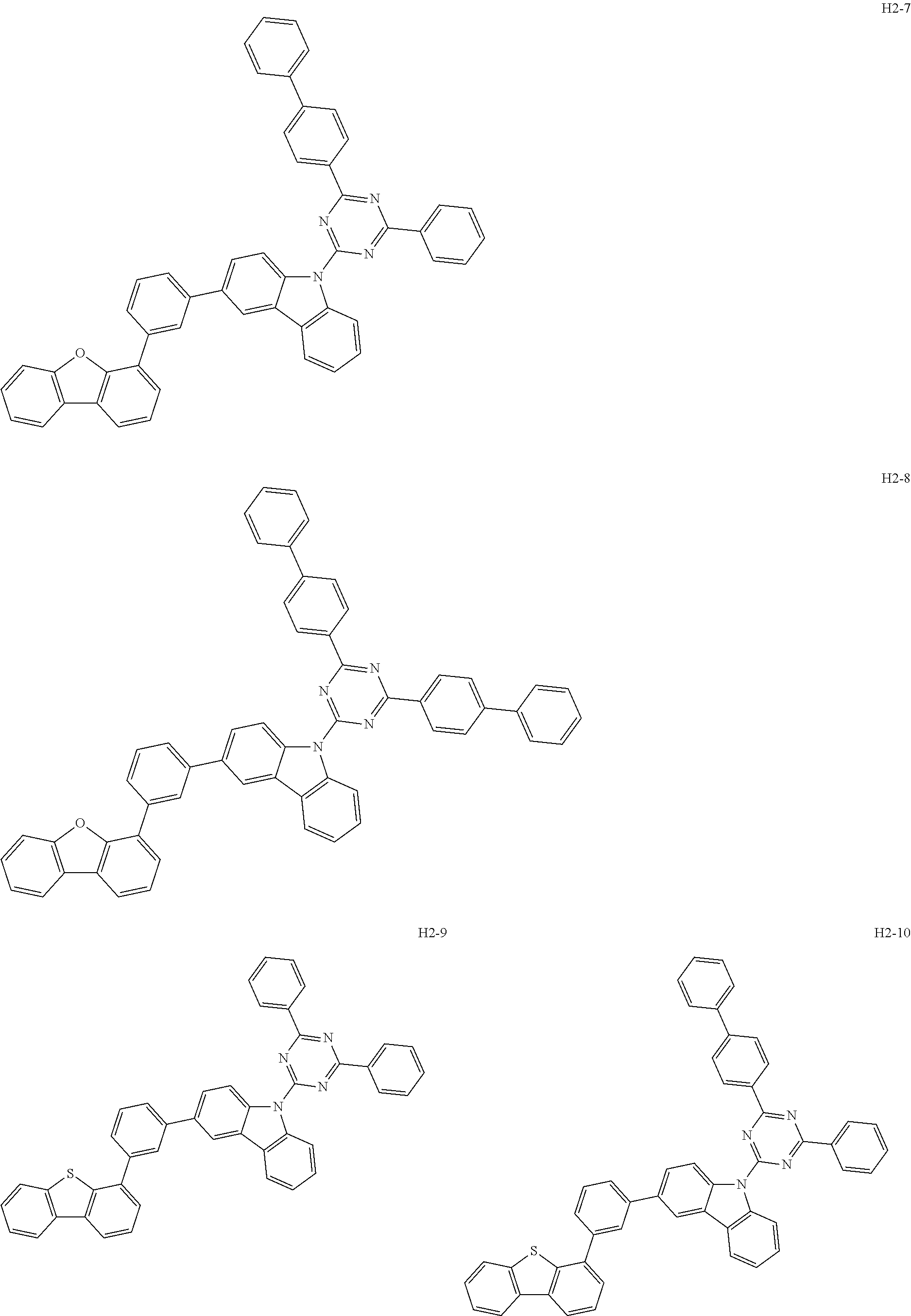 [SMILES: c1ccc(-c2ccc(-c3nc(-c4ccccc4)nc(-n4c5ccccc5c5cc(-c6cccc(-c7cccc8c7oc7ccccc78)c6)ccc54)n3)cc2)cc1 ; c1ccc(-c2ccc(-c3nc(-c4ccc(-c5ccccc5)cc4)nc(-n4c5ccccc5c5cc(-c6cccc(-c7cccc8c7oc7ccccc78)c6)ccc54)n3)cc2)cc1 ; c1ccc(-c2nc(-c3ccccc3)nc(-n3c4ccccc4c4cc(-c5cccc(-c6cccc7c6sc6ccccc67)c5)ccc43)n2)cc1 ; c1ccc(-c2ccc(-c3nc(-c4ccccc4)nc(-n4c5ccccc5c5cc(-c6cccc(-c7cccc8c7sc7ccccc78)c6)ccc54)n3)cc2)cc1]

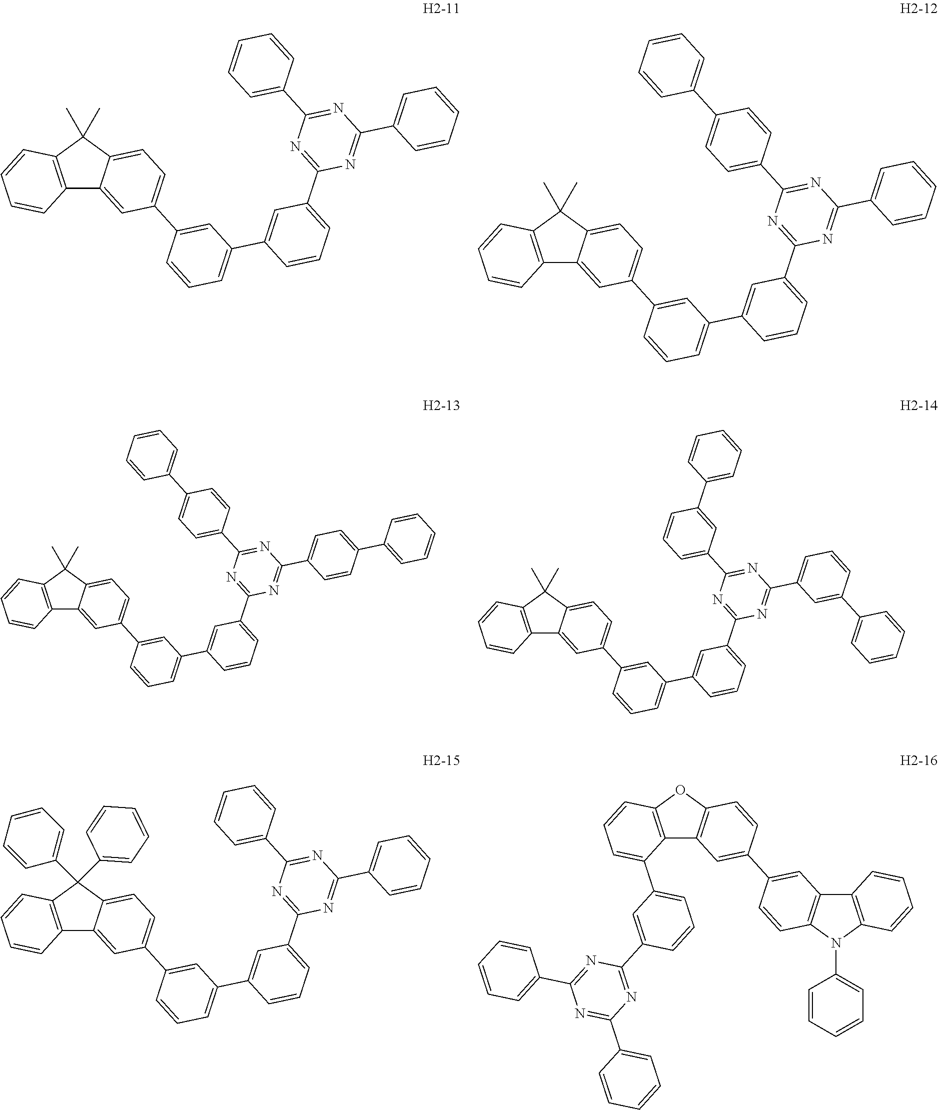

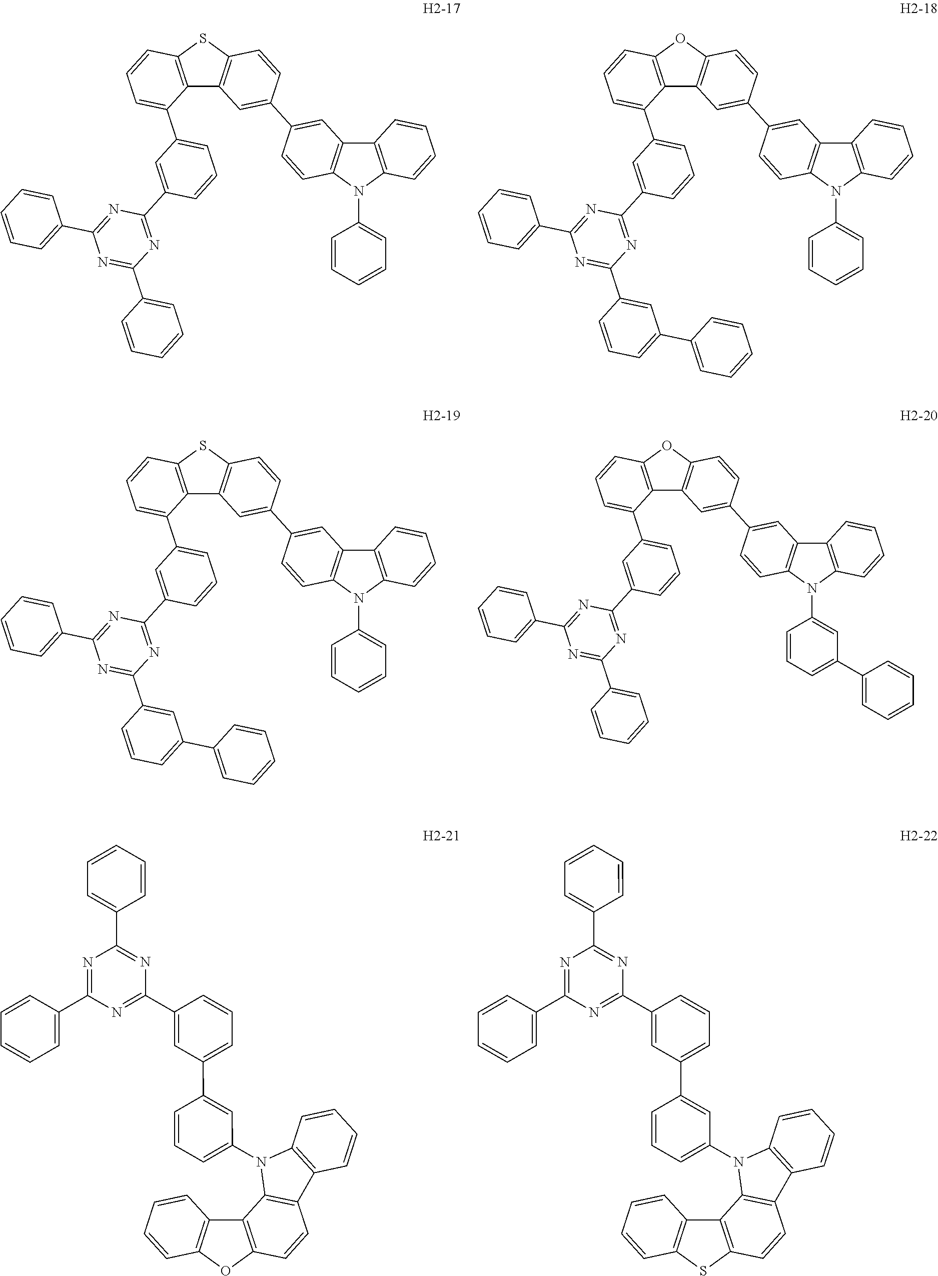

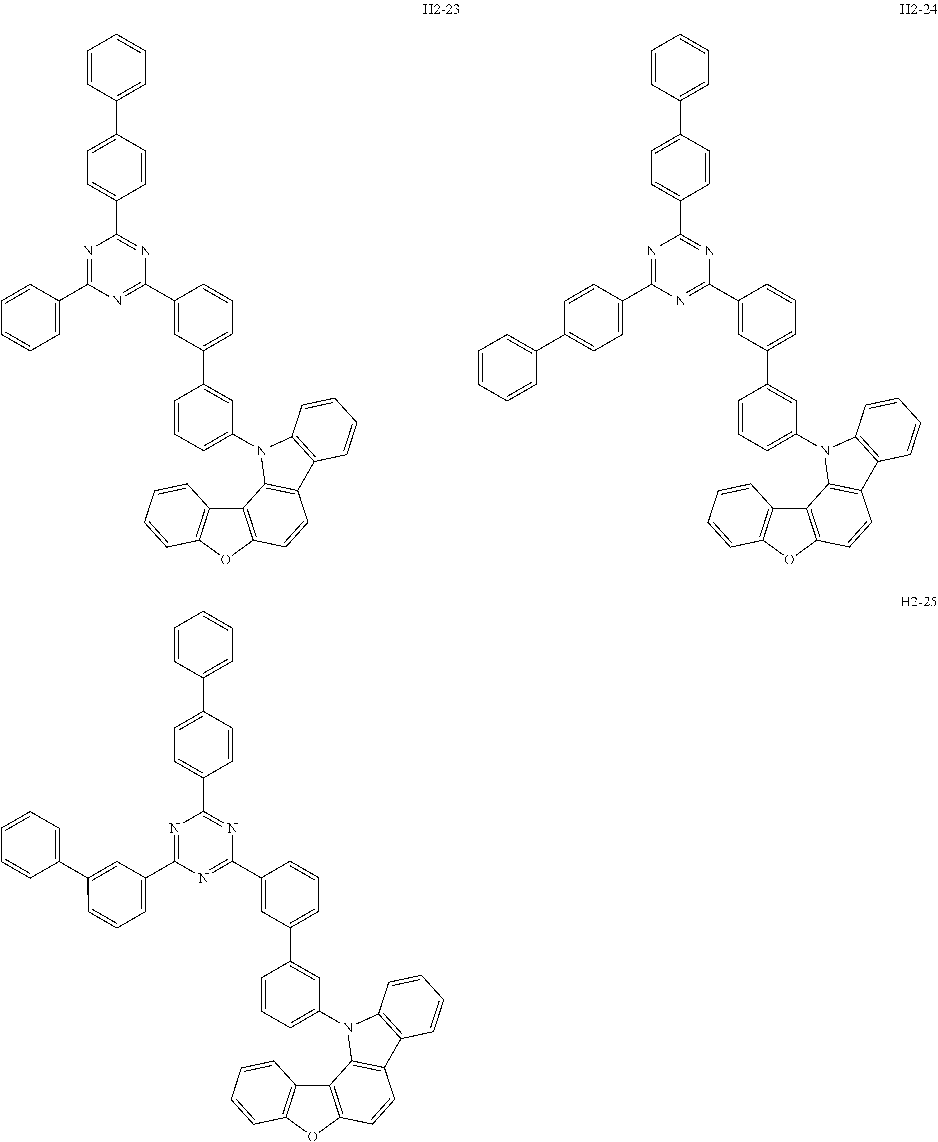 [SMILES: c1ccc(-c2ccc(-c3nc(-c4ccccc4)nc(-c4cccc(-c5cccc(-n6c7ccccc7c7ccc8oc9ccccc9c8c76)c5)c4)n3)cc2)cc1 ; c1ccc(-c2ccc(-c3nc(-c4ccc(-c5ccccc5)cc4)nc(-c4cccc(-c5cccc(-n6c7ccccc7c7ccc8oc9ccccc9c8c76)c5)c4)n3)cc2)cc1 ; c1ccc(-c2ccc(-c3nc(-c4cccc(-c5ccccc5)c4)nc(-c4cccc(-c5cccc(-n6c7ccccc7c7ccc8oc9ccccc9c8c76)c5)c4)n3)cc2)cc1]

The compound represented by Formula 1 and/or the compound represented by Formula 2 according to the present disclosure can be prepared by referring to synthetic methods known to those skilled in the art, for example, synthetic methods disclosed in Korean Patent Application Laid-Open Nos. 2015-0124902, 2021-0048735, 2013-0130236, 2012-0102374, 2023-0063852, etc., but are not limited thereto.

According to another embodiment of the present disclosure, the compound represented by Formula 11 may be included as a first dopant, and a compound including a platinum (Pt) atom unsubstituted or substituted by deuterium may be included as a second dopant.

In one embodiment, the second dopant may be represented by the following Formula 4:

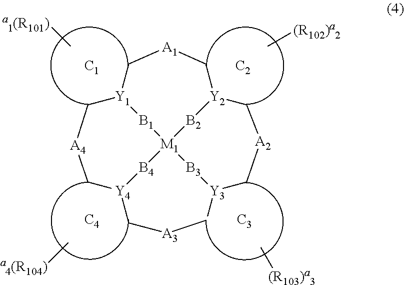

In Formula 4,
M₁ represents platinum (Pt);
rings C₁ to C₄ each independently represent (C₅-C₆₀)aryl or (5- to 60-membered)heteroaryl;
A₁ and A₄ each independently represent is absent, a single bond, —O—, —S—, —C(R₅)(R₆)—, —Si(R₅)(R₆)—, —P(R₅)(R₆)—, or —Ge(R₅)(R₆)—;
B₁ to B₄ each independently represent a single bond, —O—, or —S—;
Y₁ to Y₄ each independently represent a carbon atom (C) or a nitrogen atom (N);
R₅, R₆, and R₁₀₁ to R₁₀₄ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring; and
a₁ to a₄ each independently represent an integer ranging from 1 to 5; and when a₁ to a₄ are 2 or more, each of R₁₀₁ to each of R₁₀₄ may be the same or different.

In one embodiment, the first dopant and the second dopant can each be an emitter.

In one embodiment, the first dopant is a fluorescent emitter, the second dopant is a phosphorescent emitter, and the light-emitting layer can simultaneously emit fluorescent light emitted from the first dopant and phosphorescent light emitted from the second dopant.

In one embodiment, the first dopant is a fluorescent emitter, the second dopant is a sensitizer, and the light-emitting layer can receive energy from the second dopant and emit fluorescent light emitted from the first dopant.

Hereinafter, an organic electroluminescent device including the aforementioned host and dopant will be described with reference to the drawings.

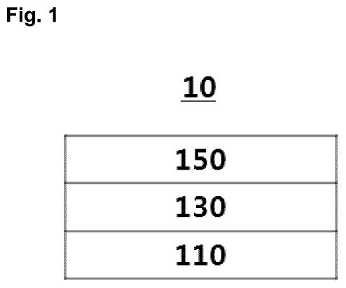

FIG. 1 illustrates a schematic structure of an organic electroluminescent device according to one embodiment.

FIG. 1 illustrates an example of an organic electroluminescent device 10 consisting of a first electrode 110 and a second electrode 150 facing each other on a substrate, and at least one light-emitting layer 130 positioned between the first electrode 110 and the second electrode 150. Specifically, an organic electroluminescent device 10 according to one embodiment may have a structure in which a first electrode 110; at least one light-emitting layer 130 positioned on the first electrode; and a second electrode 150 positioned on the light-emitting layer are sequentially laminated.

According to one embodiment, the first electrode 110 may be an anode, and the second electrode 150 may be a cathode. Herein, the first electrode 110 and the second electrode 150 may each be formed as a transmissive conductive material, a transflective conductive material, or a reflective conductive material. The organic electroluminescent device may be a top emission type, a bottom emission type, or a both-sides emission type according to the kinds of the material forming the first electrode 110 and the second electrode 150.

The at least one light-emitting layer 130 may include a host and a dopant, and preferably may include a plurality of hosts and a dopant, or may include a plurality of hosts and a plurality of dopants. The light-emitting layer 130 may include a compound represented by Formula 1 as a first host, and a compound represented by Formula 2 as a second host, respectively. Herein, the first host among the plurality of hosts may be in an amount of about 5 wt % to about 90 wt %, preferably about 10 wt % to about 90 wt %, more preferably about 10 wt % to about 80 wt %, more preferably about 15 wt % to about 70 wt %, even more preferably about 30 wt % to about 70 wt %, even more preferably about 20 wt % to about 60 wt %, and even more preferably about 30 wt % to about 60 wt %. The second host among the plurality of hosts of the present disclosure may be in an amount of about 5 wt % to about 90 wt %, preferably about 10 wt % to about 90 wt %, more preferably about 10 wt % to about 80 wt %, even more preferably about 15 wt % to about 70 wt %, even more preferably about 30 wt % to about 70 wt %, even more preferably about 20 wt % to about 60 wt %, and even more preferably about 30 wt % to about 60 wt %.

According to one embodiment, the light-emitting layer 130 may include a boron-based compound represented by Formula 11 as a first dopant, and preferably may further include a platinum-based compound unsubstituted or substituted by deuterium as a second dopant. According to one embodiment, the content of the first dopant may be smaller than the content of the second dopant. Herein, considering the lifespan of the first dopant and the second dopant and the energy transfer to the second dopant, etc., the weight ratio of the first dopant and the second dopant may be 0.1:10 to 1.0:10, for example, 0.1:10 to 0.5:10, or, for example, 0.5:10 to 1.0:10. When the weight ratio of the first dopant and the second dopant is within the above range, the efficiency and lifespan characteristics of the light-emitting element are optimized.

Although not shown, an organic electroluminescent device according to one embodiment includes a first electrode 110; a second electrode 150; and a hole transport layer, a light-emitting layer, a hole auxiliary layer, an electron-blocking layer, and a light-emitting auxiliary layer as an organic layer, in addition to a light-emitting layer 130 disposed between the first electrode and the second electrode. The organic electroluminescent device may further include at least one layer selected from a hole injection layer, an electron transport layer, an electron injection layer, an interlayer, a hole-blocking layer, and an electron buffer layer, in addition to the hole transport layer, the light-emitting layer, the hole auxiliary layer, the electron-blocking layer, and the light-emitting auxiliary layer. The organic layer may further comprise an amine-based compound and/or an azine-based compound other than the light-emitting material according to the present disclosure. Specifically, the hole injection layer, the hole transport layer, the hole auxiliary layer, the light-emitting layer, the light-emitting auxiliary layer, or the electron-blocking layer may comprise the amine-based compound, e.g., an arylamine-based compound and a styrylarylamine-based compound, etc., as a hole injection material, a hole transport material, a hole auxiliary material, a light-emitting material, a light-emitting auxiliary material, or an electron-blocking material. Also, the electron transport layer, the electron injection layer, the electron buffer layer, or the hole-blocking layer may comprise the azine-based compound as an electron transport material, an electron injection material, an electron buffer material, or a hole-blocking material. Also, the organic layer may further comprise at least one metal selected from the group consisting of metals of Group 1, metals of Group 2, transition metals of the 4^{th} period, transition metals of the 5^{th} period, lanthanides, and organic metals of the d-transition elements of the Periodic Table, or at least one complex compound comprising such a metal.

The organic electroluminescent compound according to one embodiment may be used as a light-emitting material for a white organic light-emitting device. The white organic light-emitting device has been suggested to have various structures such as a parallel side-by-side arrangement method, a stacking arrangement method, or a CCM (color conversion material) method, etc. according to the arrangement of R (red), G (green), YG (yellowish green), or B (blue) light-emitting units. In addition, the organic electroluminescent compound according to one embodiment may also be applied to the organic electroluminescent device comprising a QD (quantum dot).

A hole injection layer, a hole transport layer, an electron-blocking layer, or a combination thereof may be used between the anode 110 and the light-emitting layer 130. The hole injection layer may be a multi-layer in order to lower the hole injection barrier (or hole injection voltage) from the anode to the hole transport layer or the electron-blocking layer, wherein each of the multi-layers may use two compounds simultaneously. Also, the hole injection layer may be doped with a p-dopant. Also, the electron-blocking layer may be placed between the hole transport layer (or hole injection layer) and the light-emitting layer, and can confine the excitons within the light-emitting layer by blocking the overflow of electrons from the light-emitting layer to prevent light-emitting leakage. The hole transport layer or the electron-blocking layer may be a multi-layer, wherein each layer may use a plurality of compounds.

An electron buffer layer, a hole-blocking layer, an electron transport layer, an electron injection layer, or a combination thereof can be used between the light-emitting layer 130 and the cathode 150. The electron buffer layer may be a multi-layer in order to control the injection of the electron and improve the interfacial properties between the light-emitting layer and the electron injection layer, wherein each of the multi-layers may use two compounds simultaneously. The hole-blocking layer may be placed between the electron transport layer (or electron injection layer) and the light-emitting layer, and prevents holes from reaching the cathode, thereby improving the probability of recombination of electrons and holes in the light-emitting layer. The hole-blocking layer or the electron transport layer may also be a multi-layer, wherein each layer may use a plurality of compounds. Also, the electron injection layer may be doped with an n-dopant.

The light-emitting auxiliary layer may be placed between the anode and the light-emitting layer, or between the cathode and the light-emitting layer. When the light-emitting auxiliary layer is placed between the anode and the light-emitting layer, it can be used for promoting the hole injection and/or the hole transport, or for preventing the overflow of electrons. When the light-emitting auxiliary layer is placed between the cathode and the light-emitting layer, it can be used for promoting the electron injection and/or the electron transport, or for preventing the overflow of holes. In addition, the hole auxiliary layer may be placed between the hole transport layer (or hole injection layer) and the light-emitting layer, and may be effective to promote or block the hole transport rate (or the hole injection rate), thereby allowing control of charge balance. When an organic electroluminescent device includes two or more hole transport layers, the hole transport layer, which is further included, may be used as the hole auxiliary layer or the electron-blocking layer. The light-emitting auxiliary layer, the hole auxiliary layer, or the electron-blocking layer may have an effect of improving the efficiency and/or the lifespan of the organic electroluminescent device.

In the organic electroluminescent device of the present disclosure, preferably, at least one layer (hereinafter, “a surface layer”) selected from a chalcogenide layer, a halogenated metal layer, and a metal oxide layer may be placed on an inner surface(s) of one or both of a pair of electrodes. Specifically, a chalcogenide (including oxides) layer of silicon and aluminum is preferably placed on an anode surface of an electroluminescent medium layer, and a halogenated metal layer or a metal oxide layer is preferably placed on a cathode surface of an electroluminescent medium layer. The operation stability for the organic electroluminescent device may be obtained by the surface layer. Preferably, the chalcogenide includes SiOₓ (1≤X≤2), AlOₓ(1≤X≤1.5), SiON, SiAlON, etc.; the halogenated metal includes LiF, MgF₂, CaF₂, a rare earth metal fluoride, etc.; and the metal oxide includes Cs₂O, Li₂O, MgO, SrO, BaO, CaO, etc.

In addition, in the organic electroluminescent device of the present disclosure, a mixed region of an electron transport compound and a reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Furthermore, the hole transport compound is oxidized to a cation, and thus it becomes easier to inject and transport holes from the mixed region to the electroluminescent medium. Preferably, the oxidative dopant includes various Lewis acids and acceptor compounds, and the reductive dopant includes alkali metals, alkali metal compounds, alkaline earth metals, rare earth metals, and mixtures thereof. Also, a reductive dopant layer may be employed as a charge generation layer to prepare an organic electroluminescent device which has two or more light-emitting layers and emits white light.

The organic electroluminescent device according to one embodiment of the present disclosure may be an organic electroluminescent device having a tandem structure. In the case of a tandem organic electroluminescent device according to one embodiment, a single light-emitting unit (light-emitting unit) may be formed in a structure in which two or more units are connected by a charge generation layer. The organic electroluminescent device may include a plurality of two or more light-emitting units, for example, a plurality of three or more light-emitting units, having first and second electrodes opposed to each other on a substrate and a light-emitting layer that is stacked between the first and second electrodes and emits light in a specific wavelength range. It may include a plurality of light-emitting units, and each of the light-emitting units may include a hole transport band, a light-emitting layer, and an electron transport band, and the hole transport band may include a hole injection layer and a hole transport layer, and the electron transport band may include an electron transport layer and an electron injection layer. According to one embodiment, three or more light-emitting layers may be included in the light-emitting unit. A plurality of light-emitting units may emit the same color or different colors. Additionally, one light-emitting unit may include one or more light-emitting layers, and the plurality of light-emitting layers may be light-emitting layers of the same or different colors. It may include one or more charge generation layers located between each light-emitting unit. The charge generation layer refers to the layer in which holes and electrons are generated when voltage is applied. When there are three or more light-emitting units, a charge generation layer may be located between each light-emitting unit. Here, the plurality of charge generation layers may be the same as or different from one another. By disposing the charge generation layer between light-emitting units, current efficiency is increased in each light-emitting unit, and charges may be smoothly distributed. Specifically, the charge generation layer is provided between two adjacent stacks and can serve to drive a tandem organic electroluminescent device using only a pair of anodes and cathodes without a separate internal electrode located between the stacks.

The charge generation layer may be composed of an n-type charge generation layer and a p-type charge generation layer, and the n-type charge generation layer may be doped with an alkali metal, an alkaline earth metal, or a compound of an alkali metal and an alkaline earth metal. The alkali metal may comprise one selected from the group consisting of Li, Na, K, Rb, Cs, Fr, Yb, and combinations thereof, and the alkaline earth metal may comprise one selected from the group consisting of Be, Mg, Ca, Sr, Ba, Ra, and combinations thereof. The p-type charge generation layer may be made of a metal or an organic material doped with a p-type dopant. For example, the metal may be made of one or two or more alloys selected from the group consisting of Al, Cu, Fe, Pb, Zn, Au, Pt, W, In, Mo, Ni, and Ti. Additionally, commonly used materials may be used as the p-type dopant and host materials used in the p-type doped organic material.

The organic electroluminescent device of the present disclosure can be manufactured by forming a first electrode or a second electrode on a substrate, forming an organic layer using any one of a dry film-forming method such as vacuum deposition, sputtering, plasma, or ion plating, or a wet film-forming method such as inkjet printing, nozzle printing, slot coating, spin coating, dip coating, or flow coating, and then forming a second electrode or a first electrode thereon. When using a wet film-forming method, a thin film may be formed by dissolving or diffusing materials forming each layer into any suitable solvent such as ethanol, chloroform, tetrahydrofuran, dioxane, etc. The solvent may be any solvent where the materials forming each layer can be dissolved or diffused, and where there are no problems in film-formation capability.

When forming a layer with an organic electroluminescent material according to one embodiment, the layer can be formed via the methods listed above, and can often be formed by co-deposition or mixture-deposition. The co-deposition is a mixed deposition method in which two or more materials are put into respective individual crucible sources, and a current is applied to both cells simultaneously to evaporate the materials and to perform mixed deposition; the mixture-deposition is a mixed deposition method in which two or more materials are mixed in one crucible source before deposition, and then a current is applied to one cell to evaporate the materials.

According to one embodiment, the present disclosure can provide display devices comprising a compound according to the present disclosure as an organic electroluminescent material. In addition, by using the organic electroluminescent device of the present disclosure, display devices such as smartphones, tablets, notebooks, PCs, TVs, or display devices for vehicles, or lighting devices such as outdoor or indoor lighting can be prepared.

Hereinafter, a method for preparing a thin film comprising the compound according to the present disclosure, and its properties will be explained for a detailed understanding of the present disclosure.

### [Example 1] Preparation of a Thin Film by Co-Depositing a Host Compound According to the Present Disclosure

A thin film according to the present disclosure was manufactured. First, a glass substrate was subjected to an ultrasonic washing with acetone and isopropyl alcohol, sequentially, and was thereafter stored in isopropyl alcohol and then used. Thereafter, the glass substrate was mounted on a substrate holder of a vacuum vapor deposition apparatus. Each of the first host compound and the second host compound described in Table 1 below was introduced into two cells of the vacuum vapor deposition apparatus as a host, and Compound D-1 was introduced into another cell as a dopant. The two host materials were then evaporated at a rate of 1:1, and at the same time, the dopant was evaporated at a different rate, and the dopant was deposited in a doping amount of 2 wt % based on the total amount of the hosts and the dopant to form a light-emitting layer having a thickness of 20 nm. Each of the compounds used for all of the materials were purified by vacuum sublimation at 10⁻⁶ Torr. The deposited thin film was subjected to a glass encapsulation process to prevent degeneration by oxygen and moisture.

### [Comparative Example 1] Preparation of a Thin Film Comprising a Comparative Compound as a Host

A thin film was fabricated in the same manner as in Example 1, except that each of the first host compound and the second host compound described in Table 1 below was used as a host for the light-emitting layer.

The optical properties of the thin film devices of Example 1 and Comparative Example 1 prepared as described above were evaluated as follows.

### [Evaluation Method 1]

The photoluminescence (PL) spectrum was measured using a Jasco FP-8300 fluorescence spectrometer. The experimental conditions for measuring thin film photoluminescence were conducted under the same excitation slit conditions and detection slit conditions. Herein, the solid sample holder of FLH-809 (JASCO) was used as the thin film photoluminescence holder.

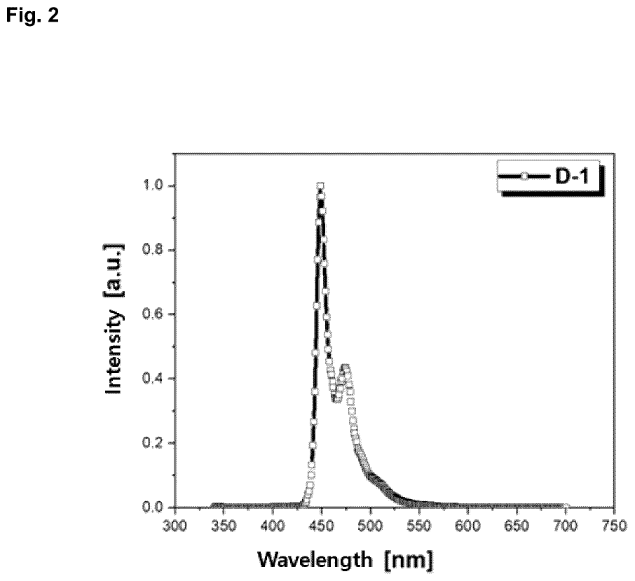

As a result, as shown in FIG. 2, it was confirmed that the maximum emission wavelength of dopant D-1 was 457 nm. Based on the above, the maximum PL intensity at 457 nm was measured in the photoluminescence results of Example 1 and Comparative Example 1, and the results are shown in Table 1 below.

TABLE 1

| | | | PL | Emission Wavelength |
|---|---|---|---|---|
| | First | Second | Intensity | of the Measurement |
| | Host | Host | (a.u.) | Standard (nm) |
| Example 1 | C-27 | H2-1 | 3442 | 457 |
| Comparative | R-H1 | R-H2 | 451 | 457 |
| Example 1 | | | | |

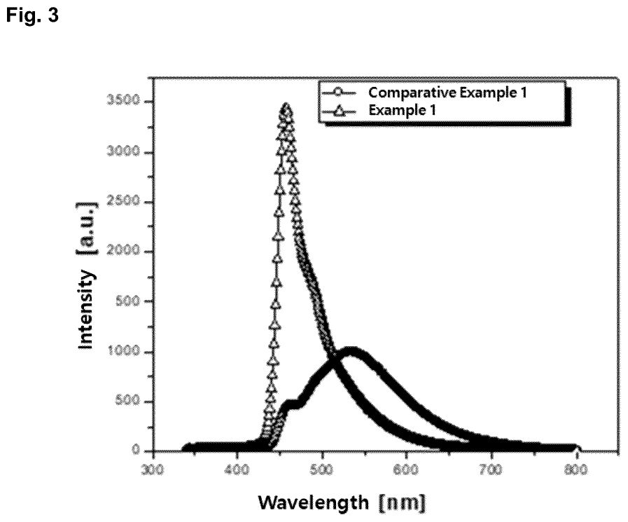

As shown in Table 1 and FIG. 3, the organic electroluminescent device comprising a specific combination of compounds as a host, according to the present disclosure, exhibits significantly superior higher luminous efficiency compared to the organic electroluminescent device comprising a conventional host compound.

### [Evaluation Method 2]

The triplet (T₁) energy levels of the second host and dopant used in Example 1 and Comparative Example 1 were simulated by TO-OFT (time-dependent density functional theory) calculations using the Gaussian program, and the evaluation results are presented in Table 2 below. The structure was optimized at the B3LYP, 6-31G (d,p) level.

TABLE 2

| | Triplet (T₁) Energy | | Triplet (T₁) Energy |
|---|---|---|---|
| | Level (eV) of | | Level (eV) of |
| | Second Host | | Dopant (D-1) |
| Example 1 | H2-1 | 3.06 | 2.61 |
| Comparative | R-H2 | 2.72 | 2.61 |
| Example 1 | | | |

As shown in Table 2 above, it was confirmed that as the triplet (T₁) energy level of the second host became higher than the triplet (T₁) energy level of the dopant, the energy transfer became easier, and thus the luminescence became more effective.

### [Examples 2 and 3] Preparation of a Thin Film by Co-Depositing a Host Compound According to the Present Disclosure

A thin film was fabricated in the same manner as in Example 1, except that the respective first and second host compounds described in Table 3 below were used in the light-emitting layer.

The optical properties of the thin film devices of Examples 2 and 3 and Comparative Example 1 prepared as described above were evaluated as follows.

### [Evaluation Method 3]

The photoluminescence (PL) spectrum was measured using a Jasco FP-8650 fluorescence spectrometer. The experimental conditions for measuring thin film photoluminescence were conducted under the same excitation slit conditions and detection slit conditions. Herein, the solid sample holder of FLH-809 (JASCO) was used as the thin film photoluminescence holder.

As a result, as shown in FIG. 2, it was confirmed that the maximum emission wavelength of dopant D-1 was 457 nm. Based on the above, the maximum PL intensity at 457 nm was measured in the photoluminescence results of Examples 2 and 3 and Comparative Example 1, and the results are shown in Table 3 below.

TABLE 3

| | | | PL | Emission Wavelength |
|---|---|---|---|---|
| | First | Second | Intensity | of the Measurement |
| | Host | Host | (a.u.) | Standard (nm) |
| Example 2 | C-26 | H2-1 | 1238 | 457 |
| Example 3 | C-26 | H2-6 | 927 | 457 |
| Comparative | R-H1 | R-H2 | 172 | 457 |
| Example 1 | | | | |

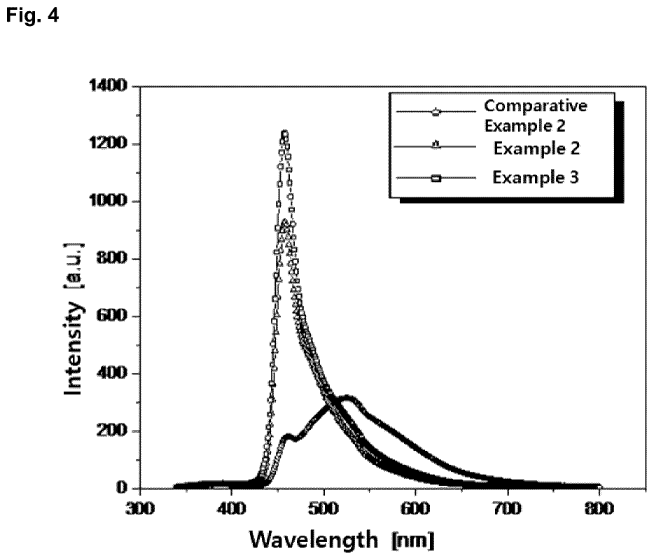

As shown in Table 3 and FIG. 4, the organic electroluminescent device comprising a specific combination of host compounds according to the present disclosure exhibits significantly superior higher luminous efficiency than an organic electroluminescent device comprising conventional host compounds.

### [Evaluation Method 4]

The triplet (T₁) energy levels of the second host and dopant used in Example 3 and Comparative Example 1 were simulated using the TO-OFT (time-dependent density functional theory) method in the Gaussian program, and the evaluation results are shown in Table 4 below. The structure was optimized at the B3LYP, 6-31G (d,p) level.

TABLE 4

| | Triplet (T₁) Energy | | Triplet (T₁) Energy |
|---|---|---|---|
| | Level (eV) of | | Level (eV) of |
| | Second Host | | Dopant (D-1) |
| Example 3 | H2-6 | 2.96 | 2.61 |
| Comparative | R-H2 | 2.72 | 2.61 |
| Example 1 | | | |

As shown in Table 4 above, it was confirmed that the higher the triplet (T₁) energy level of the second host compared to that of the dopant, the more efficient the energy transfer, resulting in more effective luminescence.

The compounds used in the Examples and the Comparative Example are specifically shown in Table 5 below.

TABLE 5

| | |
|---|---|
| Light-Emitting Layer | 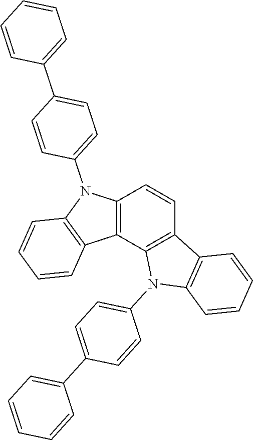 [SMILES: c1ccc(-c2ccc(-n3c4ccccc4c4c3ccc3c5ccccc5n(-c5ccc(-c6ccccc6)cc5)c34)cc2)cc1] |
| | n = 0 |
| | C-27 |
| | 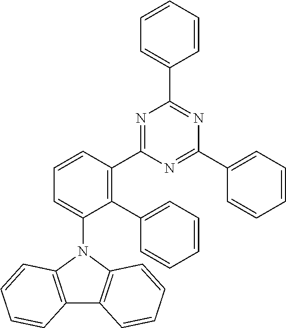 [SMILES: c1ccc(-c2nc(-c3ccccc3)nc(-c3cccc(-n4c5ccccc5c5ccccc54)c3-c3ccccc3)n2)cc1] |
| | H2-1 |
| | 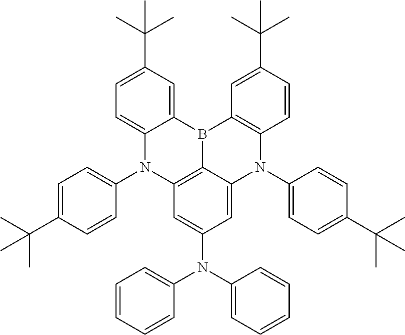 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | D-1 |
| | 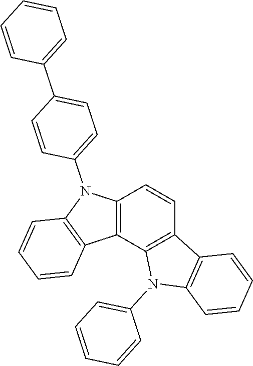 [SMILES: c1ccc(-c2ccc(-n3c4ccccc4c4c3ccc3c5ccccc5n(-c5ccccc5)c34)cc2)cc1] |
| | n = 0 |
| | C-26 |
| | 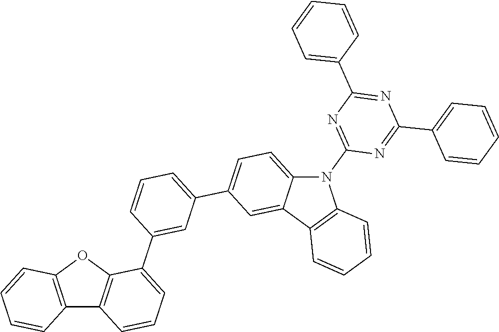 [SMILES: c1ccc(-c2nc(-c3ccccc3)nc(-n3c4ccccc4c4cc(-c5cccc(-c6cccc7c6oc6ccccc67)c5)ccc43)n2)cc1] |
| | H2-6 |
| | 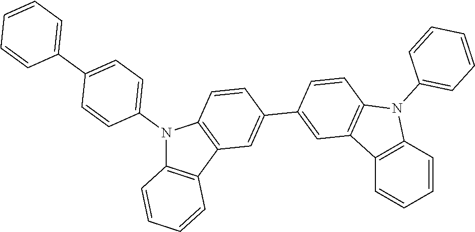 [SMILES: c1ccc(-c2ccc(-n3c4ccccc4c4cc(-c5ccc6c(c5)c5ccccc5n6-c5ccccc5)ccc43)cc2)cc1] |
| | R-H1 |
| | 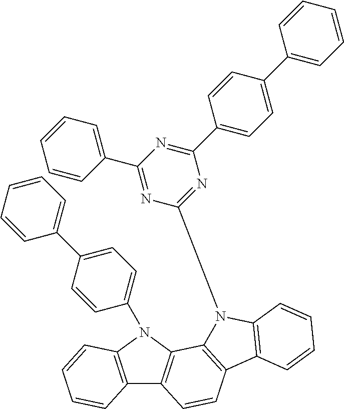 [SMILES: c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1] |
| | R-H2 |

### [Device Examples 1 and 2] Preparation of OLEDs by Depositing a Compound According to the Present Disclosure as a Host

OLEDs according to the present disclosure were prepared. First, a transparent electrode indium tin oxide (ITO) thin film on a glass substrate for an OLED (GEOMATEC CO., LTD., Japan) was subjected to an ultrasonic washing with acetone and isopropyl alcohol, sequentially, and thereafter was stored in isopropyl alcohol and then used. Thereafter, the ITO substrate was mounted on a substrate holder of a vacuum vapor deposition apparatus. Compound HI-1 shown in Table 2 was then introduced into a cell of the vacuum vapor deposition apparatus, and Compound HT-1 was introduced into another cell. The two materials were evaporated at different rates, and Compound HI-1 was deposited in a doping amount of 3 wt % based on the total amount of Compound HI-1 and Compound HT-1 to form a hole injection layer having a thickness of 10 nm. Compound HT-1 was then deposited as a first hole transport layer having a thickness of 80 nm on the hole injection layer, and Compound HT-2 was thereafter introduced into another cell of the vacuum vapor deposition apparatus and was evaporated by applying an electric current to the cell, thereby forming a second hole transport layer having a thickness of 6 nm on the first hole transport layer. After formation of the hole injection layer and the hole transport layers, a light-emitting layer was formed thereon as follows: The host compounds described in Table 6 below were introduced into two cells of the vacuum vapor deposition apparatus as a host, and Compound D-1 was introduced into another cell as a dopant. The two host compounds were evaporated at a ratio of 1:1, and at the same time, the dopant compound was evaporated at a different rate and was deposited in a doping amount of 2 wt % based on the total amount of the hosts and dopant to form a light-emitting layer having a thickness of 20 nm on the second hole transport layer. Compound ET-1 and Compound EI-1 were then deposited at a weight ratio of 50:50 to form an electron transport layer having a thickness of 35 nm on the light-emitting layer, and subsequently Compound EI-1 was evaporated to form an electron injection layer having a thickness of 2 nm on the electron transport layer. Thereafter, an AI cathode having a thickness of 80 nm was deposited on the electron injection layer by another vacuum vapor deposition apparatus. Thus, OLEDs were produced. Each of the compounds used for all of the materials were purified by vacuum sublimation at 10⁻⁶ Torr.

### [Device Comparative Example 1] Preparation of an OLED Comprising a Conventional Compound as a Host

An OLED was fabricated in the same manner as in Device Example 1, except that the host compounds of Table 6 below were used as hosts for the light-emitting layer.

The luminous efficiency at a luminance of 1,000 nits, external quantum efficiency (EQE), and color coordinates of the OLEDs of Device Examples 1 and 2 and Device Comparative Example 1 produced as described above were measured, and the results thereof are shown in Table 6 below.

TABLE 6

| | | Luminous | | Color |
|---|---|---|---|---|
| | | Efficiency | | Coordinate |
| | Host | [cd/A] | EQE | [CIE x, y] |
| Device Example 1 | C26:H2-1 | 14.4 | 8.7 | 0.157, 0.227 |
| Device Example 2 | C26:H2-6 | 10.9 | 6.1 | 0.169, 0.242 |
| Device | R-H1:R-H2 | 9.8 | 3.6 | 0.270, 0.465 |
| Comparative | | | | |
| Example 1 | | | | |

From Table 6 above, it can be confirmed that the organic electroluminescent device comprising the host compounds according to the present disclosure exhibits significantly improved luminous efficiency and external quantum efficiency compared to that comprising conventional host compounds. Accordingly, the organic electroluminescent device of the present disclosure is expected to exhibit excellent characteristics in terms of energy efficiency and may be advantageously used in realizing high-efficiency organic electroluminescent devices.

The compounds used in the Device Examples and Device Comparative Example are specifically shown in Table 7 below.

TABLE 7

| | |
|---|---|
| Hole Injection Layer/ Hole Transport Layer | 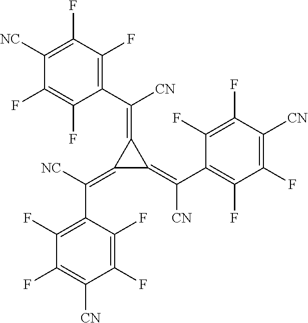 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F] |
| | HI-1 |
| | 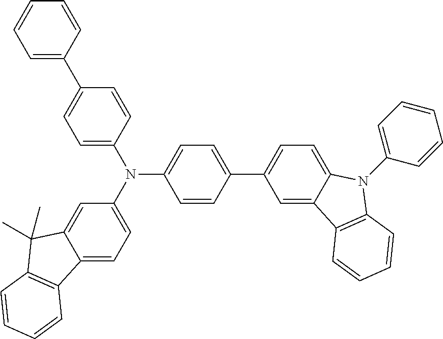 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21] |
| | HT-1 |
| | 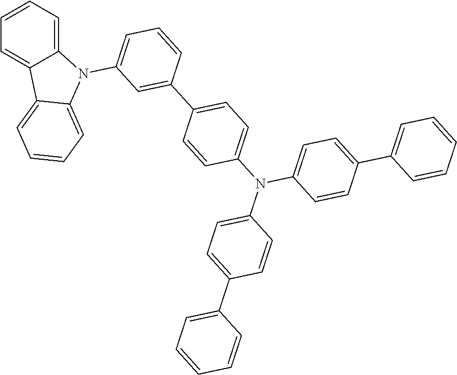 [SMILES: c1ccc(-c2ccc(N(c3ccc(-c4ccccc4)cc3)c3ccc(-c4cccc(-n5c6ccccc6c6ccccc65)c4)cc3)cc2)cc1] |
| | HT-2 |
| Light-Emitting Layer | 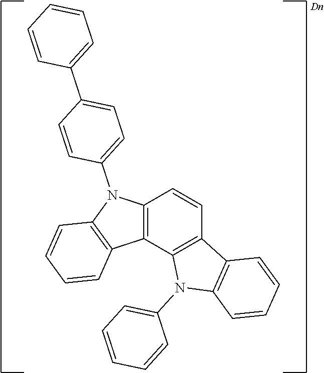 |
| | n = 0 |
| | C-26 |
| | 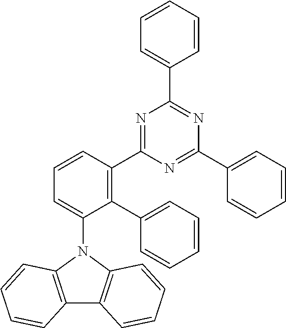 [SMILES: c1ccc(-c2nc(-c3ccccc3)nc(-c3cccc(-n4c5ccccc5c5ccccc54)c3-c3ccccc3)n2)cc1] |
| | H2-1 |
| | 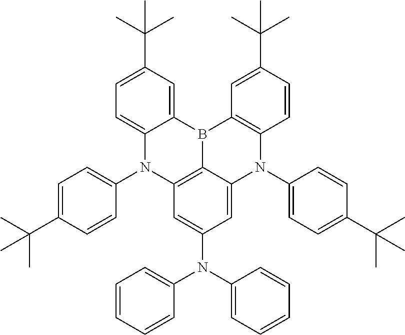 [SMILES: CC(C)(C)c1ccc(N2c3ccc(C(C)(C)C)cc3B3c4cc(C(C)(C)C)ccc4N(c4ccc(C(C)(C)C)cc4)c4cc(N(c5ccccc5)c5ccccc5)cc2c43)cc1] |
| | D-1 |
| | 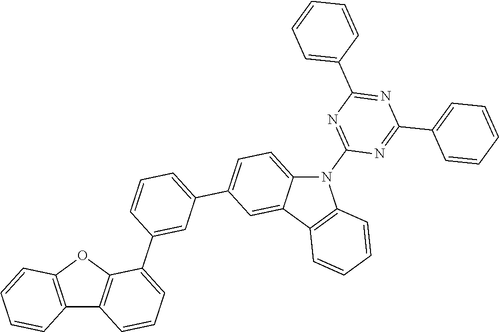 [SMILES: c1ccc(-c2nc(-c3ccccc3)nc(-n3c4ccccc4c4cc(-c5cccc(-c6cccc7c6oc6ccccc67)c5)ccc43)n2)cc1] |
| | H2-6 |
| | 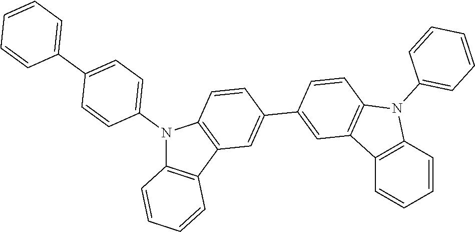 [SMILES: c1ccc(-c2ccc(-n3c4ccccc4c4cc(-c5ccc6c(c5)c5ccccc5n6-c5ccccc5)ccc43)cc2)cc1] |
| | R-H1 |
| | 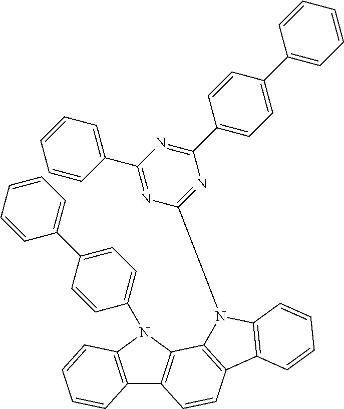 [SMILES: c1ccc(-c2ccc(-c3nc(-c4ccccc4)nc(-n4c5ccccc5c5ccc6c7ccccc7n(-c7ccc(-c8ccccc8)cc7)c6c54)n3)cc2)cc1] |
| | R-H2 |
| Electron Transport Layer/Electron Injection Layer | 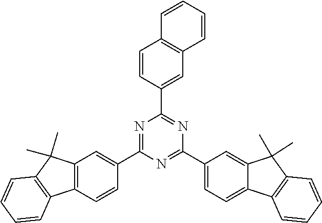 [SMILES: CC1(C)c2ccccc2-c2ccc(-c3nc(-c4ccc5c(c4)C(C)(C)c4ccccc4-5)nc(-c4ccc5ccccc5c4)n3)cc21] |
| | ET-1 |
| | 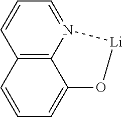 |
| | EI-1 |

### DESCRIPTION OF SYMBOLS

10: Organic electroluminescent device
110: First electrode
130: Light-emitting layer
150: Second electrode

1. An organic electroluminescent device comprising: a first electrode; a second electrode; and a light-emitting layer positioned between the first electrode and the second electrode, wherein the light-emitting layer comprises a host and a dopant, wherein the host comprises a compound represented by the following Formula 1, and wherein the dopant comprises a compound containing a boron (B) atom: 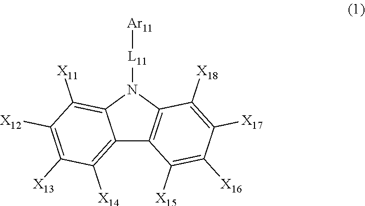
wherein,
an adjacent pair(s) in X₁₅ to X₁₈ is(are) liked to [symbol] in the following Formula 1-A: 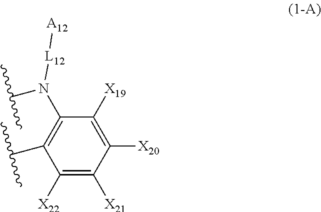
wherein,
X₁₁ to X₁₄, X₁₅ to X₁₈ that are not linked to form a ring(s), and X₁₉ to X₂₂ each independently represent hydrogen, deuterium, a substituted or unsubstituted (C₆-C₃₀)alkyl, a substituted or unsubstituted (C₆-C₃₀)cycloalkyl, a substituted or unsubstituted (C₆-C₃₀)aryl, a substituted or unsubstituted (3- to 30-membered)heteroaryl, or a combination thereof;
L₁₁ and L₁₂ each independently represent a single bond or a substituted or unsubstituted (C₆-C₃₀)arylene; and
Ar₁₁ and Ar₁₂ each independently represent a substituted or unsubstituted (C₆-C₃₀)aryl, a substituted or unsubstituted (3- to 30-membered)heteroaryl having hole-transporting properties, or a combination thereof.

2. The organic electroluminescent device according to claim 1, wherein the compound represented by Formula 1 is represented by any one of the following Formulas 1-1 to 1-6: 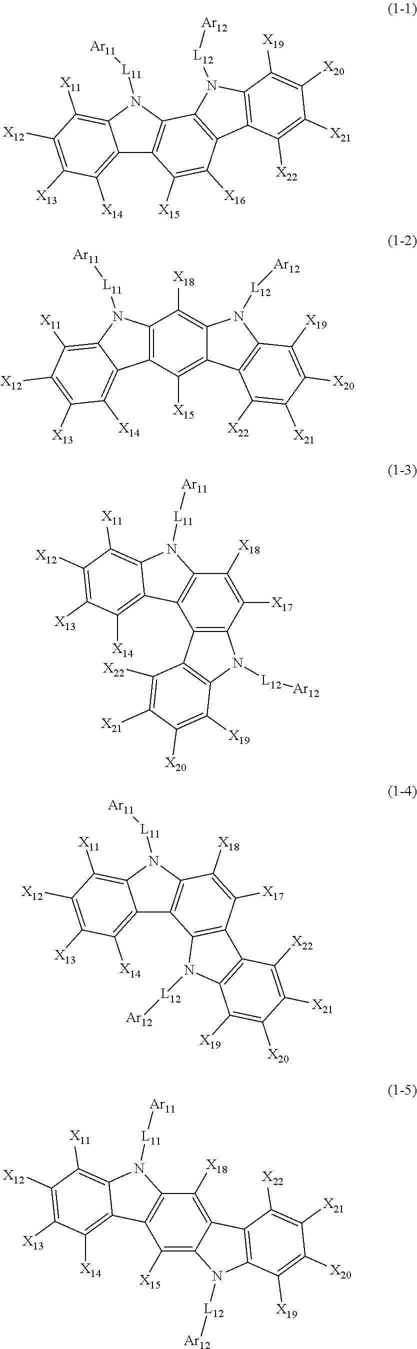 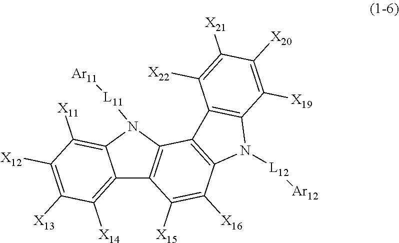
wherein,
Ar₁₁, Ar₁₂, L₁₁, L₁₂, and X₁₁ to X₂₂ are as defined in claim 1.

3. The organic electroluminescent device according to claim 1, wherein at least one of X₁₁ to X₂₂ is deuterium.

4. The organic electroluminescent device according to claim 1, wherein the substituted or unsubstituted (3- to 30-membered)heteroaryl having hole-transporting properties is a substituted or unsubstituted carbazolyl, a substituted or unsubstituted dibenzofuranyl, or a substituted or unsubstituted dibenzothiophenyl.

5. The organic electroluminescent device according to claim 1, wherein the compound represented by Formula 1 is selected from the following compounds: 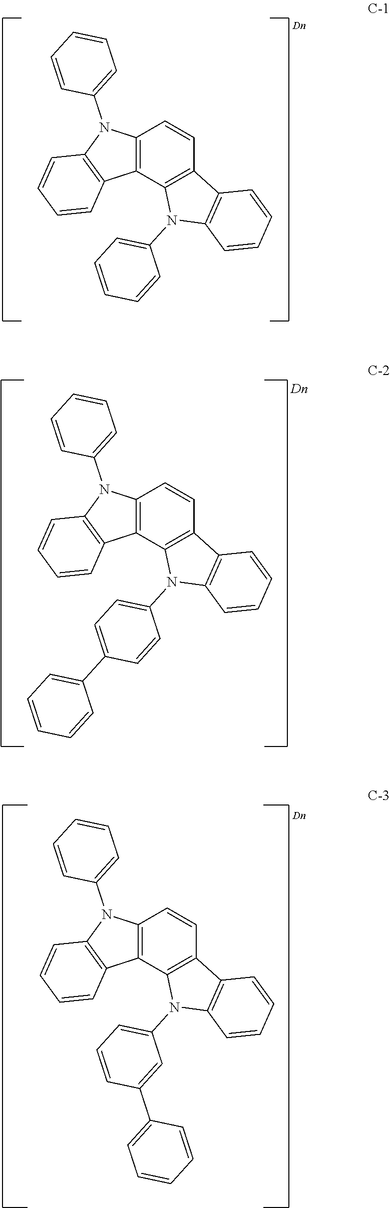 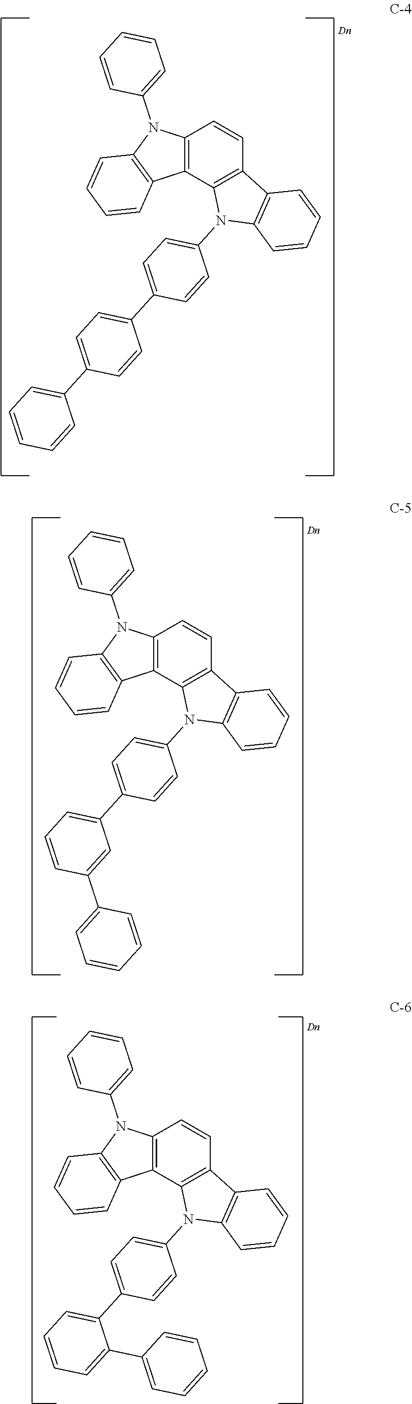 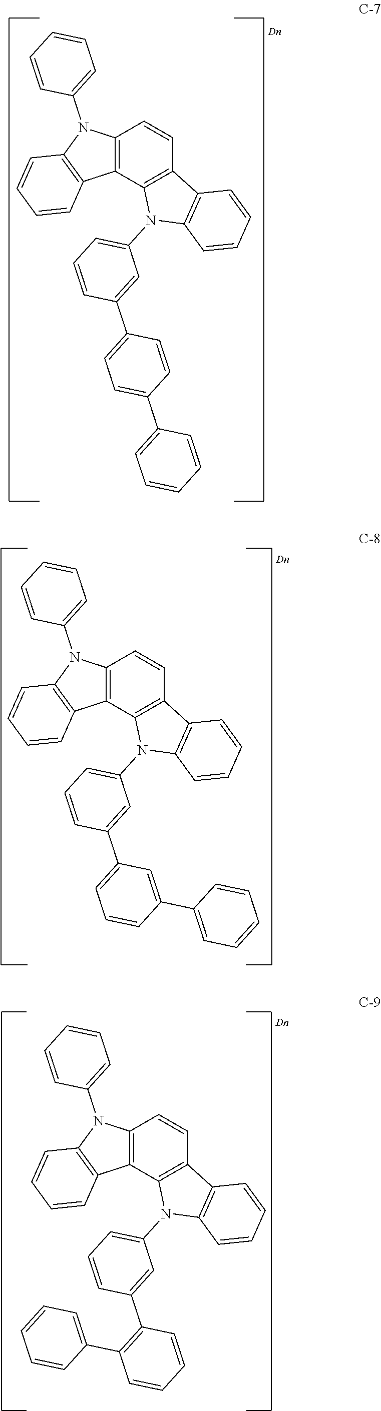 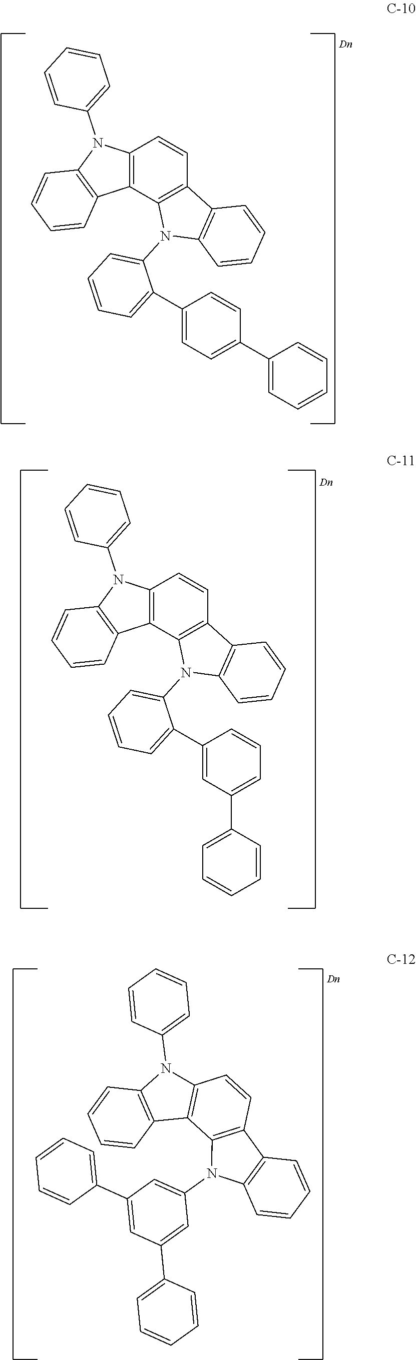 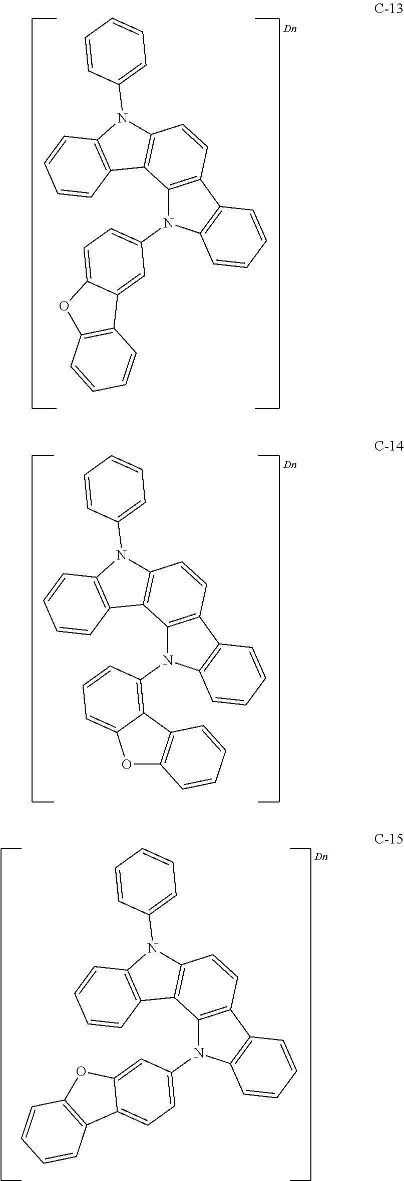 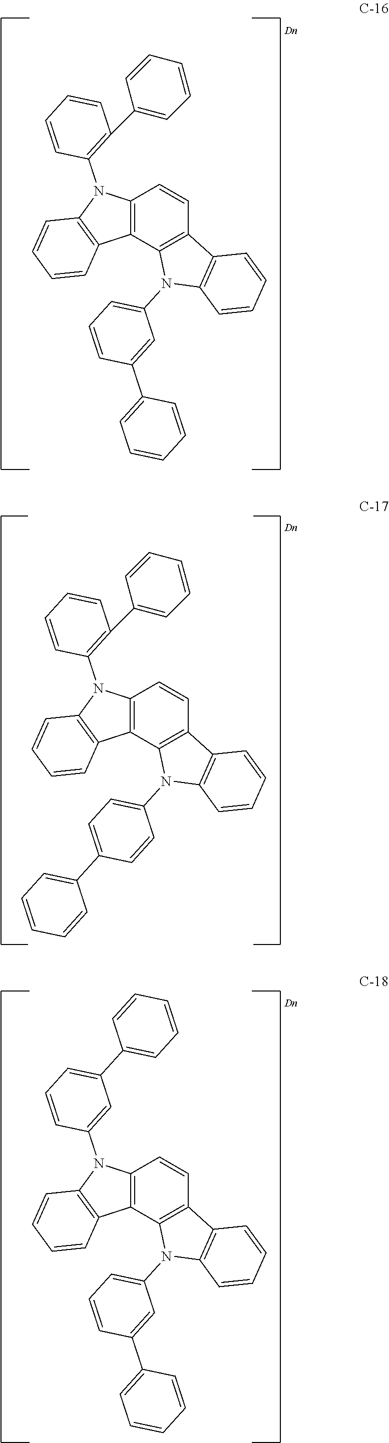 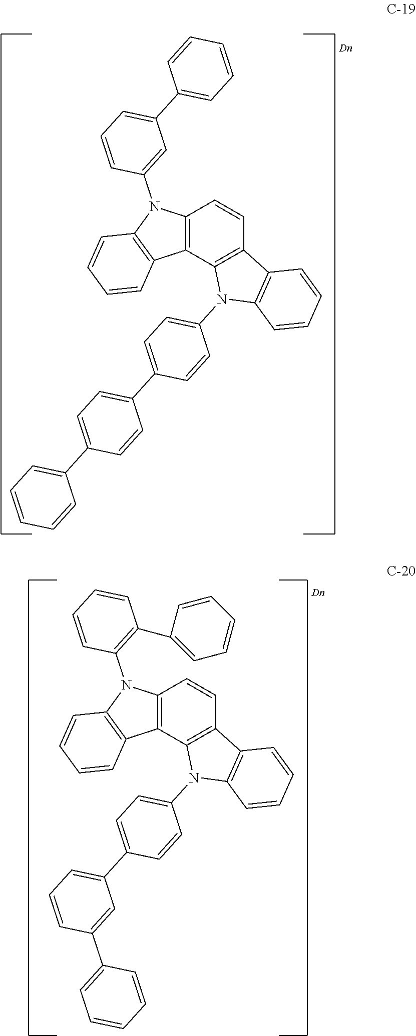 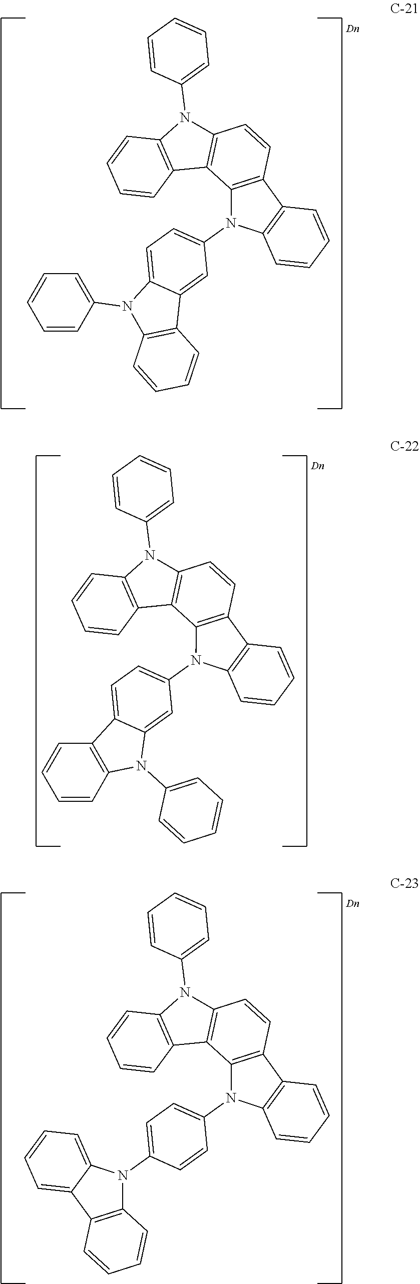 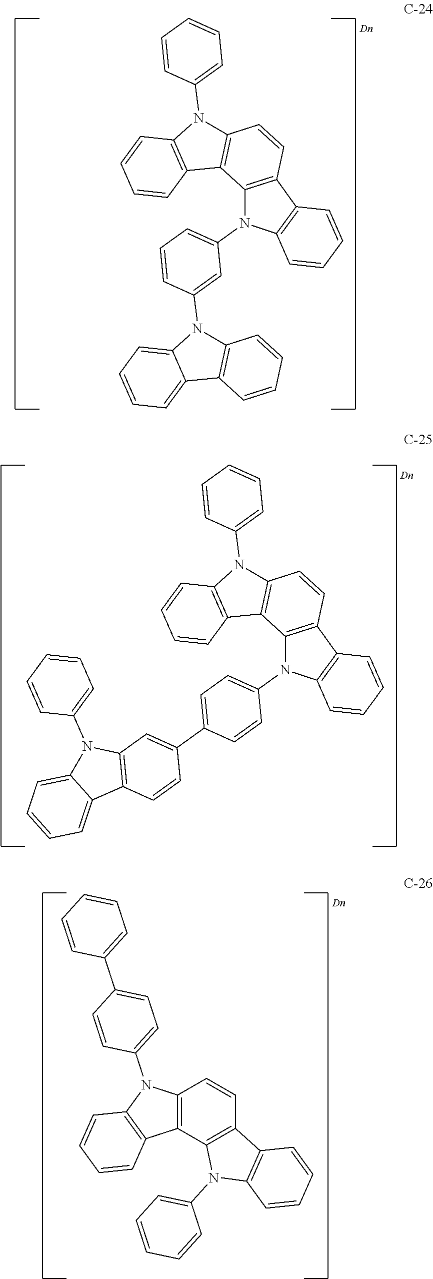 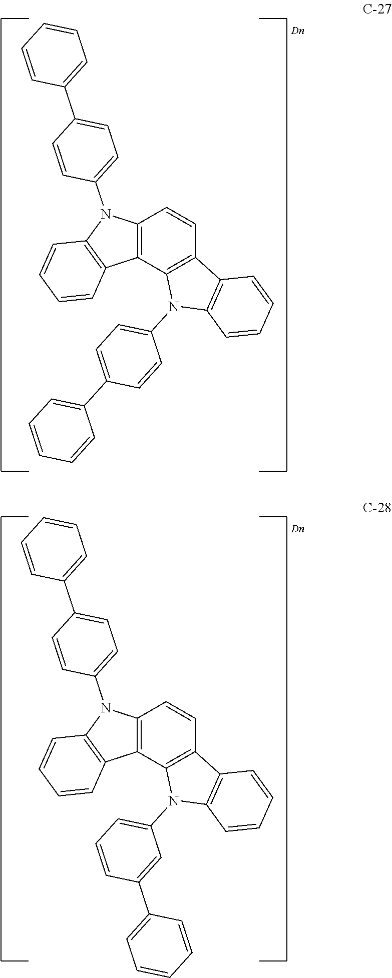 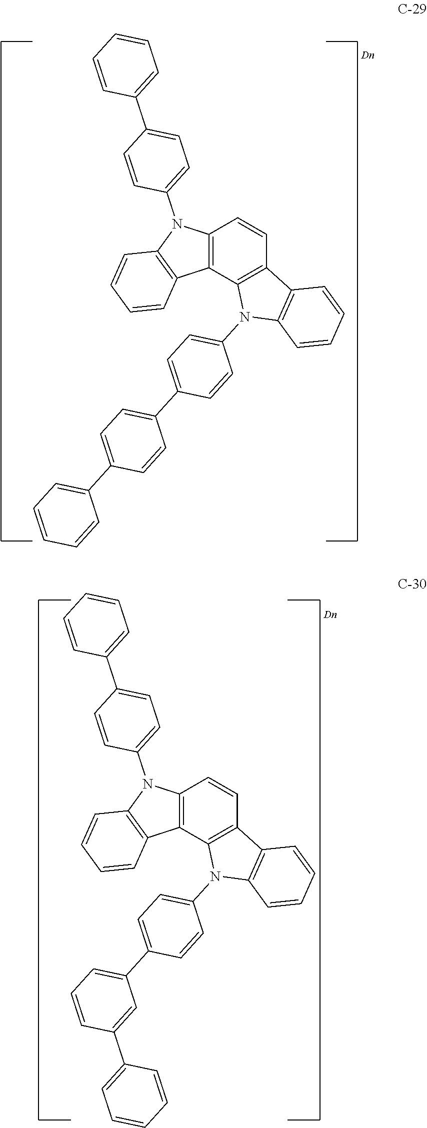 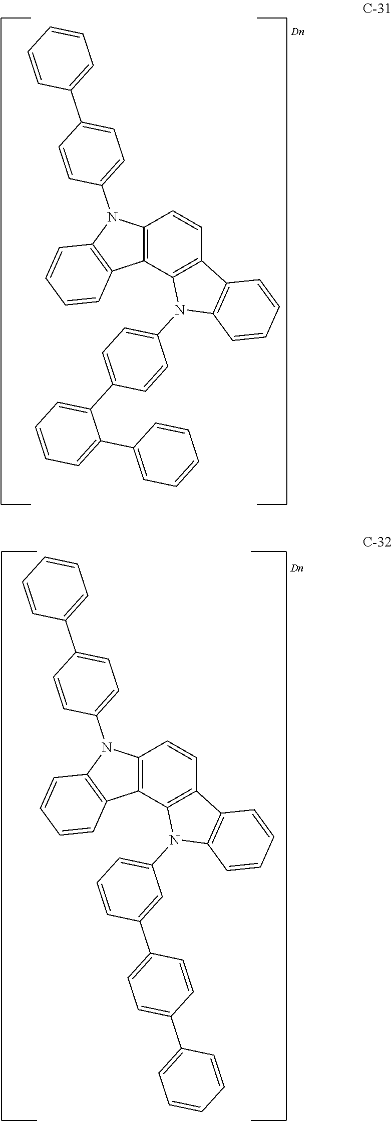 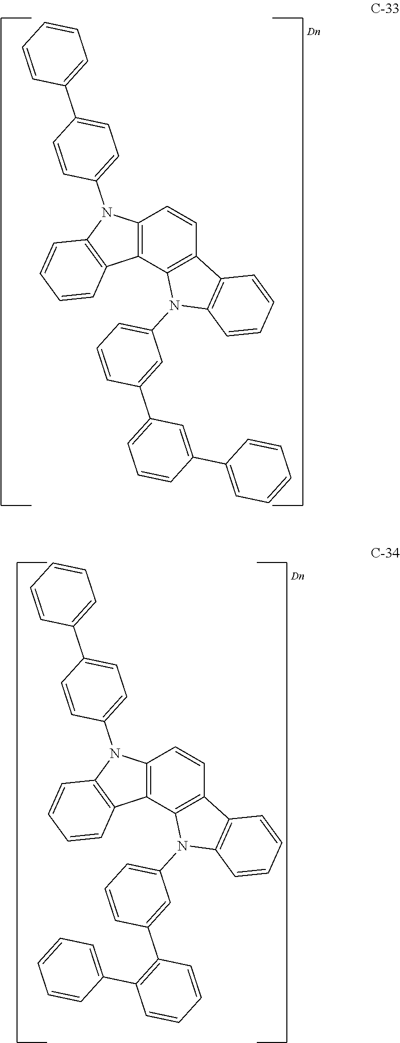 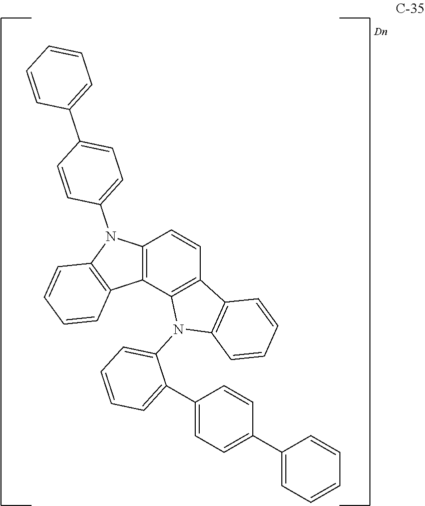 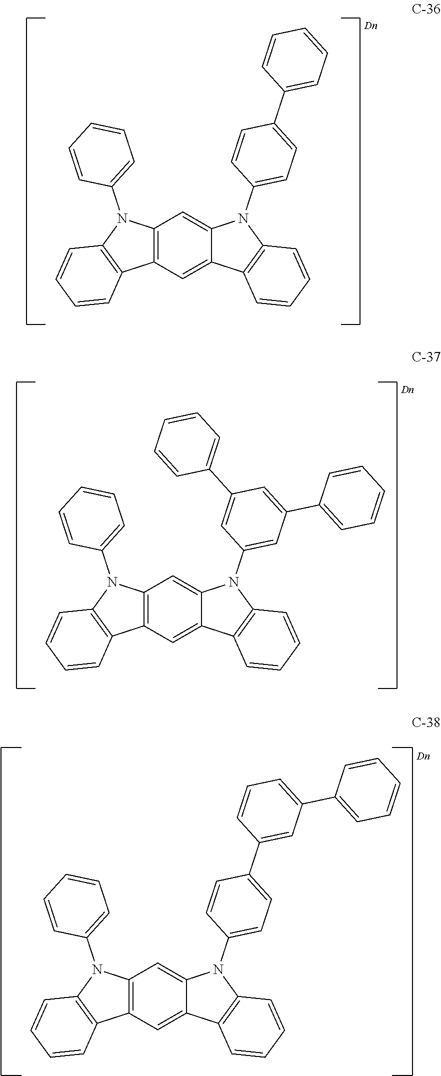 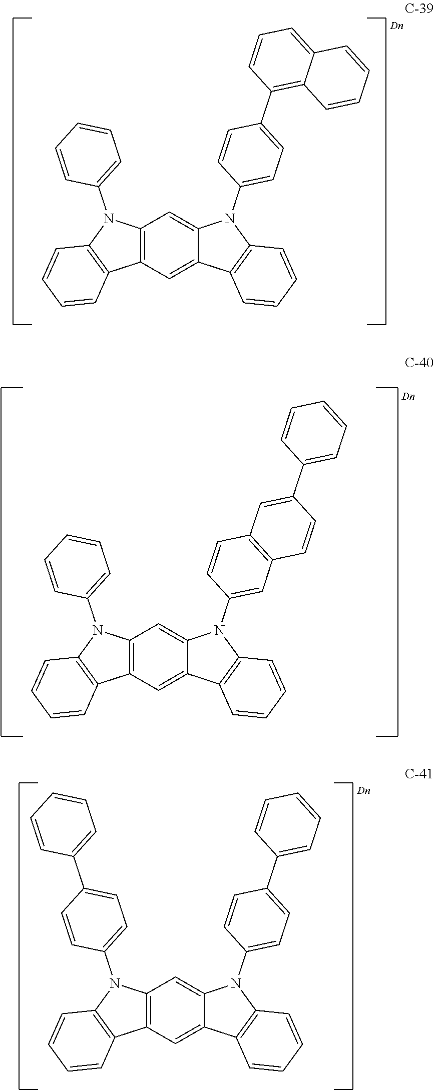 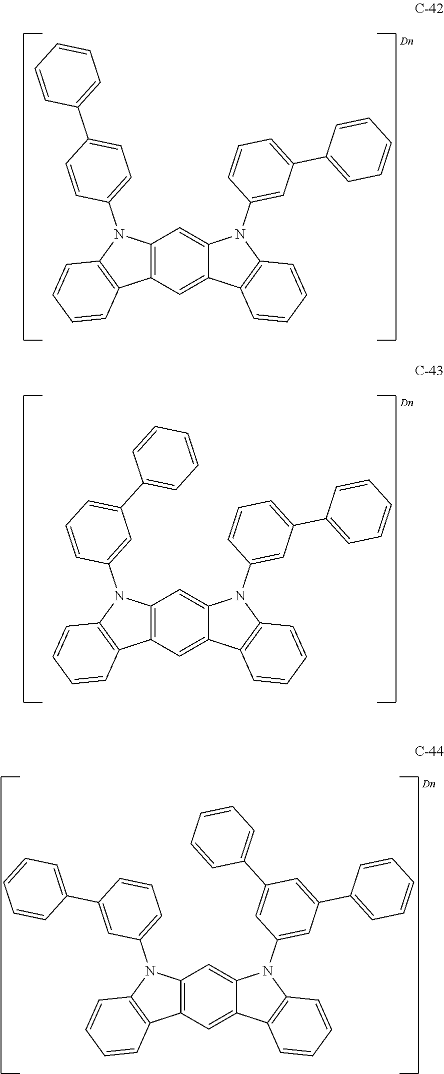 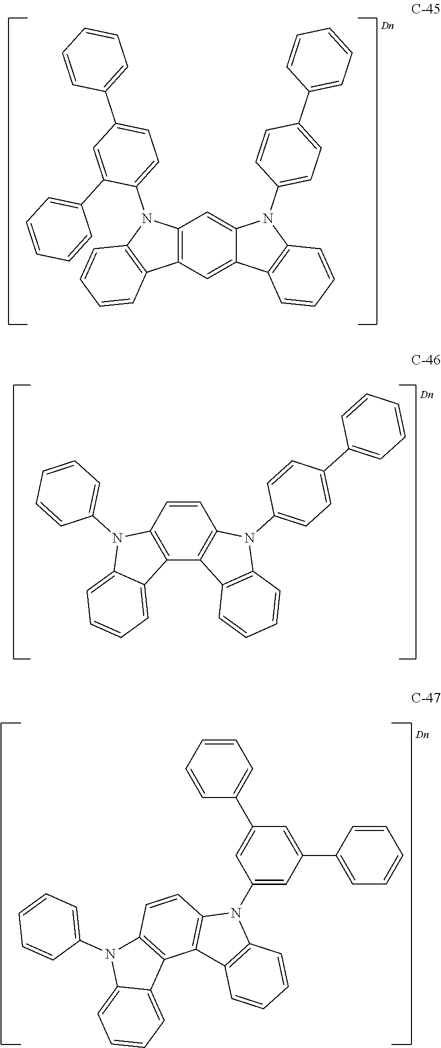 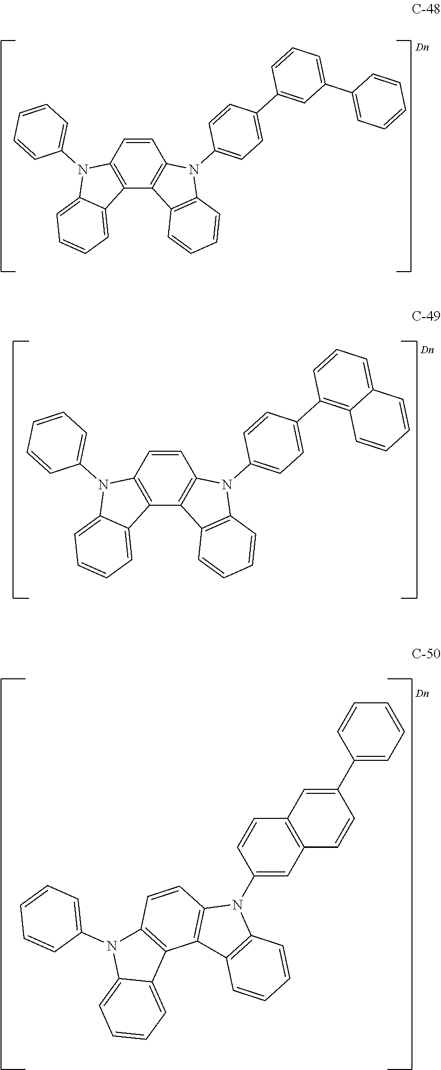 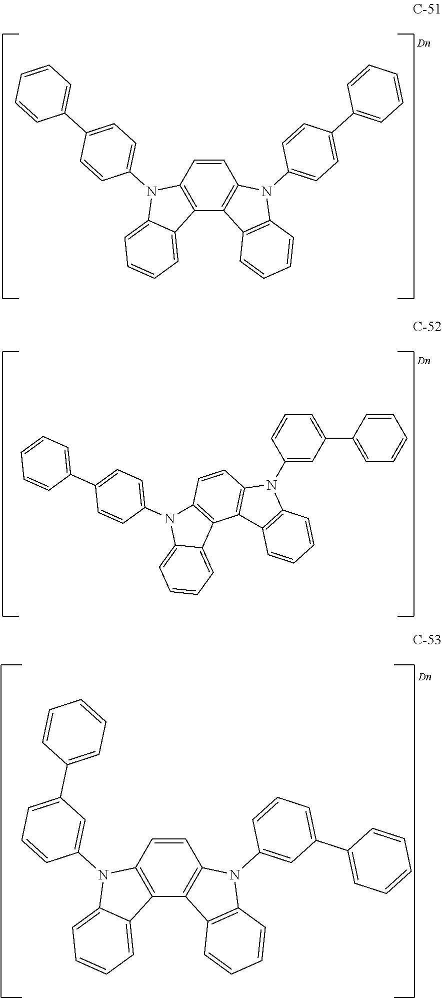 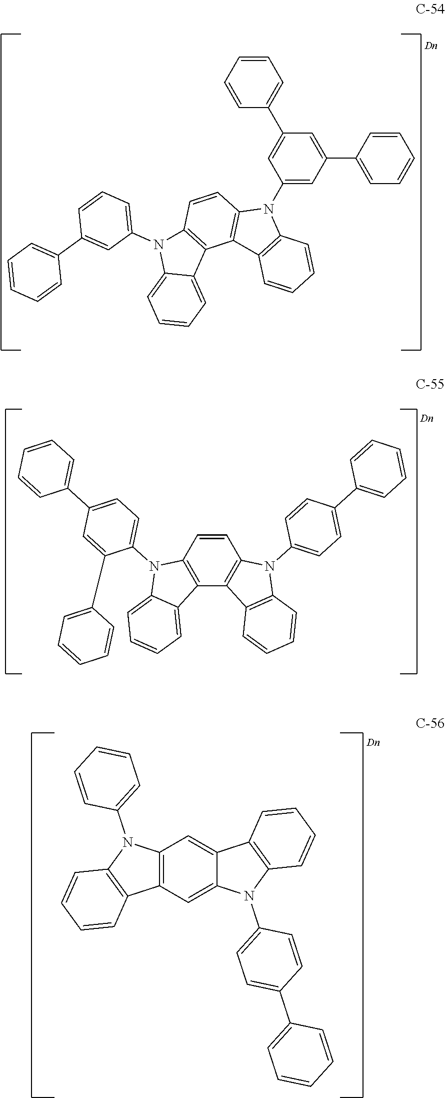 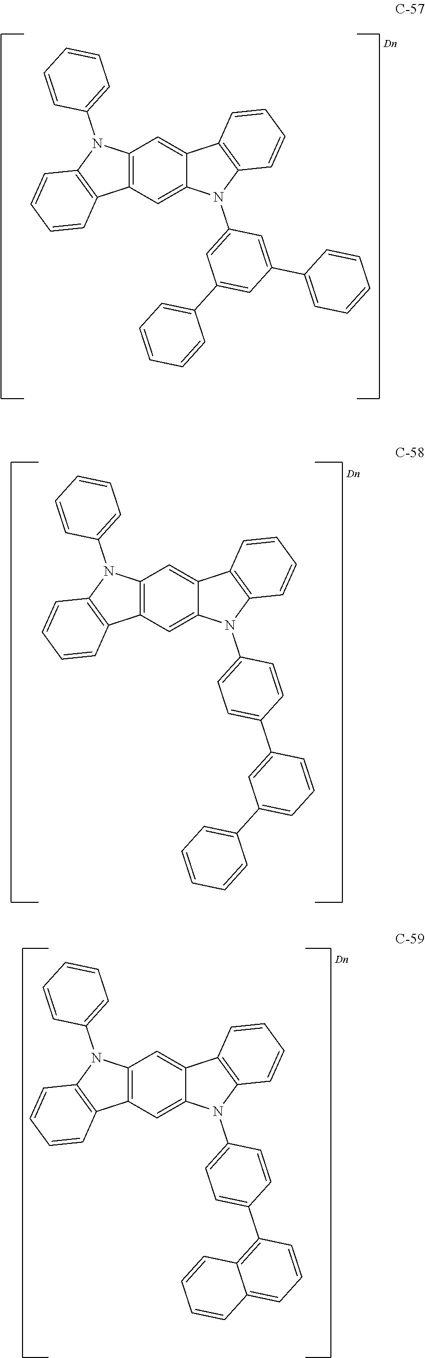 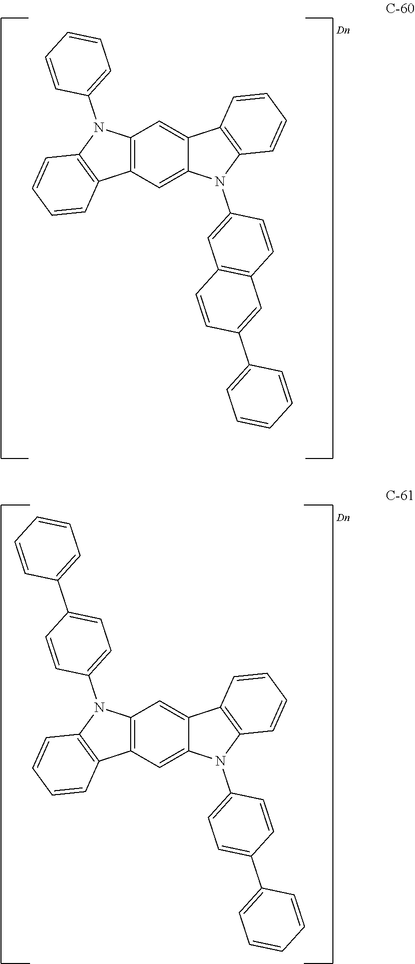 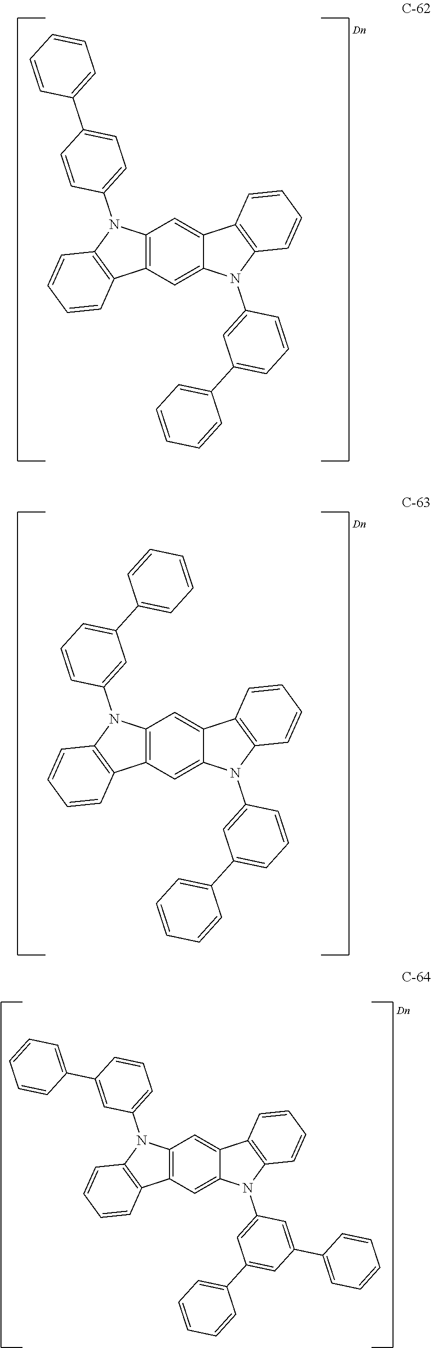 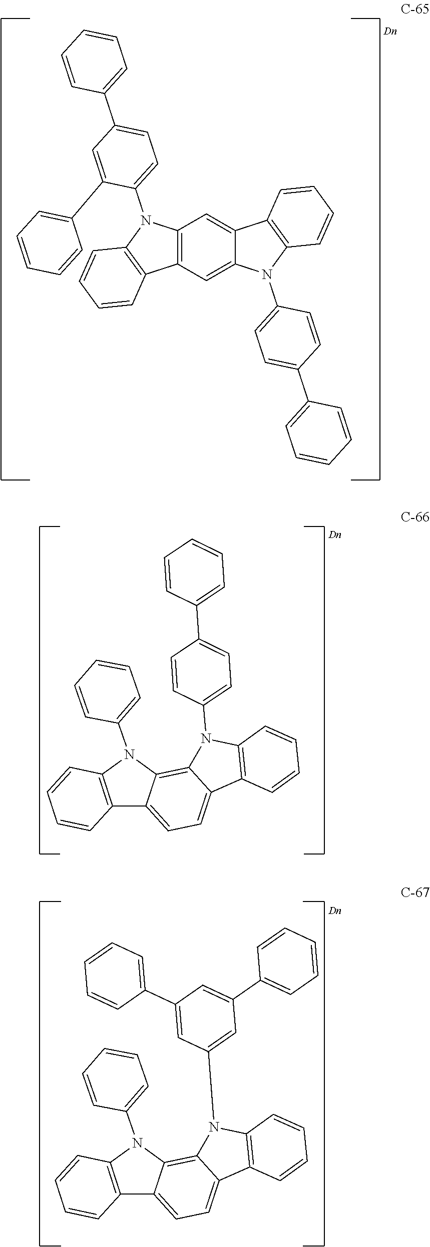 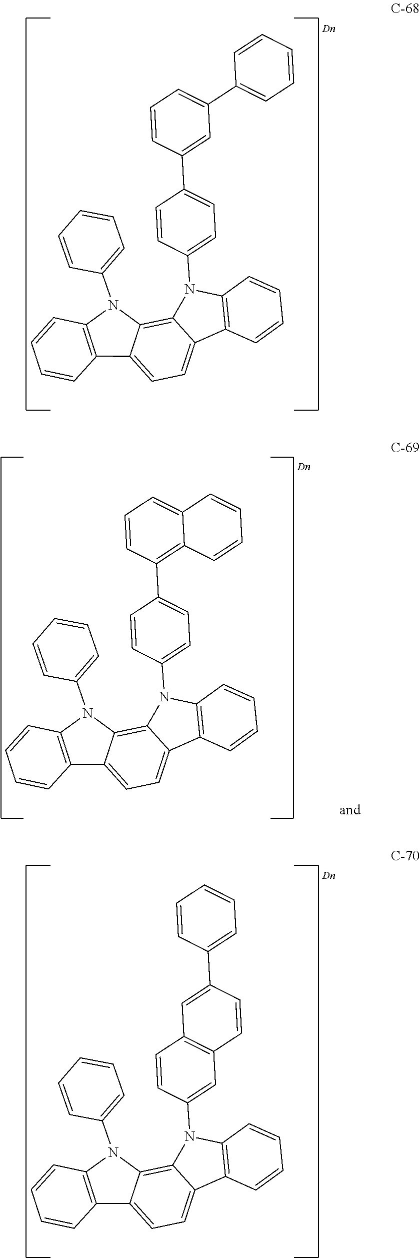
wherein in the compounds, Dₙ means that n hydrogens are replaced by deuterium, and n is an integer from 0 to 1 or more, which sets an upper limit on the number of hydrogen atoms in the non-deuterated compound.

6. The organic electroluminescent device according to claim 1, wherein the compound containing a boron atom is represented by the following Formula 11: 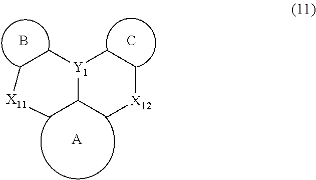
wherein,
ring A, ring B, and ring C each independently represent a substituted or unsubstituted (C₆-C₃₀)aryl or a substituted or unsubstituted (3- to 50-membered)heteroaryl;
X₁₁ and X₁₂ each independently represent NRₐ, O, or S;
Rₐ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or -L₄-N—(Ar₄)(Ar₅); or may be linked to at least one of ring A, ring B, and ring C to form a ring(s);
L₄ represents a single bond, a substituted or unsubstituted (C₆-C₃₀)arylene, a substituted or unsubstituted (3- to 30-membered)heteroarylene, a substituted or unsubstituted divalent (C₂-C₃₀)aliphatic hydrocarbon group, or a substituted or unsubstituted divalent fused ring of a (C₃-C₃₀)aliphatic ring and a (C₆-C₃₀)aromatic ring; and
Ar₄ and Ar₅ each independently represent a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl.

7. The organic electroluminescent device according to claim 1, wherein the light-emitting layer does not comprise a compound comprising an anthracene-based moiety.

8. The organic electroluminescent device according to claim 1, wherein the organic electroluminescent device comprises the compound represented by Formula 1 as a first host, and a compound represented by the following Formula 2 as a second host: 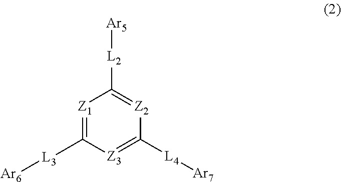
wherein,
Z₁ to Z₃ each independently represent —N═ or —C(R₂₀)═, provided that at least one of Z₁ to Z₃ is N;
R₂₀ represents hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring;
L₂ to L₄ each independently represent a single bond, a substituted or unsubstituted (C₆-C₃₀)arylene, a substituted or unsubstituted (C₃-C₃₀)cycloalkylene, or a substituted or unsubstituted (3- to 30-membered)heteroarylene;
Ar₅ to Ar₇ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, a substituted or unsubstituted fused ring of a (C₃-C₃₀)aliphatic ring and a (C₆-C₃₀)aromatic ring, or *—N—(R₁₁)(R₁₂); or may be linked to adjacent substituents to form a ring(s), provided that at least one of Ar₅ to Ar₇ is a substituted or unsubstituted (C₆-C₃₀)aryl or a substituted or unsubstituted (3- to 30-membered)heteroaryl; and
R₁₁ and R₁₂ each independently represent a substituted or unsubstituted (C₁-C₃₀)alkyl, a substituted or unsubstituted (C₂-C₃₀)alkenyl, a substituted or unsubstituted (C₆-C₃₀)aryl, or a substituted or unsubstituted (3- to 30-membered)heteroaryl.

9. The organic electroluminescent device according to claim 8, wherein at least one of Ar₅ to Ar₇ is represented by any one of the following Formulas 2-1 to 2-7. 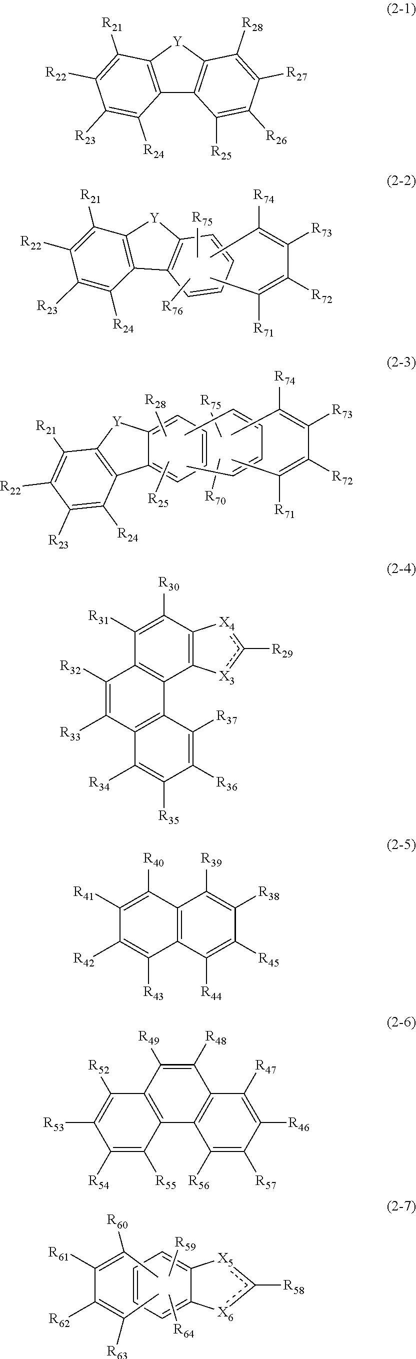
wherein,
Y represents O, S, N(Rn), or C(R₇₈)(R₇₉);
R₇₇ represents a site linked to any one of L₂ to L₄, or a substituted or unsubstituted (C₆-C₃₀)aryl;
R₇₈ and R₇₉ each independently represent a site linked to any one of L₂ to L₄, or a substituted or unsubstituted (C₁-C₃₀)alkyl, a substituted or unsubstituted (C₆-C₃₀)aryl, or a substituted or unsubstituted (3- to 30-membered)heteroaryl; or may be linked to each other to form a ring(s);
R₂₁ to R₂₈, R₃₀ to R₄₉, and R₅₂ to R₅₇, R₅₉ to R₆₄, and R₇₀ to R₇₆ each independently represent a site linked to any one of L₂ to L₄; or hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring; or may be linked to adjacent substituents to form a ring(s);
X₃ to X₆ each independently represent —O—, —S—, —Se—, or —N═; and
R₂₉ and R₅₈ each independently represent a site linked to any one of L₂ to L₄, or a substituted or unsubstituted (C₁-C₃₀)alkyl, a substituted or unsubstituted (C₆-C₃₀)aryl, or a substituted or unsubstituted (3- to 30-membered)heteroaryl.

10. The organic electroluminescent device according to claim 8, wherein at least one of L₂ to L₄ is represented by the following Formula 2-11: 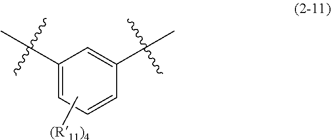
wherein,
R′₁₁ represents hydrogen, deuterium, (C₆-C₃₀)aryl, or a combination thereof, and each of R′₁₁ may be the same or different.

11. The organic electroluminescent device according to claim 8, wherein the compound represented by Formula 2, which has a triplet energy (T₁) greater than 2.8, is included as a second host.

12. The organic electroluminescent device according to claim 8, wherein the compound represented by Formula 2 is selected from the following compounds:

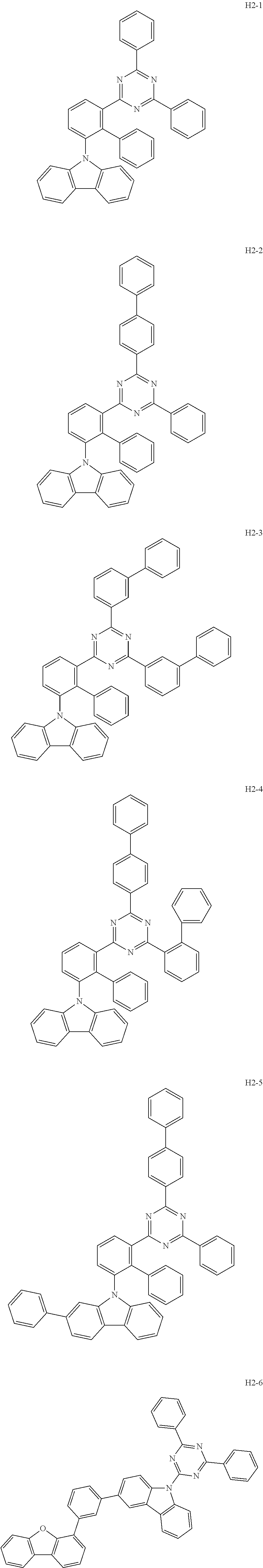

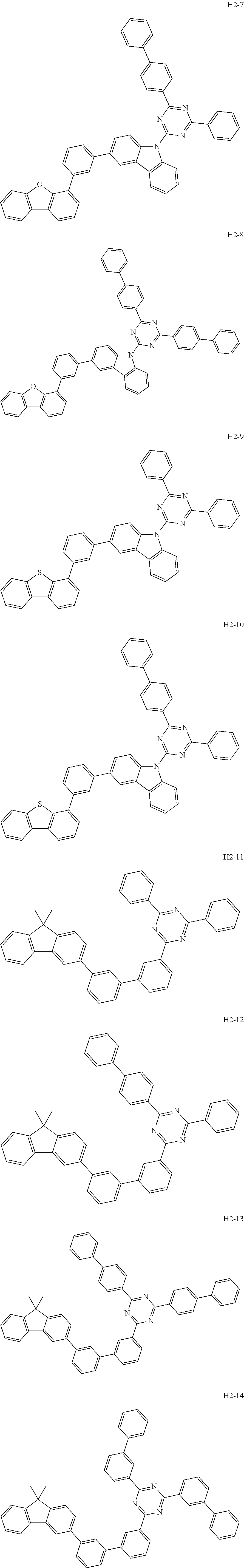

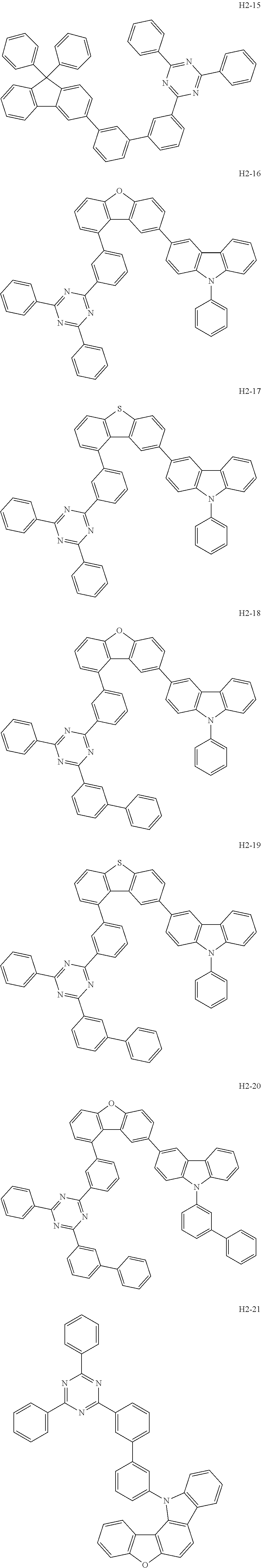

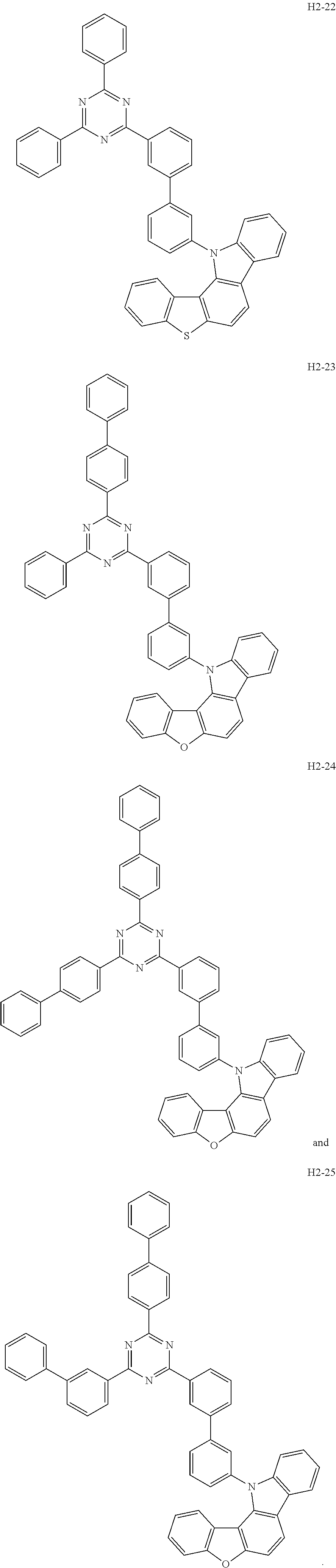 [SMILES: c1ccc(-c2nc(-c3ccccc3)nc(-c3cccc(-c4cccc(-n5c6ccccc6c6ccc7sc8ccccc8c7c65)c4)c3)n2)cc1 ; c1ccc(-c2ccc(-c3nc(-c4ccccc4)nc(-c4cccc(-c5cccc(-n6c7ccccc7c7ccc8oc9ccccc9c8c76)c5)c4)n3)cc2)cc1 ; c1ccc(-c2ccc(-c3nc(-c4ccc(-c5ccccc5)cc4)nc(-c4cccc(-c5cccc(-n6c7ccccc7c7ccc8oc9ccccc9c8c76)c5)c4)n3)cc2)cc1 ; c1ccc(-c2ccc(-c3nc(-c4cccc(-c5ccccc5)c4)nc(-c4cccc(-c5cccc(-n6c7ccccc7c7ccc8oc9ccccc9c8c76)c5)c4)n3)cc2)cc1]

13. The organic electroluminescent device to claim 1, comprises a first dopant which is the compound containing a boron atom and a second dopant which is a compound represented by the following Formula 4, which contains a platinum (Pt) atom and is unsubstituted or substituted with deuterium: 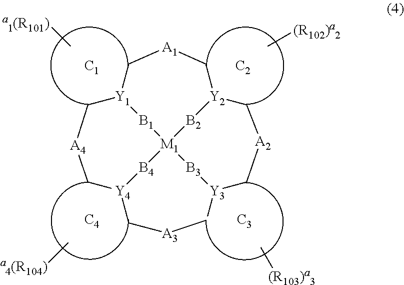
wherein,
M₁ represents platinum (Pt);
ring C₁ to ring C₄ each independently represent (C₅-C₆₀)aryl or (5- to 60-membered)heteroaryl;
A₁ and A₄ each independently represent is absent, or a single bond, —O—, —S—, —C(R₅)(R₆)—, —Si(R₅)(R₆)—, —P(R₅)(R₆)—, or —Ge(R₅)(R₆)—;
B₁ to B₄ each independently represent a single bond, —O—, or —S—;
Y₁ to Y₄ each independently represent a carbon atom (C) or a nitrogen atom (N);
R₅, R₆, and R₁₀₁ to R₁₀₄ each independently represent hydrogen, deuterium, halogen, cyano, a substituted or unsubstituted (C₁-C₃₀)alkyl, a substituted or unsubstituted (C₆-C₃₀)aryl, a substituted or unsubstituted (3- to 30-membered)heteroaryl, a substituted or unsubstituted (C₃-C₃₀)cycloalkyl, a substituted or unsubstituted (C₁-C₃₀)alkoxy, a substituted or unsubstituted tri(C₁-C₃₀)alkylsilyl, a substituted or unsubstituted di(C₁-C₃₀)alkyl(C₆-C₃₀)arylsilyl, a substituted or unsubstituted (C₁-C₃₀)alkyldi(C₆-C₃₀)arylsilyl, a substituted or unsubstituted tri(C₆-C₃₀)arylsilyl, or a substituted or unsubstituted fused ring of a (C₃-C₃₀)aliphatic ring and a (C₆-C₃₀)aromatic ring; and
a₁ to a₄ each independently represent an integer of 1 to 5; and when a₁ to a₄ are 2 or more, each of R₁₀₁ to each of R₁₀₄ may be the same or different.

14. The organic electroluminescent device to claim 13, wherein
the first dopant is a fluorescent emitter,
the second dopant is a phosphorescent emitter, and
the light-emitting layer simultaneously emits fluorescent from the first dopant and phosphorescent from the second dopant.

15. The organic electroluminescent device to claim 13, wherein
the first dopant is a fluorescent emitter,
the second dopant is a sensitizer, and
the light-emitting layer receives energy from the second dopant and emits fluorescent from the first dopant.

16. The organic electroluminescent device to claim 13, wherein the content of the first dopant is less than that of the second dopant.
